(19) United States
(12) Patent Application Publication
(10) Pub. No.: US 2026/0223353 A1
(43) Pub. Date: Jul. 30, 2026

(54) SEMICONDUCTOR DEVICE AND MEMORY DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Hiroki INOUE, Atsugi (JP); Takanori MATSUZAKI, Atsugi (JP); Yuki OKAMOTO, Ebina (JP)

(21) Appl. No.: 19/147,067

(22) PCT Filed: Jan. 17, 2024
(86) PCT No.: PCT/IB2024/050422

§ 371 Date: Jul. 10, 2025

(30) Foreign Application Priority Data
Jan. 24, 2023 (JP) 2023-008691

(51) Int. Cl. H10B 12/00

(52) U.S. Cl. CPC H10B 12/30

(57) ABSTRACT

A semiconductor device that can be highly integrated is provided. The semiconductor device includes a first transistor; a first wiring electrically connected to one of a source and a drain of the first transistor; a second wiring electrically connected to the other of the source and the drain of the first transistor; and a second transistor in which a source or a drain is electrically connected to a gate of the first transistor. The second transistor is provided above the first transistor. The first transistor includes a channel formation region in a semiconductor layer. The semiconductor layer includes a region that extends in a channel length direction of the first transistor. The first wiring includes a region that extends in a channel length direction of the first transistor. The second wiring includes a region that extends in a channel width direction of the first transistor. The first wiring includes a region positioned below the semiconductor layer to overlap with the semiconductor layer. The second wiring includes a region positioned above the semiconductor layer.

### TECHNICAL FIELD

One embodiment of the present invention relates to a semiconductor device, a memory device, and an electronic device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a method for driving any of them, and a method of manufacturing any of them.

Note that in this specification and the like, a semiconductor device generally means a device that can function by utilizing semiconductor characteristics. A semiconductor element such as a transistor, a semiconductor circuit, an arithmetic device, and a memory device are each one embodiment of a semiconductor device. It can sometimes be said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

### BACKGROUND ART

In recent years, semiconductor devices such as an LSI (Large Scale Integration), a CPU (Central Processing Unit), and a memory (memory device) have been developed. These semiconductor devices have been used in various electronic devices such as computers and portable information terminals. In addition, memories under development employ various memory systems for intended uses such as temporary storage at the time of executing arithmetic processing and long-term storage of data. Memories with typical memory systems include a DRAM (Dynamic Random Access Memory), an SRAM (Static Random Access Memory), and a flash memory.

With an increase in the amount of data dealt with, semiconductor devices having a larger memory capacity have been required. Patent Document 1 and Non-Patent Document 1 disclose memory cells formed by stacking transistors.

In order to increase the memory capacity of the semiconductor device, miniaturization of transistors included in the semiconductor device has been promoted. To miniaturize the transistors, a transistor having a vertical structure has been actively studied. For example, Non-Patent Document 2 and Non-Patent Document 3 disclose a transistor having a vertical structure including a metal oxide in a region where a channel is formed (also referred to as a channel formation region).

### REFERENCE

### Patent Document

[Patent Document 1] PCT International Publication No. 2021/053473

### Non-Patent Documents

[Non-Patent Document 1] M. Oota, et. al, “3D-Stacked CAAC-In—Ga—Zn Oxide FETs with Gate Length of 72 nm”, IEDM Tech. Dig., 2019, pp. 50-53
[Non-Patent Document 2] X. Duan et. al, “Novel Vertical Channel-All-Around (CAA) IGZO FETs for 2TOC DRAM with High Density beyond 4F² by Monolithic Stacking”, IEDM Tech. Dig., 2021, pp. 222-225
[Non-Patent Document 3] H. Fujiwara et. al, “Surrounding Gate Vertical-Channel FET with Gate Length of 40 nm Using BEOL Compatible High-Thermal-Tolerance In—Al—Zn Oxide Channel”, 2020 Symposium on VLSI Technology: Digest of Technical Papers, pp. 1-2, TH2.2

### SUMMARY OF THE INVENTION

### Problems to be Solved by the Invention

An object of one embodiment of the present invention is to provide a semiconductor device that can be miniaturized or highly integrated. Another object of one embodiment of the present invention is to provide a memory device having large memory capacity. Another object of one embodiment of the present invention is to provide a semiconductor device occupying a small area. Another object of one embodiment of the present invention is to provide a highly reliable semiconductor device. Another object of one embodiment of the present invention is to provide a semiconductor device with low power consumption. Another object of one embodiment of the present invention is to provide a novel semiconductor device. Another object of one embodiment of the present invention is to provide a novel memory device.

Note that the description of these objects does not preclude the presence of other objects. One embodiment of the present invention does not need to achieve all of these objects. Other objects can be derived from the description of the specification, the drawings, and the claims.

### Means for Solving the Problems

One embodiment of the present invention is a semiconductor device including a first transistor; a first wiring electrically connected to one of a source and a drain of the first transistor; a second wiring electrically connected to the other of the source and the drain of the first transistor; and a second transistor in which a source or a drain is electrically connected to a gate of the first transistor. The second transistor is provided above the first transistor. The first transistor includes a channel formation region in a semiconductor layer. The semiconductor layer includes a region that extends in a channel length direction of the first transistor. The first wiring includes a region that extends in a channel length direction of the first transistor. The second wiring includes a region that extends in a channel width direction of the first transistor. The first wiring includes a region positioned below the semiconductor layer to overlap with the semiconductor layer. The second wiring includes a region positioned above the semiconductor layer.

Another embodiment of the present invention is a semiconductor device including a first transistor; a second transistor over the first transistor; and a first conductor under the first transistor. The first transistor includes a first oxide semiconductor; a second conductor and a third conductor which are separated from each other over the first oxide semiconductor; a first insulator being positioned over the second conductor and the third conductor and including an opening positioned between the second conductor and the third conductor; a second insulator positioned in an opening of the first insulator and over the first oxide semiconductor; and a fourth conductor positioned in the opening of the first insulator and over the second insulator. The second transistor includes a third insulator being positioned over the first insulator and the fourth conductor and including an opening overlapping with the first oxide semiconductor; a fifth conductor being positioned over the third insulator and including an opening overlapping with the opening of the third insulator; a second oxide semiconductor positioned in the opening of the third insulator and the fifth conductor; a fourth insulator positioned over the second oxide semiconductor in the opening of the third insulator and the fifth conductor; and a sixth conductor positioned over the fourth insulator in the opening of the third insulator and the fifth conductor. The second oxide semiconductor is electrically connected to the fourth conductor. The first conductor is electrically connected to the third conductor. The first conductor extends in a channel length direction of the first transistor. The first conductor is positioned to overlap with the first oxide semiconductor and the second oxide semiconductor.

In the above, it is preferable that a seventh conductor be placed to penetrate the third conductor and the first oxide semiconductor, and the seventh conductor be in contact with a top surface of the first conductor.

In the above, the semiconductor device may further include an eighth conductor in contact with a top surface of the sixth conductor, the eighth conductor may extend in a channel length direction of the first transistor, and the fifth conductor may extend to intersect the channel length direction of the first transistor.

In the above, the semiconductor device may further include an eighth conductor in contact with a top surface of the sixth conductor, the eighth conductor may extend to intersect a channel length direction of the first transistor, and the fifth conductor may extend in the channel length direction of the first transistor.

In the above, it is preferable that the second oxide semiconductor include one or more selected from In, Ga, and Zn.

In the above, it is preferable that a ninth conductor be positioned over the second conductor, and the ninth conductor extend to intersect a channel length direction of the first transistor.

In the above, it is preferable that a tenth conductor be positioned under the second oxide semiconductor, the opening of the third insulator reach the tenth conductor, and the tenth conductor be in contact with a part of the second oxide semiconductor and electrically connected to the fourth conductor.

In the above, it is preferable that the channel length of the second transistor be smaller than at least the channel width of the second transistor.

In the above, it is preferable that another part of the second oxide semiconductor, a part of the fourth insulator, and a part of the sixth conductor be positioned over the fifth conductor.

In the above, it is preferable that the another part of the second oxide semiconductor be in contact with a top surface of the fifth conductor.

In the above, it is preferable that the opening of the third insulator and the fifth conductor have a circular shape or a substantially circular shape in a plan view.

In the above, it is preferable that the third insulator have a stacked-layer structure, the stacked-layer structure include a first layer, a second layer over the first layer, and a third layer over the second layer, the first layer include silicon and nitrogen, the second layer include silicon and oxygen, and the third layer include silicon and nitrogen.

In the above, it is preferable that the first oxide semiconductor include one or more selected from In, Ga, and Zn.

Another embodiment of the present invention is a memory device including the above-described semiconductor device; a first circuit; and a second circuit. The first circuit is electrically connected to the first conductor, and the second circuit is electrically connected to the ninth conductor.

### Effect of the Invention

One embodiment of the present invention can provide a semiconductor device that can be miniaturized or highly integrated. Another embodiment of the present invention can provide a memory device having large memory capacity. Another embodiment of the present invention can provide a semiconductor device occupying a small area. Another embodiment of the present invention can provide a highly reliable semiconductor device. Another embodiment of the present invention can provide a semiconductor device with low power consumption. Another embodiment of the present invention can provide a novel semiconductor device. Another embodiment of the present invention can provide a novel memory device.

Note that the description of these effects does not preclude the presence of other effects. One embodiment of the present invention does not necessarily have all the effects. Other effects can be derived from the description of the specification, the drawings, and the claims.

### BRIEF DESCRIPTION OF THE DRAWINGS

FIG. 1A is a perspective view illustrating a structure example of a memory device. FIG. 1B is a circuit diagram illustrating a structure of a memory device.

FIG. 2A and FIG. 2B are perspective views illustrating a structure example of a memory device.

FIG. 3A and FIG. 3B are cross-sectional views illustrating a structure example of a memory device.

FIG. 4A and FIG. 4B are cross-sectional views illustrating a structure example of a memory device.

FIG. 5A and FIG. 5B are layout diagrams illustrating a structure example of a memory device.

FIG. 6A is a circuit diagram illustrating a structure of a memory device, and FIG. 6B is a timing chart illustrating a method for driving the memory device.

FIG. 7A and FIG. 7B are cross-sectional views illustrating a structure example of a memory device.

FIG. 8A to FIG. 8F are cross-sectional views each illustrating a structure example of a memory device.

FIG. 9A to FIG. 9F are cross-sectional views each illustrating a structure example of a memory device.

FIG. 10 is a cross-sectional view illustrating a structure example of a memory device.

FIG. 11A is a perspective view illustrating a structure example of a memory device. FIG. 11B is a circuit diagram illustrating the structure of the memory device.

FIG. 12A and FIG. 12B are layout diagrams illustrating a structure example of a memory device.

FIG. 13A and FIG. 13B are cross-sectional views each illustrating a structure example of a memory device.

FIG. 14A and FIG. 14B are layout diagrams each illustrating a structure example of a memory device.

FIG. 15A and FIG. 15B are layout diagrams each illustrating a structure example of a memory device.

FIG. 16A is a plan view illustrating an example of a semiconductor device. FIG. 16B to FIG. 16D are cross-sectional views illustrating the example of the semiconductor device.

FIG. 17A and FIG. 17B are cross-sectional views illustrating an example of a semiconductor device.

FIG. 18A and FIG. 18B are cross-sectional views illustrating an example of a semiconductor device.

FIG. 19A and FIG. 19B are cross-sectional views illustrating an example of a semiconductor device.

FIG. 20A to FIG. 20E are cross-sectional views each illustrating an example of a semiconductor device.

FIG. 21A to FIG. 21D are cross-sectional views each illustrating an example of a semiconductor device.

FIG. 22A to FIG. 22D are cross-sectional views each illustrating an example of a semiconductor device.

FIG. 23A and FIG. 23B are cross-sectional views each illustrating an example of a semiconductor device.

FIG. 24A is a block diagram illustrating a structure example of a memory device. FIG. 24B is a perspective view illustrating the structure example of the memory device.

FIG. 25A and FIG. 25B are perspective views illustrating a structure example of a memory device.

FIG. 26A and FIG. 26B are diagrams illustrating an example of a semiconductor device.

FIG. 27A and FIG. 27B are diagrams each illustrating an example of an electronic component.

FIG. 28A to FIG. 28E are schematic diagrams of memory devices of one embodiment of the present invention.

FIG. 29A and FIG. 29B are diagrams each illustrating an example of an electronic device, and FIG. 29C to FIG. 29E are diagrams illustrating an example of a large computer.

FIG. 30 is a diagram illustrating an example of a device for space.

FIG. 31 is a diagram illustrating an example of a storage system that can be used in a data center.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Hence, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). In some cases, an ordinal number used for a component in a certain part in this specification is not the same as an ordinal number used for the component in another part in this specification or claims.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

Note that in this specification and the like, an oxynitride refers to a material having a composition in which the oxygen content is higher than the nitrogen content, and a nitride oxide refers to a material having a composition in which the nitrogen content is higher than the oxygen content. For example, silicon oxynitride refers to a material having a composition in which the oxygen content is higher than the nitrogen content, and silicon nitride oxide refers to a material having a composition in which the nitrogen content is higher than the oxygen content.

In this specification and the like, terms for describing positioning, such as “over”, “under”, “above”, and “below”, are sometimes used for convenience to describe the positional relationship between components with reference to drawings. The positional relationship between components is changed as appropriate in accordance with the direction in which each component is described. Thus, the positional relationship is not limited to the terms described in this specification and the like, and can be described with another term as appropriate depending on the situation. For example, the expression “an insulator positioned over a conductor” can be replaced with the expression “an insulator positioned under a conductor” when the direction of a drawing illustrating these components is rotated by 180°.

In this specification and the like, the expression “level with” indicates a structure having the same level from a reference surface (e.g., a flat surface such as a substrate surface) in the cross-sectional view. For example, in a manufacturing process of a semiconductor device, planarization treatment (typically, CMP treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the surfaces on which the CMP treatment is performed. This case is also regarded as being “level with” in this specification and the like. For example, the expression, a top surface of a first layer “level with” a top surface of a second layer includes the case where the difference between a level of the top surface of the first layer from a reference surface and a level of the top surface of the second layer from the reference surface is less than or equal to 20 nm.

In this specification and the like, the expression “end portions are aligned” means that at least outlines of stacked layers partly overlap with each other in the top view. For example, the case of processing the upper layer and the lower layer with use of the same mask pattern or mask patterns that are partly the same is included. However, in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned”.

Note that in general, it is difficult to clearly differentiate “perfectly aligned” from “substantially aligned”. Thus, the expression “aligned” includes both “perfectly aligned” and “substantially aligned” in this specification and the like.

### Embodiment 1

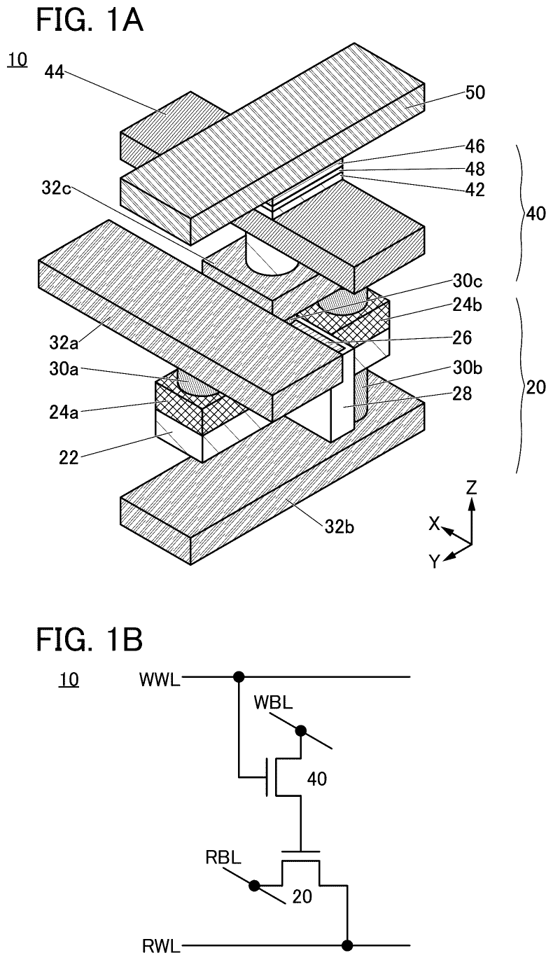

In this embodiment, a memory device of one embodiment of the present invention will be described with reference to FIG. 1 to FIG. 15.

One embodiment of the present invention relates to a memory device provided with a transistor. The memory device includes a first transistor and a second transistor, which can form a memory cell. In the memory device, a plurality of memory cells are arranged in a matrix to form a memory cell array. The memory device of one embodiment of the present invention has a function of storing data.

A transistor used in a memory device of one embodiment of the present invention is preferably a transistor including a metal oxide in a channel formation region. Here, the metal oxide is preferably an oxide semiconductor functioning as a semiconductor. That is, the memory device of one embodiment of the present invention uses a semiconductor and thus can be referred to as a semiconductor device. Hereinafter, a transistor including a metal oxide in a channel formation region is referred to as an OS (oxide semiconductor) transistor in some cases. The OS transistor has a low off-state current. Thus, by including the OS transistor, the memory device can retain stored contents for a long time. That is, no refresh operation is required or the frequency of refresh operation is extremely low; thus, the power consumption of the memory device can be adequately reduced. Accordingly, a memory device with low power consumption can be provided. Since the OS transistor has high frequency characteristics, the memory device can perform data reading and writing at high speed. Consequently, a memory device with high operating speed can be provided.

### <Structure Example of Memory Device>

Structure examples of a memory device of one embodiment of the present invention will be described below.

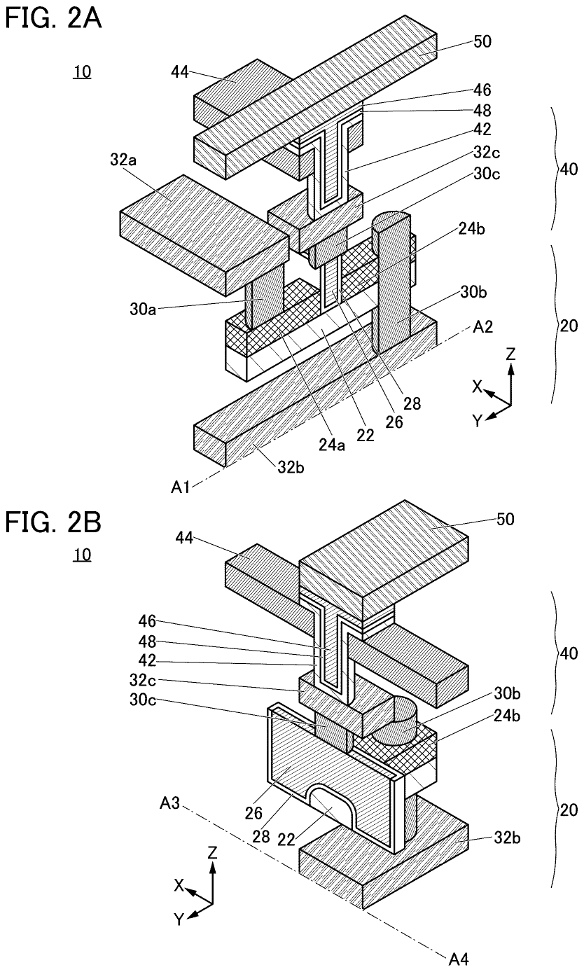

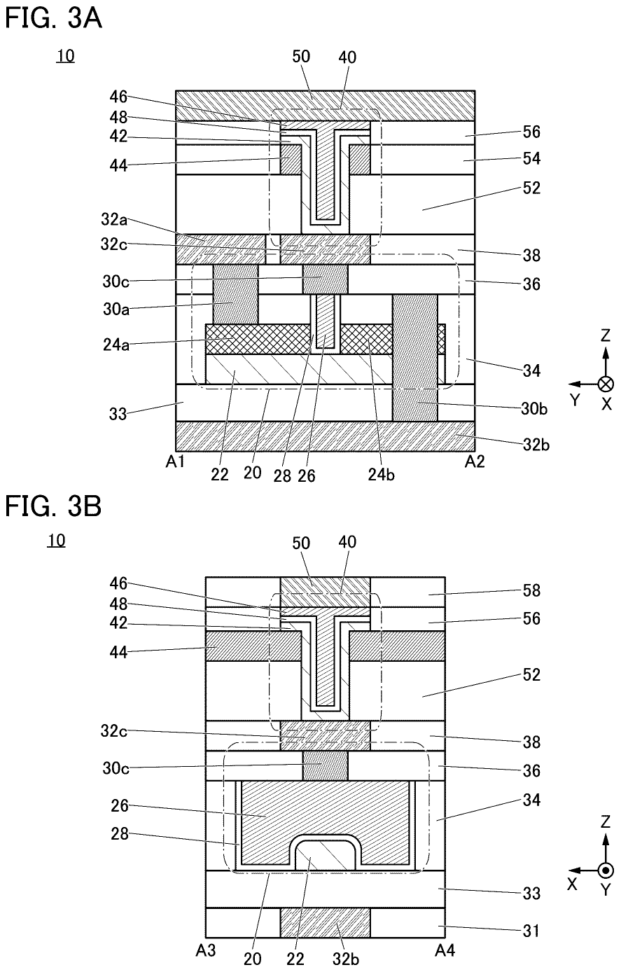

FIG. 1A is a perspective view illustrating a structure example of a memory device of one embodiment of the present invention. FIG. 1B is a circuit diagram corresponding to the memory device illustrated in FIG. 1A. FIG. 2A illustrates a perspective view obtained by cutting the perspective view of FIG. 1A along a plane including the dashed-dotted line A1-A2. FIG. 2B illustrates a perspective view obtained by cutting the perspective view of FIG. 1A along a plane including the dashed-dotted line A3-A4. FIG. 3A is a cross-sectional view of the memory device corresponding to the portion indicated by the dashed-dotted line A1-A2. FIG. 3B is a cross-sectional view of the memory device corresponding to the portion indicated by the dashed-dotted line A3-A4. Note that the dashed-dotted line A1-A2 is a straight line parallel to the Y-axis in the drawing and is parallel or substantially parallel to the channel length direction of a transistor 20. The dashed-dotted line A3-A4 is a straight line parallel to the X-axis in the drawing and is parallel or substantially parallel to the channel width direction of the transistor 20. For clarity of the drawing, some components are not illustrated in the perspective views.

Note that in the drawings and the like in this specification, arrows indicating the X-axis direction, the Y-axis direction, and the Z-axis direction are illustrated in some cases. Note that in this specification and the like, the “X-axis direction” is a direction along the X axis, and unless otherwise specified, the forward direction and the reverse direction are not distinguished in some cases. The same applies to the “Y-axis direction” and the “Z-axis direction”. For example, the Z-axis direction refers to a direction perpendicular or substantially perpendicular to the substrate surface in some cases. The X-axis direction, the Y-axis direction, and the Z-axis direction are directions intersecting with one another. For example, the X-axis direction, the Y-axis direction, and the Z-axis direction are directions orthogonal to one another. In this specification and the like, one of the X-axis direction, the Y-axis direction, and the Z-axis direction is referred to as a “first direction” in some cases. Another one of the directions is referred to as a “second direction” in some cases. The remaining one of the directions is referred to as a “third direction” in some cases.

The memory device of one embodiment of the present invention includes a plurality of memory cells 10. The memory cell 10 includes the transistor 20 and a transistor 40 over the transistor 20. The transistor 20 includes an oxide semiconductor 22, a conductor 24a, a conductor 24b, an insulator 28, and a conductor 26. An insulator 34 is preferably provided over the transistor 20. The oxide semiconductor 22 is provided over a substrate (not illustrated). The conductor 24a and the conductor 24b are apart from each other and provided over the oxide semiconductor 22. The insulator 34 is positioned over the conductor 24a and the conductor 24b and includes an opening positioned between the conductor 24a and the conductor 24b. The insulator 28 is positioned in the opening of the insulator 34 and is positioned over the oxide semiconductor 22. The conductor 26 is positioned in the opening of the insulator 34 and is positioned over the insulator 28.

The transistor 40 includes a conductor 32c, a conductor 44, an oxide semiconductor 42, an insulator 48, and a conductor 46. An insulator 52 is preferably provided over the conductor 32c. The conductor 32c is provided over the conductor 26. The insulator 52 is positioned over the conductor 32c and includes an opening overlapping with the oxide semiconductor 22. The conductor 44 is positioned over the insulator 52 and includes an opening overlapping with an opening of the insulator 52. The oxide semiconductor 42 is positioned in the opening of the insulator 52 and the conductor 44. The insulator 48 is positioned over the oxide semiconductor 42 in the opening of the insulator 52 and the conductor 44. The conductor 46 is positioned over the insulator 48 in the opening of the insulator 52 and the conductor 44. Here, part of the oxide semiconductor 42 penetrates the insulator 52 and is in contact with the conductor 32c.

Note that as illustrated in FIG. 3A, FIG. 3B, and the like, an insulator 36 is provided over the insulator 34. A conductor 30a is positioned in an opening formed in the insulator 34 and the insulator 36. A conductor 30c is positioned in an opening formed in the insulator 36. The conductor 30a is in contact with a top surface of the conductor 24a, and the conductor 30c is in contact with a top surface of the conductor 26.

The insulator 38 is provided over the insulator 36. A conductor 32a and the conductor 32c are positioned in openings formed in the insulator 38. The conductor 32a is positioned in contact with the top surface of the conductor 30a, and the conductor 32c is positioned in contact with the top surface of the conductor 30c. The insulator 52 is provided over the insulator 38.

An insulator 33 is provided under the insulator 34 and the oxide semiconductor 22. A conductor 30b is preferably positioned in an opening formed in the insulator 33, the oxide semiconductor 22, the conductor 24b, and the insulator 34. That is, the conductor 30b is preferably positioned to penetrate the oxide semiconductor 22 and the conductor 24b, and the side surface of the conductor 30b is preferably in contact with the conductor 24b and the oxide semiconductor 22.

An insulator 31 is provided below the insulator 33. A conductor 32b is positioned in an opening formed in the insulator 31. The conductor 32b is provided in contact with the bottom surface of the conductor 30b. That is, the conductor 32b is electrically connected to the conductor 24b through the conductor 30b. Here, the conductor 32b is preferably positioned to overlap with the oxide semiconductor 22.

Note that as illustrated in FIG. 3B, the top surface of the conductor 30b is preferably level or substantially level with the top surface of the insulator 34. For example, the difference between the top surface of the conductor 30b and the top surface of the insulator 34 is preferably smaller than or equal to the thickness of the conductor 24b. Such a structure can reduce the risk of electrical continuity between the conductor 30b and each of the conductor 30c and the conductor 32c. Note that the present invention is not limited thereto, and a structure in which the top surface of the conductor 30b is level with or substantially level with the top surface of the insulator 36 can be employed. For example, the difference between the top surface of the conductor 30b and the top surface of the insulator 36 is preferably smaller than or equal to the thickness of the conductor 24b. Alternatively, a structure can be employed in which the top surface of the conductor 30b is level with or substantially level with the top surface of the conductor 24b. For example, the difference in level between the top surface of the conductor 30b and the top surface of the conductor 24b is preferably smaller than or equal to the thickness of the conductor 24b.

An insulator 54 is provided over the insulator 52. The conductor 44 is positioned in an opening formed in the insulator 54. An insulator 56 is provided over the insulator 54. Part of the oxide semiconductor 42, part of the insulator 48, and part of the conductor 46 are positioned in an opening formed in the insulator 56. That is, the part of the oxide semiconductor 42, the part of the insulator 48, and the part of the conductor 46 are positioned over the conductor 44. An insulator 58 is provided over the insulator 56. A conductor 50 is positioned in an opening formed in the insulator 58. The conductor 50 is positioned in contact with a top surface of the conductor 46.

In the following description of matters common to components distinguished from each other using letters of the alphabet, reference numerals without the letters of the alphabet are sometimes used. For example, in the case where matters common to the conductor 24a and the conductor 24b are described, the term “conductor 24” is sometimes used.

In the transistor 20, the conductor 26 functions as a gate electrode, the insulator 28 functions as a gate insulator, the conductor 24a functions as one of a source electrode and a drain electrode, and the conductor 24b functions as the other of the source electrode and the drain electrode. The conductor 32a is provided to extend in the X-axis direction and functions as a wiring electrically connected to one of the source electrode and the drain electrode of the transistor 20. The conductor 32b is provided to extend in the Y-axis direction and functions as a wiring electrically connected to the other of the source electrode and the drain electrode of the transistor 20. Here, when the conductor 32b is placed under the oxide semiconductor 22, the conductor 32b can be provided to extend in the Y-axis direction without interference of the conductor 30c, the conductor 32c, the oxide semiconductor 42, and the like. Thus, the conductor 32b and the conductor 32a can be placed to intersect with each other. Note that in this specification and the like, “extend in the X-axis direction” refers to a state where an angle formed therebetween is greater than or equal to −30° and less than or equal to +30° with reference to the X-axis. Furthermore, “extend in the Y-axis direction” refers to a state where an angle formed therebetween is greater than or equal to −30° and less than or equal to +30° with reference to the Y-axis. Furthermore, “extend in the Z-axis direction” refers to a state where an angle formed therebetween is greater than or equal to −30° and less than or equal to +30° with reference to the Z-axis.

In the transistor 20, the conductor 26 and the insulator 28 are formed in a self-aligned manner to fill an opening formed by the insulator 34, the conductor 24a, and the conductor 24b. This enables the conductor 26 to be positioned without fail in a region between the conductor 24a and the conductor 24b even without alignment. Note that specific structure examples of the transistor 20 will be described in Embodiment 2.

In the transistor 40, the conductor 46 functions as a gate electrode, the insulator 48 functions as a gate insulator, the conductor 44 functions as one of a source electrode and a drain electrode, and the conductor 32c functions as the other of the source electrode and the drain electrode. Part of the conductor 44 is provided to extend in the Y-axis direction and functions as a wiring electrically connected to one of the source electrode and the drain electrode. The conductor 50 is provided to extend in the X-axis direction and functions as a wiring electrically connected to the gate electrode. Thus, the direction in which the conductor 44 extends and the direction in which the conductor 50 extends intersect with each other.

With the above structure, the other of the source electrode and the drain electrode of the transistor 40 and the gate electrode of the transistor 20 are electrically connected to each other through the conductor 30c. That is, the conductor 32c is electrically connected to the conductor 26. The oxide semiconductor 42 is electrically connected to the conductor 26. Here, the transistor 40 is a vertical transistor whose channel formation region is formed parallel to the Z-axis direction. Thus, the conductor 32c functioning as the other of the source electrode and the drain electrode is formed at a bottom portion of the transistor 40. Meanwhile, the conductor 26 functioning as the gate electrode of the transistor 20 is formed at a top portion of the transistor 20. Thus, in a memory cell 10 in which the other of the source electrode and the drain electrode of the transistor 40 and the gate electrode of the transistor 20 are electrically connected to each other, the transistor 40 and the transistor 20 can be electrically connected to each other without additional wirings or vias. This results in a reduction in the area occupied by the memory cell, so that memory cells can be arranged densely to increase the memory capacity of the memory device. In other words, the memory device can be highly integrated.

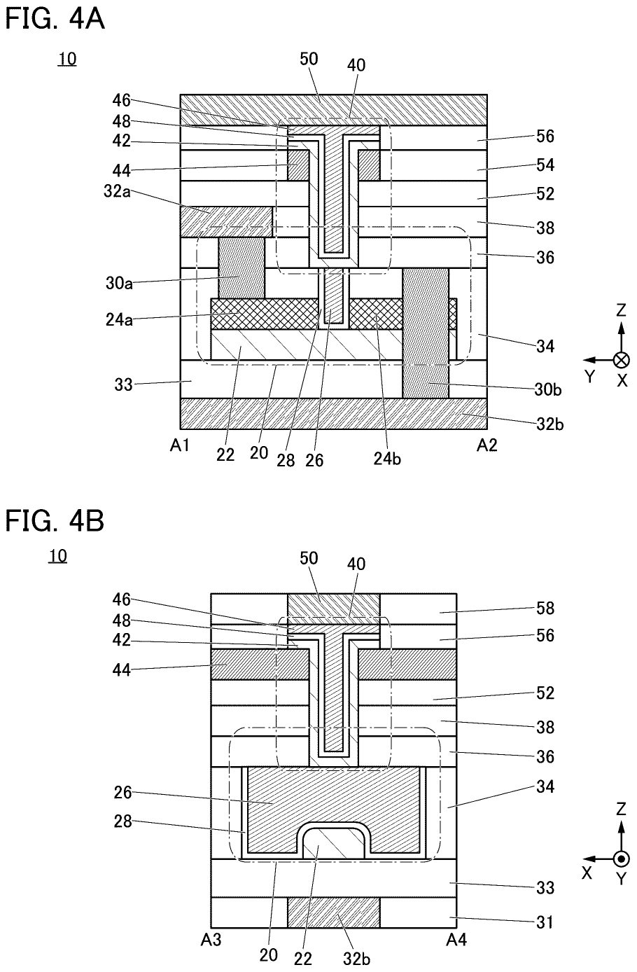

Note that the present invention is not limited to the aforementioned structure in which the transistor 20 and the transistor 40 are connected to each other through the conductor 32c and the conductor 30c. For example, as illustrated in FIG. 4A and FIG. 4B, the oxide semiconductor 42 of the transistor 40 may be in contact with the conductor 26 of the transistor 20. Here, FIG. 4A is a drawing corresponding to FIG. 3A, and FIG. 4B is a drawing corresponding to FIG. 3B.

In that case, the oxide semiconductor 42, the insulator 48, and the conductor 46 are positioned in the opening formed in the conductor 44, the insulator 52, the insulator 38, and the insulator 36. Since the opening reaches the conductor 26, the insulator 28, and the insulator 34, a bottom surface of the oxide semiconductor 42 is in contact with top surfaces of the conductor 26, the insulator 28, and the insulator 34. Such a structure eliminates the need to form the conductor 30c and the conductor 32c, thereby miniaturizing the memory device.

The oxide semiconductor 42 includes regions in contact with side surfaces of the conductor 44 and regions in contact with part of a top surface of the conductor 44 in the vicinity of the opening of the conductor 44. When the oxide semiconductor 42 is thus in contact with the top surface as well as the side surfaces of the conductor 44, the area where the oxide semiconductor 42 is in contact with the conductor 44 can be increased.

The transistor 40 preferably overlaps with at least part of the transistor 20. For example, the oxide semiconductor 42 preferably overlaps with at least part of the oxide semiconductor 22 with the conductor 26 therebetween. With such a structure, the transistor 20 and the transistor 40 can be provided without a great increase in the occupation area in the plan view. This results in a reduction in the area occupied by the memory cell, so that memory cells can be arranged densely to increase the memory capacity of the memory device.

It is preferable that one of the conductor 32a and the conductor 32b function as a bit line of the memory cell 10 and the other function as a word line of the memory cell 10. Thus, the conductor 32a and the conductor 32b are preferably positioned to intersect with each other. Here, in consideration of the case where both the conductor 32a and the conductor 32b are provided over the oxide semiconductor 22, the conductor 32a or the conductor 32b which is provided to extend in the Y-axis direction is positioned so as not to be provided in the conductor 30c, the conductor 32c, the oxide semiconductor 42, and the like. Thus, the area occupied by the memory cell 10 is increased in the X-axis direction by one wiring. In contrast, in this embodiment, one of the conductor 32a and the conductor 32b (the conductor 32a in FIG. 1 and the like) is placed over the oxide semiconductor 22, and the other of the conductor 32a and the conductor 32b (the conductor 32b in FIG. 1 and the like) is placed under the oxide semiconductor 22. Thus, the conductor 32a over the oxide semiconductor 22 can be placed to extend in the X-axis direction without avoiding the conductor 30c, the conductor 32c, the oxide semiconductor 42, and the like. Furthermore, the conductor 32b under the oxide semiconductor 22 can be placed to overlap with the oxide semiconductor 22 and extend in the Y-axis direction. As described above, the area occupied by the memory cell 10 can be reduced by an overlapped area between the conductor 32b provided to extend in the Y-axis direction and the oxide semiconductor 22 provided to extend in the Y-axis direction. Thus, in the case where the conductor 32a is placed over the oxide semiconductor 42 and the conductor 32b is placed under the oxide semiconductor 42, the conductor 32a and the conductor 32b can be placed to intersect with each other and the area occupied by the memory cell 10 can be smaller than that in the case where both the conductor 32a and the conductor 32b are placed over the oxide semiconductor 42.

Here, in the plan view, the oxide semiconductor 22 is formed such that the major axis is parallel or substantially parallel to the Y axis, and the channel length direction of the transistor 20 is parallel or substantially parallel to the Y axis. In other words, the conductor 32b extends in the channel length direction of the transistor 20. Thus, the conductor 32b can be provided to overlap with the oxide semiconductor 22 and the oxide semiconductor 42. With such a structure, the transistor 20, the transistor 40, and a wiring connected to these transistors can be provided without a great increase in the area occupied by the memory cell in the plan view. This results in a reduction in the area occupied by the memory cell, so that memory cells can be arranged densely to increase the memory capacity of the memory device.

As described above, the conductor 32b and the conductor 50 are provided to extend in the Y-axis direction, and the conductor 32a and the conductor 44 are provided to extend in the X-axis direction. That is, the conductor 32b and the conductor 50 extend in the channel length direction of the transistor 40, and the conductor 32a and the conductor 44 extend to intersect the channel length direction of the transistor 40. Thus, the conductor 50 provided to extend in the Y-axis direction is preferably provided to overlap with the conductor 32b. Such a structure results in a reduction in the area occupied by the memory cell, so that memory cells can be arranged densely to increase the memory capacity of the memory device.

The memory device described in this embodiment can function as a memory cell array by arranging the plurality of memory cells 10 in a matrix. As illustrated in FIG. 1B, in the memory cell 10, the gate electrode of the transistor 40 is electrically connected to a wiring WWL, one of the source electrode and the drain electrode thereof is electrically connected to a wiring WBL, and the other of the source electrode and the drain electrode thereof is electrically connected to the gate electrode of the transistor 20. Note that a node at which the other of the source electrode and the drain electrode of the transistor 40 and the gate electrode of the transistor 20 are connected is referred to as a storage node in some cases. One of the source electrode and the drain electrode of the transistor 20 is electrically connected to a wiring RBL, and the other of the source electrode and the drain electrode thereof is electrically connected to a wiring RWL. The gate capacitance of the transistor 20 is used as a storage capacitor. That is, the memory cell described in this embodiment can be regarded as a capacitorless memory cell. Therefore, the memory cell can also be regarded as a gain-cell memory cell with two transistors and no capacitor.

When an OS transistor is used as the transistor 40 and the transistor 40 is turned off, electric charge at a node where one of the source and the drain of the transistor 40 is electrically connected to the gate of the transistor 20 can be retained for an extremely long time. Accordingly, a memory cell with an extremely long refresh interval or a nonvolatile memory cell can be obtained.

Note that in FIG. 1B and the like, the transistor 20 and the transistor 40 have a single gate structure. However, the transistor 20 and the transistor 40 are not limited to this structure, and may each be provided with a second gate (also referred to as a back gate).

The wiring WWL functions as a write word line, the wiring WBL functions as a write bit line, the wiring RBL functions as a read bit line, and the wiring RWL functions as read word line. Here, it is preferable that the wiring WWL and the wiring RWL be connected to the row circuit and the wiring WBL and the wiring RBL be connected to the column circuit.

The wiring WWL corresponds to the conductor 50, the wiring WBL corresponds to the conductor 44, the wiring RBL corresponds to the conductor 32a, and the wiring RWL corresponds to the conductor 32b. As described above, the conductor 50 (the wiring WWL) and the conductor 32b (the wiring RWL) are provided to extend in the Y-axis direction, and the conductor 44 (the wiring WBL) and the conductor 32a (the wiring RBL) are provided to extend in the X-axis direction. Thus, the wiring WWL and the wiring RWL can be connected to the row circuit, and the wiring WBL and the wiring RBL can be connected to the column circuit.

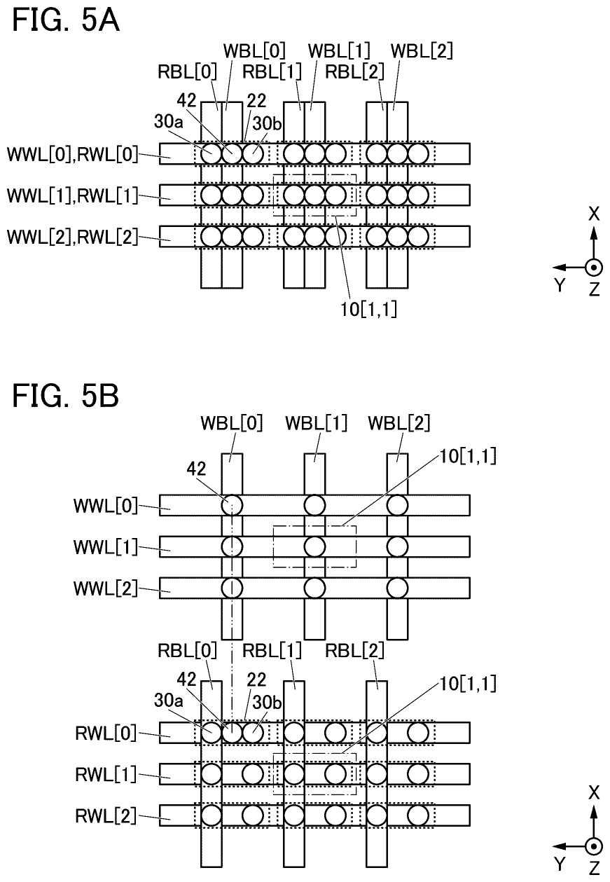

Here, FIG. 5A and FIG. 5B each illustrate a schematic layout diagram of a memory cell array in which the memory cells 10 are arranged in a matrix of three rows and three columns. In the layout diagrams illustrated in FIG. 5A and FIG. 5B, the wiring WWL, the wiring RWL, the wiring WBL, the wiring RBL, the oxide semiconductor 42, the oxide semiconductor 22, the conductor 30a, and the conductor 30b are illustrated. Note that for clarity of the drawings, the oxide semiconductor 22 is indicated by a dashed line. Arrows indicating the X-axis direction, the Y-axis direction, and the Z-axis direction illustrated in FIG. 5A and FIG. 5B correspond to arrows indicating the X-axis direction, the Y-axis direction, and the Z-axis direction illustrated in FIG. 1A and the like.

Three wirings WWL, three wirings RWL, three wirings WBL, and three wirings RBL are provided, and are denoted by the numbers [0] to [2]. Note that in the following description, a wiring WWL[0] to a wiring WWL[2] are collectively referred to as a wiring WWL in some cases. The same applies to the wiring RWL, the wiring WBL, and the wiring RBL. The memory cells 10 can be referred to as a memory cell 10[0,0] to a memory cell 10[2,2] by adding the numbers of wirings connected to the respective memory cells 10. Note that in FIG. 5A and FIG. 5B, only a memory cell 10[1,1] is shown by a dashed-dotted frame line for clarity of the drawings.

FIG. 5B is a layout diagram in which components of the transistor 40 (the wiring WWL, the wiring WBL, and the oxide semiconductor 42) and components of the transistor 20 (the wiring RWL, the wiring RBL, the oxide semiconductor 22, the conductor 30a, and the conductor 30b) are separately displayed for clarity of the drawing. Note that to clarify a portion where the layout diagram of the transistor 40 overlaps with the layout diagram of the transistor 20, the oxide semiconductor 42 is displayed in only one portion in the layout diagram of the transistor 20, and is connected to the oxide semiconductor 42 in the layout diagram of the transistor 40 with a dashed double-dotted line.

As illustrated in FIG. 5A and FIG. 5B, the wiring WWL, the wiring RWL, and the oxide semiconductor 22 are provided to overlap with each other and extend in the Y-axis direction. The wiring WBL and the wiring RBL are provided to extend in the X-axis direction. The conductor 30a is positioned at the intersection between the wiring RWL and the wiring RBL. The oxide semiconductor 42 is positioned at the intersection between the wiring WWL and the wiring WBL. In each memory cell 10, the conductor 30b is placed in a position of the oxide semiconductor 22 where neither the conductor 30a nor the oxide semiconductor 42 is formed.

When the memory cell 10 has the above-described layout, the oxide semiconductor 22 can be provided between the wiring RWL and the wiring WWL to overlap with them, and the oxide semiconductor 42, the conductor 30a, and the conductor 30b can be provided to overlap with the oxide semiconductor 22. Therefore, ideally, as illustrated in FIG. 5A and FIG. 5B, the area occupied by the memory cell 10 can be reduced to an area obtained by adding an alignment margin area to the area occupied by the oxide semiconductor 22. For example, in the case where the wiring RWL, the oxide semiconductor 22, and the wiring WWL are laid out side by side with the wiring RWL not overlapping with the oxide semiconductor 22, the area occupied by the memory cell 10 is probably increased to be approximately 1.5 times or more as large as that in the layout illustrated in FIG. 5A and FIG. 5B. Thus, with the structure illustrated in FIG. 5A and FIG. 5B, the memory device can be highly integrated.

Although the layout of the memory cell array of three rows and three columns is described above as an example, the memory device of the present invention is not limited thereto. The memory device of the present invention can have a structure including a memory cell array of m rows and n columns (m and n are each a natural number greater than or equal to 1).

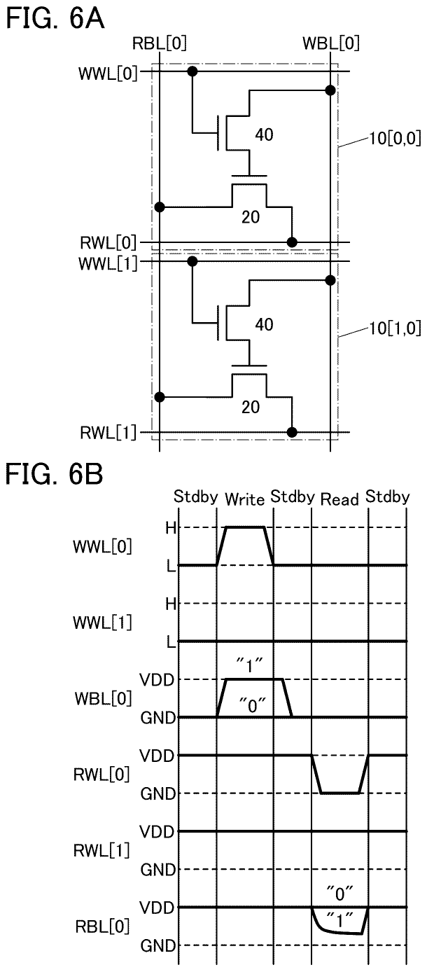

Next, an example of a method for driving the memory device illustrated in FIG. 5A and FIG. 5B is described with reference to FIG. 6A and FIG. 6B. Here, FIG. 6A is a circuit diagram corresponding to the memory cell 10[0,0] and the memory cell 10[1,0]. FIG. 6B is a timing chart of a circuit illustrated in FIG. 6A.

As illustrated in FIG. 6A, the memory cell 10[0,0] and the memory cell 10[1,0] each have a structure similar to that of the memory cell 10 illustrated in FIG. 1B. In the memory cell 10[0,0], the wiring WWL[0] is electrically connected to the gate electrode of the transistor 40, and a wiring RWL[0] is electrically connected to the other of the source electrode and the drain electrode of the transistor 20. In the memory cell 10[1,0], a wiring WWL[1] is electrically connected to the gate electrode of the transistor 40, and a wiring RWL[1] is electrically connected to the other of the source electrode and the drain electrode of the transistor 20. A wiring WBL[0] is electrically connected to one of the source electrode and the drain electrode of the transistor 40 in the memory cell 10[0,0] and the memory cell 10[1,0]. A wiring RBL[0] is electrically connected to one of the source electrode and the drain electrode of the transistor 20 in the memory cell 10[0,0] and the memory cell 10[1,0].

The timing chart in FIG. 6B shows an example of an operation of writing data to the memory cell 10[0,0] and an operation of reading the data written to the memory cell 10[0,0]. In FIG. 6B, Write denotes a data writing period, Read denotes a data reading period, and Stdby denotes a standby period. FIG. 6B shows the potentials of the wiring WWL[0], the wiring WWL[1], the wiring WBL[0], the wiring RWL[0], the wiring RWL[1], and the wiring RBL[0] in each period. A potential H shown in FIG. 6B is a potential at which the transistor 40 can be turned on, and a potential L is a potential at which the transistor 40 can be turned off. A potential VDD shown in FIG. 6B is a high power supply potential, and a potential GND is the ground potential (a low power supply potential).

First, writing of data of the memory cell 10[0,0] is described. In the writing period Write, the potential H is applied to the wiring WWL[0], the potential L is applied to the wiring WWL[1], and a potential corresponding to data “1” or data “0” is applied to the wiring WBL[0]. Here, a potential corresponding to the data “1” is the potential VDD, and a potential corresponding to the data “0” is the potential GND. Thus, the transistor 40 in the memory cell 10[0,0] is turned on, and a potential corresponding to the data “1” or the data “O” is applied to a storage node of the memory cell 10[0,0]. Meanwhile, since the transistor 40 in the memory cell 10[1,0] is in an off state, data is not written to the memory cell 10[1,0].

After the writing period Write ends, the potential L is applied to the wiring WWL[0] to turn off the transistor 40 in the memory cell 10[0,0]. At this time, since a potential corresponding to the data “1” or the data “0” is applied to the storage node of the memory cell 10[0,0], data with a potential corresponding to the data “1” or the data “0” can be written to the memory cell 10[0,0]. Furthermore, the transistor 40 is an OS transistor and has a low off-state current. Thus, the written data “1” or “0” can be retained for a long time. Note that the wiring WBL[0] is set at the potential GND after the wiring WWL[0] is set at the potential L. In the writing period Write, it is preferable that the source and the drain of the transistor 20 be set at the same potential to turn off the transistor 20. For example, the wiring RWL[0], the wiring RWL[1], and the wiring RBL[0] may be set at the potential VDD.

Next, reading of data from the memory cell 10[0,0] is described. Immediately before the reading period Read, the wiring RBL and a high power supply potential line are electrically disconnected so that the wiring RBL is brought into a floating state in a state where the wiring RBL is precharged with the potential VDD. In the reading period Read, the potential GND is applied to the wiring RWL[0], and the potential VDD is applied to the wiring RWL[1] continuously. Thus, in the case where the data “1” is retained in the storage node of the memory cell 10[0,0], the transistor 20 in the memory cell 10[0,0] is turned on, and the potential of the wiring RBL[0] becomes lower than VDD. Here, the potential of the wiring RBL[0] is higher than or equal to GND and lower than or equal to VDD-Vth. Here, Vth is the threshold voltage of the transistor 20. In the case where the data “0” is retained in the storage node of the memory cell 10[0,0], the transistor 20 in the memory cell 10[0,0] is kept in an off state and the potential VDD is also maintained in the wiring RBL[0]. Thus, the potential of the wiring RBL is changed by data retained in the memory cell 10[0,0]. A change in the potential of the wiring RBL is read out with a circuit electrically connected to the wiring RBL, whereby data reading can be performed. Meanwhile, since the transistor 20 in the memory cell 10[1,0] is in an off state regardless of the retained potential, data in the memory cell 10[1,0] is not read out.

After the reading period Read ends, the potential VDD is applied to the wiring RWL[0] and the wiring RBL[0]. Thus, the transistor 20 in the memory cell 10[0,0] is turned off regardless of the retained data. Note that in the reading period Read, the wiring WWL[0] and the wiring WWL[1] are set at the potential L and the wiring WBL[0] is set at the potential GND.

As described above, the writing operation and the reading operation can be performed in the memory device of this embodiment. Although the timing chart of the memory cell array of two rows and one column is described above as an example, the memory device of the present invention is not limited thereto. In the memory device of the present invention, the writing operation and the reading operation can be performed in a memory cell array of m rows and n columns (m and n are each a natural number greater than or equal to 1).

### [Transistor 40]

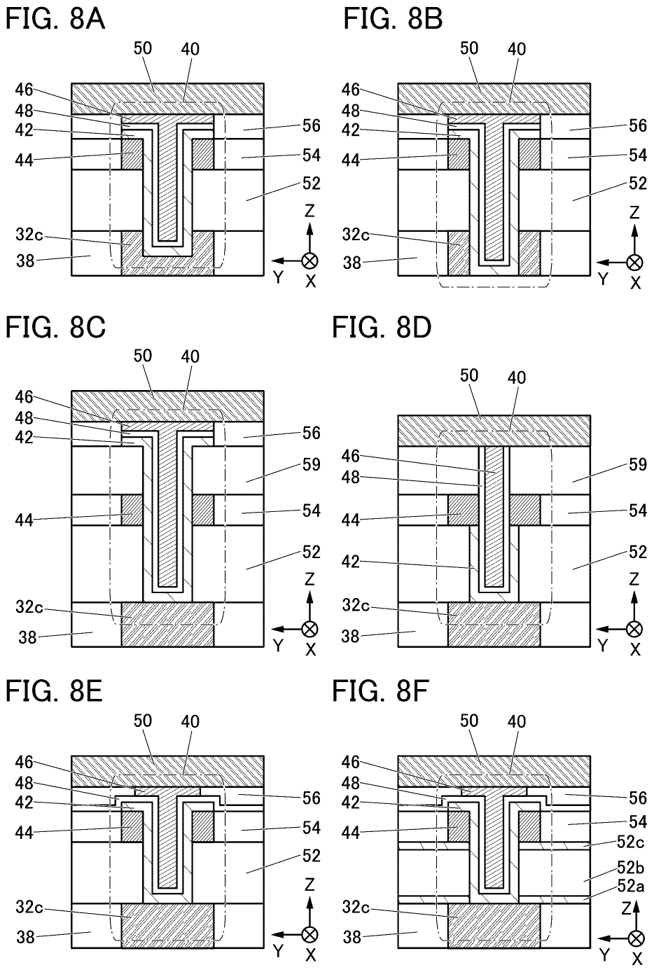

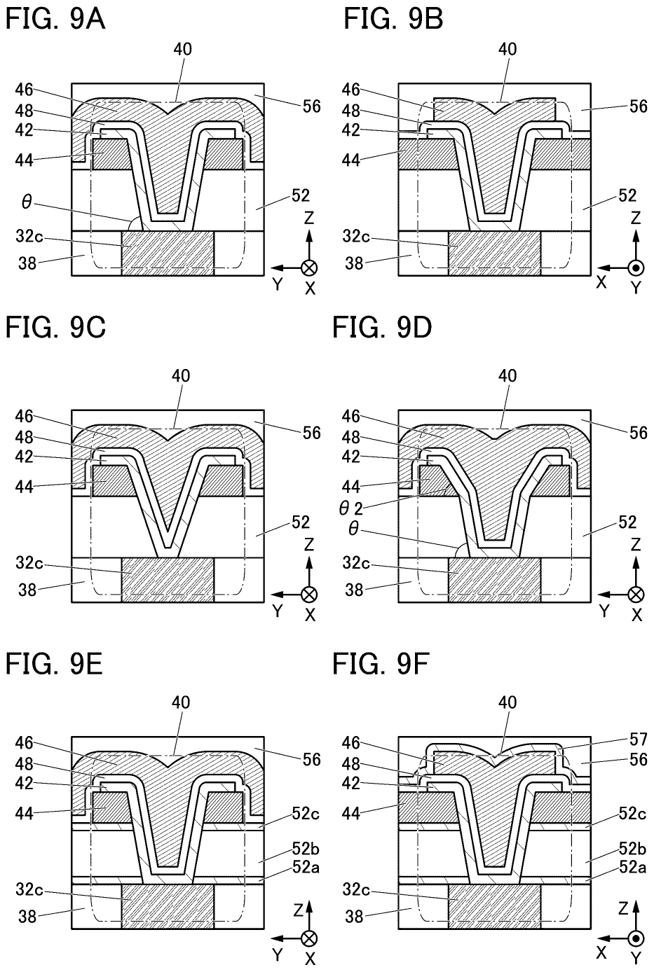

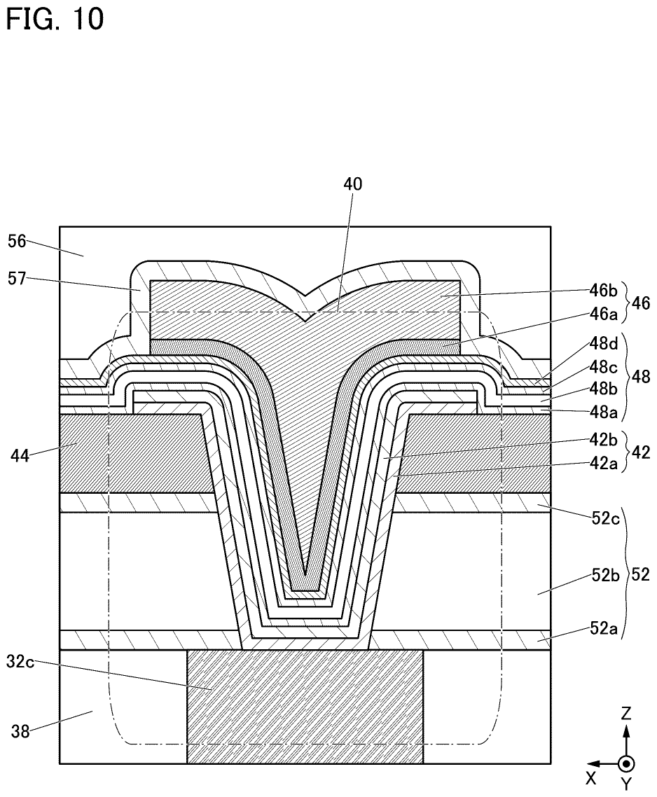

The structures of the transistor 40 are described below with reference to FIG. 1A to FIG. 3B and FIG. 8A to FIG. 10. Note that the transistor 40 illustrated in FIG. 8A to FIG. 10 is obtained by modifying part of the structure of the transistor 40 illustrated in FIG. 3A and FIG. 3B. Here, FIG. 8A to FIG. 9A and FIG. 9C to FIG. 9E are cross-sectional views corresponding to FIG. 3A. FIG. 9B, FIG. 9F, and FIG. 10 are cross-sectional views corresponding to FIG. 3B.

As illustrated in FIG. 1A and the like, the transistor 40 can have a structure including the conductor 32c, the conductor 44 over the insulator 52, the oxide semiconductor 42 over the conductor 32c, the insulator 48 provided in contact with a top surface of the oxide semiconductor 42, and the conductor 46 provided in contact with a top surface of the insulator 48. Here, the oxide semiconductor 42 is provided in contact with at least part of a top surface of the conductor 32c exposed in the opening of the insulator 52 and the conductor 44, part of a side surface of the insulator 52 and a side surface of the conductor 44 in the opening, and part of the top surface of the conductor 44.

Note that the conductor 50 over the conductor 46 is not necessarily provided. For example, as illustrated in FIG. 9A, FIG. 9B, and the like, part of the conductor 46 that is above the opening of the insulator 52 may extend in the Y-axis direction to function as a wiring. In this case, the part of the conductor 46 functions as the wiring WWL.

At least part of the components of the transistor 40 is placed in the opening of the insulator 52 and the conductor 44. Here, a bottom portion of the opening of the insulator 52 and the conductor 44 is the top surface of the conductor 32c, and a sidewall of the opening is the side surface of the insulator 52 and the side surface of the conductor 44.

As illustrated in FIG. 3A and FIG. 8A to FIG. 8F, the sidewall of the opening of the insulator 52 and the conductor 44 can have a shape perpendicular or substantially perpendicular to the top surface of the conductor 32c or the like. In that case, the opening of the insulator 52 and the conductor 44 has a cylindrical shape. Such a structure enables a reduction in the area occupied by the opening of the insulator 52 and the conductor 44 and high integration of the memory device.

As illustrated in FIG. 9A to FIG. 9F and FIG. 10, the sidewall of the opening of the insulator 52 and the conductor 44 may have a tapered shape. When the sidewall of the opening of the insulator 52 and the conductor 44 has a tapered shape, the coverage with the oxide semiconductor 42, the insulator 48, and the like can be improved, so that defects such as voids can be reduced. For example, the angle formed by the side surface of the insulator 52 and the top surface of the conductor 32c in the opening of the insulator 52 and the conductor 44 (the angle θ illustrated in FIG. 9A) is preferably greater than or equal to 45° and less than or equal to 90°. Alternatively, the angle is preferably greater than or equal to 45° and less than or equal to 75°. Alternatively, the angle is preferably greater than or equal to 45° and less than or equal to 65°.

Note that in this specification and the like, the tapered shape refers to a shape in which at least part of a side surface of a component is inclined to a substrate surface or a formation surface. For example, the tapered shape includes a region in which the angle formed by the inclined side surface and the substrate surface (hereinafter, the angle is sometimes referred to as a taper angle) is less than 90°. Note that the side surface of the component and the substrate surface are not necessarily completely flat and may have a substantially flat shape with a slight curvature or a substantially flat shape with slight unevenness.

The openings of the insulator 52 and the conductor 44 can have a circular shape in a plan view. Note that the shape of the openings of the insulator 52 and the conductor 44 is not limited thereto and may have a shape other than the circular shape in the plan view. For example, the openings of the insulator 52 and the conductor 44 may have a substantially circular shape such as an elliptical shape, a polygonal shape such as a quadrangular shape, or a polygonal shape such as a quadrangular shape with rounded corners in the plan view. In that case, the maximum width of the openings of the insulator 52 and the conductor 44 can be calculated as appropriate in accordance with the shape of the uppermost portion of the openings of the insulator 52 and the conductor 44. For example, in the case where the opening portion has a quadrangular shape in the plan view, the maximum width of the openings of the insulator 52 and the conductor 44 can be the length of a diagonal of the uppermost portion of the openings of the insulator 52 and the conductor 44. The maximum width of the opening of the conductor 44 may be larger than the maximum width of the opening of the insulator 52. In addition, the conductor 44 can be divided into a portion on the A3 side and a portion on the A4 side in the opening.

Note that in the case where the openings of the insulator 52 and the conductor 44 have a circular shape in the plan view and the sidewall of the opening has a tapered shape as illustrated in FIG. 9A to FIG. 9F and FIG. 10, the opening of the insulator 52 and the conductor 44 has a conical trapezoidal shape. Here, the area of an upper bottom surface of the conical trapezoidal shape (e.g., the opening portion provided in the conductor 44) is larger than the area of a lower bottom surface of the conical trapezoidal shape (the top surface of the conductor 32c exposed in the opening of the insulator 52). At this time, the maximum diameter of the opening of the insulator 52 and the conductor 44 can be calculated on the basis of the upper bottom surface of the conical trapezoidal shape.

Portions of the oxide semiconductor 42, the insulator 48, and the conductor 46 that are provided in the opening of the insulator 52 and the conductor 44 reflect the shape of the opening. Thus, the oxide semiconductor 42 is provided to cover the bottom portion and the sidewall of the opening of the insulator 52 and the conductor 44, the insulator 48 is provided to cover the oxide semiconductor 42, and the conductor 46 is provided to fill a depressed portion of the insulator 48 that reflects the shape of the opening of the insulator 52 and the conductor 44.

As illustrated in FIG. 9A and the like, a bottom portion of the conductor 46 positioned in the opening of the insulator 52 and the conductor 44 includes a flat region. Note that the bottom portion of the conductor 46 positioned in the opening of the insulator 52 and the conductor 44 does not include a flat region in some cases depending on the maximum width of the opening (the maximum diameter in the case where the opening is circular in the plan view), the thickness of the insulator 52, the thickness of the oxide semiconductor 42, the thickness of the insulator 48, and the like. For example, as illustrated in FIG. 9C, the bottom portion of the conductor 46 positioned in the opening of the insulator 52 and the conductor 44 has a needle-like shape in some cases.

Here, the needle-like shape refers to a shape tapering off toward the tip (at a position closer to the bottom portion of the conductor 46 positioned in the opening of the insulator 52 and the conductor 44). Note that the needle-like tip may have an acute angle or a downward-convex curved shape. Note that among the needle-like shapes, a shape whose tip has an acute angle may be referred to as a V shape.

A region of the conductor 46 positioned in the opening of the insulator 52 and the conductor 44, which faces the oxide semiconductor 42 with the insulator 48 therebetween, functions as a gate electrode. Thus, the conductor 46 that fills the opening of the insulator 52 and the conductor 44 and has a needle-like bottom portion may be referred to as a needle-like gate. The conductor 46 may be referred to as a needle-like gate in some cases even when having a bottom portion with a flat region as illustrated in FIG. 9A and FIG. 9B.

The present invention is not limited to the structure illustrated in FIG. 9A and the like in which the side surface of the conductor 44 in the opening of the insulator 52 and the conductor 44 is aligned with the side surface of the insulator 52 in the opening. For example, as illustrated in FIG. 9D, the side surface of the conductor 44 in the opening of the insulator 52 and the conductor 44 may be discontinuous from the side surface of the insulator 52 in the opening. The slope of the side surface of the conductor 44 in the opening of the insulator 52 and the conductor 44 may be different from the slope of the side surface of the insulator 52 in the opening.

Here, as illustrated in FIG. 9D, the angle formed by the side surface of the conductor 44 in the opening of the insulator 52 and the conductor 44 and the top surface of the conductor 32c is referred to as an angle θ2. At this time, the angle θ2 is preferably smaller than the angle θ. With such a structure, the coverage of the side surface of the conductor 44 in the opening of the insulator 52 and the conductor 44 with the oxide semiconductor 42 can be improved, so that defects such as voids can be reduced.

Here, in the transistor 40, at least part of a region of the oxide semiconductor 42 that is in contact with the conductor 44 (hereinafter referred to as a first low-resistance region) functions as one of a source region and a drain region. In the transistor 40, at least part of a region of the oxide semiconductor 42 that is in contact with the conductor 32c (hereinafter referred to as a second low-resistance region) functions as the other of the source region and the drain region. As illustrated in FIG. 2A and FIG. 2B, the conductor 44 is preferably in contact with all the outer circumference of the oxide semiconductor 42. Thus, the one of the source region and the drain region of the transistor 40 can be formed along all the outer circumference of a portion formed in the same layer as the conductor 44 in the oxide semiconductor 42.

In the oxide semiconductor 42, at least part of a region between the first low-resistance region and the second low-resistance region (hereinafter referred to as a high-resistance region) functions as a channel formation region. That is, the channel formation region of the transistor 40 is positioned in a region of the oxide semiconductor 42 between the conductor 32c and the conductor 44. It can be said that the channel formation region of the transistor 40 is positioned in a region of the oxide semiconductor 42 that is in contact with the insulator 52 or in the vicinity of the region.

The channel length of the transistor 40 is the distance between the source region and the drain region. In other words, the channel length of the transistor 40 is determined by the thickness of the insulator 52 over the conductor 32c. The channel length is the distance between an end portion of a region where the oxide semiconductor 42 and the conductor 32c are in contact with each other and an end portion of a region where the oxide semiconductor 42 and the conductor 44 are in contact with each other in a cross-sectional view. That is, the channel length corresponds to the length of the side surface of the insulator 52 on the opening side in the cross-sectional view.

In a conventional transistor, the channel length is determined by the light exposure limit of photolithography. However, in the present invention, the channel length can be determined by the thickness of the insulator 52 and the angle θ formed by the side surface of the insulator 52 in the opening of the insulator 52 and the top surface of the conductor 32c. Thus, the transistor 40 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 40 can have higher on-state current and improved frequency characteristics. This can increase the read speed and the write speed of the memory cell, thereby providing a memory device with high operating speed.

As described above, the channel formation region, the source region, and the drain region can be formed in the opening of the insulator 52 and the conductor 44. Thus, the area occupied by the transistor 40 can be reduced as compared with that occupied by a conventional transistor in which the channel formation region, the source region, and the drain region are provided separately on the X-Y plane. This allows high integration of the memory device, thereby increasing the memory capacity per unit area.

In the vicinity of the channel formation region, the oxide semiconductor 42, the insulator 48, and the conductor 46 are provided concentrically in the plan view. Thus, a side surface of the conductor 46 provided at the center faces a side surface of the oxide semiconductor 42 with the insulator 48 therebetween. That is, in the plan view, all the circumference of the oxide semiconductor 42 serves as the channel formation region. In that case, for example, the channel width of the transistor 40 is determined by the length of the outer circumference of the oxide semiconductor 42. In other words, the channel width of the transistor 40 is determined by the maximum width of the opening of the insulator 52 and the conductor 44 (the maximum diameter in the case where the opening is circular in the plan view). Thus, an increase in the maximum width of the opening of the insulator 52 and the conductor 44 can increase the channel width per unit area and the on-state current.

Note that the length of the outer circumference of the oxide semiconductor 42 can be derived from a region facing the conductor 44 or a position that is half the thickness of the insulator 52, for example. Note that the length of the circumference of the opening of the insulator 52 and the conductor 44 at an arbitrary position may be regarded as the channel width of the transistor 40 as necessary. For example, the length of the circumference at the lowest portion of the opening of the insulator 52 and the conductor 44 may be regarded as the channel width, or the length of the circumference at the uppermost portion of the opening of the insulator 52 and the conductor 44 may be regarded as the channel width.

In the case where the opening of the insulator 52 and the conductor 44 is formed by a photolithography method, the maximum width of the opening is determined by the light exposure limit of photolithography. The maximum width of the opening of the insulator 52 and the conductor 44 is determined by the thickness of each of the oxide semiconductor 42, the insulator 48, and the conductor 46 provided in the opening. The maximum width of the opening of the insulator 52 and the conductor 44 is preferably greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm, for example. Note that in the case where the opening of the insulator 52 and the conductor 44 is circular in the plan view, the maximum width of the opening corresponds to the diameter of the opening of the insulator 52 and the conductor 44.

In the memory cell 10, the channel length of the transistor 40 is preferably shorter than at least the channel width of the transistor 40. The channel length of the transistor 40 in one embodiment of the present invention is greater than or equal to 0.1 times and less than or equal to 0.99 times, preferably greater than or equal to 0.5 times and less than or equal to 0.8 times the channel width of the transistor 40. This structure enables a transistor with favorable electrical characteristics and high reliability.

In the case where the opening of the insulator 52 and the conductor 44 is formed to be circular in a plan view, the oxide semiconductor 42, the insulator 48, and the conductor 46 are formed concentrically. This makes the distance between the conductor 46 and the oxide semiconductor 42 substantially uniform, so that a gate electric field can be substantially uniformly applied to the oxide semiconductor 42.

It is preferable that the channel formation region of the transistor including an oxide semiconductor in a semiconductor layer include fewer oxygen vacancies or have a lower concentration of an impurity such as hydrogen, nitrogen, or a metal element than the source region and the drain region. In some cases, hydrogen in the vicinity of an oxygen vacancy forms a defect that is an oxygen vacancy into which hydrogen enters (hereinafter sometimes referred to as VoH), which generates an electron serving as a carrier. Therefore, it is preferable that VoH be also decreased in the channel formation region. Thus, the channel formation region of the transistor is a high-resistance region having a low carrier concentration. Thus, the channel formation region of the transistor can be regarded as being an i-type (intrinsic) or substantially i-type region.

The source region and the drain region of the transistor including an oxide semiconductor in a semiconductor layer include more oxygen vacancies, include more VoH, or have a higher concentration of an impurity such as hydrogen, nitrogen, or a metal element than the channel formation region, and thus are low-resistance regions with high carrier concentrations. In other words, the source region and the drain region of the transistor are n-type regions that have a higher carrier concentration and a lower resistance than the channel formation region.

As illustrated in FIG. 3A, FIG. 3B, and the like, part of the oxide semiconductor 42 is positioned outside the opening of the insulator 52 and the conductor 44, that is, over the conductor 44. Note that the present invention is not limited to the structure illustrated in FIG. 3A, FIG. 3B, and the like in which the oxide semiconductor 42 is divided in the Y-axis direction. For example, the oxide semiconductor 42 may be provided to extend in the Y-axis direction.

The present invention is not limited to the structure illustrated in FIG. 3A in which a side end portion of the oxide semiconductor 42 and a side end portion of the conductor 44 are aligned with each other. For example, as illustrated in FIG. 9A, the side end portion of the oxide semiconductor 42 may be positioned inward from the side end portion of the conductor 44. Alternatively, the side end portion of the oxide semiconductor 42 may be positioned outward from the side end portion of the conductor 44.

The band gap of the metal oxide used as the oxide semiconductor 42 is preferably larger than that of silicon (typically 1.1 eV), further preferably larger than or equal to 2 eV, still further preferably larger than or equal to 2.5 eV, yet still further preferably larger than or equal to 3.0 eV. When a metal oxide having a larger band gap than silicon is used as the oxide semiconductor 42, the off-state current of the transistor can be reduced. Using the transistor having a low off-state current in the memory cell enables long-period retention of stored contents. In other words, such a memory device does not require refresh operation or has an extremely low frequency of refresh operation, which leads to a sufficient reduction in power consumption of the memory device. The frequency of refresh operation in a general DRAM needs to be approximately once per 60 msec, whereas the frequency of refresh operation in the memory device of one embodiment of the present invention can be approximately once per 10 sec, which is greater than or equal to 10 times or greater than or equal to 100 times that of the general DRAM. In the memory device of one embodiment of the present invention, the frequency of refresh operation can be once per period more than or equal to 1 sec and less than or equal to 100 sec, preferably once per period more than or equal to 5 sec and less than or equal to 50 sec.

As the oxide semiconductor 42, a single layer or stacked layers including any of the metal oxides described in the later-described section [Metal oxide] can be used.

Specifically, as the oxide semiconductor 42, a metal oxide with a composition of In:M:Zn=1:3:2 [atomic ratio] or in the neighborhood thereof, a composition of In:M:Zn=1:3:4 [atomic ratio] or in the neighborhood thereof, a composition of In:M:Zn=1:1:0.5 [atomic ratio] or in the neighborhood thereof, a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of ±30% of an intended atomic ratio. It is preferable to use gallium as the element M.

When the metal oxide is deposited by a sputtering method, the above atomic ratio is not limited to the atomic ratio of the deposited metal oxide and may be the atomic ratio of a sputtering target used for depositing the metal oxide.

As an analysis method of the composition of the metal oxide used for the oxide semiconductor 42, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, any of these methods may be combined with each other for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A sputtering method or an atomic layer deposition (ALD) method can be suitably used to form the metal oxide. Note that in the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The oxide semiconductor 42 preferably has crystallinity. It is particularly preferable to use a CAAC-OS (c-axis aligned crystalline oxide semiconductor) as the oxide semiconductor 42. The crystallinity of the oxide semiconductor 42 can be improved by, for example, depositing the oxide semiconductor 42 by a sputtering method involving substrate heating or by performing microwave treatment on the oxide semiconductor 42 in an oxygen-containing atmosphere.

The CAAC-OS preferably includes a plurality of layered crystal regions and the c-axis is preferably aligned in a normal direction of a surface where the CAAC-OS is deposited. For example, the oxide semiconductor 42 preferably includes layered crystals that are substantially parallel to the sidewall of the opening of the insulator 52 and the conductor 44, particularly the side surface of the insulator 52. With this structure, the layered crystals of the oxide semiconductor 42 are formed substantially parallel to the channel length direction of the transistor 40, so that the on-state current of the transistor can be increased.

The CAAC-OS is a metal oxide having a dense structure with high crystallinity and small amounts of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as a CAAC-OS, is used for the oxide semiconductor 42, oxygen extraction from the oxide semiconductor 42 by the source electrode or the drain electrode can be inhibited. This can reduce oxygen extraction from the oxide semiconductor 42 even when heat treatment is performed; thus, the transistor 40 is stable with respect to high temperatures in the manufacturing process (what is called thermal budget).

The crystallinity of the oxide semiconductor 42 can be analyzed with X-ray diffraction (XRD), a transmission electron microscope (TEM), or electron diffraction (ED), for example. Alternatively, any of these methods may be combined with each other for the analysis.

Although the oxide semiconductor 42 has a single-layer structure in FIG. 3A and the like, the present invention is not limited thereto. The oxide semiconductor 42 may have a stacked-layer structure of a plurality of oxide layers with different chemical compositions. For example, a structure in which a plurality of kinds of metal oxides selected from the above-described metal oxides are stacked as appropriate may be used.

For example, as illustrated in FIG. 10, the oxide semiconductor 42 may have a stacked-layer structure of an oxide semiconductor 42a and an oxide semiconductor 42b over the oxide semiconductor 42a.

The conductivity of a material used for the oxide semiconductor 42a is preferably different from the conductivity of a material used for the oxide semiconductor 42b.

For example, a material having higher conductivity than that for the oxide semiconductor 42b can be used for the oxide semiconductor 42a. When a material having high conductivity is used for the oxide semiconductor 42a, which is in contact with the conductor 32c and the conductor 44 functioning as a source electrode and a drain electrode, the contact resistance between the oxide semiconductor 42 and the conductor 32c and the contact resistance between the oxide semiconductor 42 and the conductor 44 can be reduced, so that the transistor can have a high on-state current.

Here, in the case where a material having high conductivity is used for the oxide semiconductor 42b provided on the conductor 46 side functioning as the gate electrode, the threshold voltage of the transistor is shifted and a drain current flowing when the gate voltage is 0 V (hereinafter also referred to as a cutoff current) becomes large in some cases. Specifically, in the case of being an n-channel transistor, the transistor 40 might have a low threshold voltage. Thus, a material having lower conductivity than that for the oxide semiconductor 42a is preferably used for the oxide semiconductor 42b. This enables the transistor 40 to have a high threshold voltage and a low cut-off current in the case where the transistor 40 is an n-channel transistor. Note that characteristics with a low cut-off current are sometimes referred to as normally-off characteristics.

When the oxide semiconductor 42 has a stacked-layer structure and a material having higher conductivity than that for the oxide semiconductor 42b is used for the oxide semiconductor 42a as described above, the transistor can have normally-off characteristics and a high on-state current. Consequently, the semiconductor device can have both low power consumption and high performance.

Note that the carrier concentration of the oxide semiconductor 42a is preferably higher than that of the oxide semiconductor 42b. Increasing the carrier concentration of the oxide semiconductor 42a results in higher conductivity thereof, which can reduce the contact resistance between the oxide semiconductor 42 and the conductor 32c and the contact resistance between the oxide semiconductor 42 and the conductor 44, so that the transistor can have a high on-state current. When the carrier concentration of the oxide semiconductor 42b is reduced, the conductivity thereof is reduced, so that the transistor can have normally-off characteristics.

One embodiment of the present invention is not limited to the example described here in which a material having higher conductivity than that for the oxide semiconductor 42b is used for the oxide semiconductor 42a. A material having lower conductivity than that for the oxide semiconductor 42b may be used for the oxide semiconductor 42a. The carrier concentration of the oxide semiconductor 42a can be lower than that of the oxide semiconductor 42b.

The band gap of a first metal oxide used for the oxide semiconductor 42a is preferably different from the band gap of a second metal oxide used for the oxide semiconductor 42b. For example, the difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the oxide semiconductor 42a can be smaller than that of the second metal oxide used for the oxide semiconductor 42b. This can reduce the contact resistance between the oxide semiconductor 42 and the conductor 32c and the contact resistance between the oxide semiconductor 42 and the conductor 44, so that the transistor can have a high on-state current. In addition, the transistor 40 can have a high threshold voltage in the case of being an n-channel transistor, and can be a normally-off transistor.

One embodiment of the present invention is not limited to the example described here in which the band gap of the first metal oxide is smaller than that of the second metal oxide. The band gap of the first metal oxide can be larger than that of the second metal oxide.

As described above, the band gap of the first metal oxide used for the oxide semiconductor 42a can be smaller than the band gap of the second metal oxide used for the oxide semiconductor 42b. The composition of the first metal oxide is preferably different from that of the second metal oxide. When the compositions of the first metal oxide and the second metal oxide are different from each other, the band gap can be controlled. For example, the content percentage of the element M in the first metal oxide is preferably lower than that of the element M in the second metal oxide. Specifically, in the case where the first metal oxide and the second metal oxide are each an In-M-Zn oxide, the first metal oxide can have a composition of In:M:Zn=1:1:1 [atomic ratio] or in the neighborhood thereof, and the second metal oxide can have a composition of In:M:Zn=1:3:2 [atomic ratio] or in the neighborhood thereof. It is particularly preferable to use one or more of gallium, aluminum, and tin as the element M.

The first metal oxide may have a composition not including the element M. For example, the first metal oxide used for the oxide semiconductor 42a can be an In—Zn oxide, and the second metal oxide used for the oxide semiconductor 42b can be an In-M-Zn oxide. Specifically, the first metal oxide can be an In—Zn oxide, and the second metal oxide can be an In—Ga—Zn oxide. More specifically, the first metal oxide can have a composition of In:Zn=1:1 [atomic ratio] or in the neighborhood thereof or a composition of In:Zn=4:1 [atomic ratio] or in the neighborhood thereof and the second metal oxide can have a composition of In:Ga:Zn=1:1:1 [atomic ratio] or in the neighborhood thereof.

One embodiment of the present invention is not limited to the example described here in which the content percentage of the element M in the first metal oxide is lower than that of the element M in the second metal oxide. The content percentage of the element M in the first metal oxide may be higher than that of the element M in the second metal oxide. As long as the compositions of the first metal oxide and the second metal oxide are different from each other, the content percentages of elements other than the element M may be different from each other.

The thickness of the oxide semiconductor 42 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The thicknesses of the layers included in the oxide semiconductor 42 (here, the oxide semiconductor 42a and the oxide semiconductor 42b) are determined in such a manner that the thickness of the oxide semiconductor 42 is within the above-described range. The thickness of the oxide semiconductor 42a can be determined in such a manner that the contact resistance between the oxide semiconductor 42a and the conductor 32c and the contact resistance between the oxide semiconductor 42a and the conductor 44 are within required ranges. The thickness of the oxide semiconductor 42b can be determined in such a manner that the threshold voltage of the transistor is within a required range. Note that the thickness of the oxide semiconductor 42a may be the same as or different from the thickness of the oxide semiconductor 42b.

The present invention is not limited to the structure illustrated in FIG. 10 in which the oxide semiconductor 42 has a stacked-layer structure of two layers of the oxide semiconductor 42a and the oxide semiconductor 42b. The oxide semiconductor 42 may have a stacked-layer structure of three or more layers.

In the case where the oxide semiconductor 42 has a stacked-layer structure of a first layer to a third layer from the conductor 32c side, the following structure may be used for example: a metal oxide with a composition of In:Ga:Zn=1:1:1 [atomic ratio] or in the neighborhood thereof is used for the first layer, a metal oxide with a composition of In:Zn=1:1 [atomic ratio] or in the neighborhood thereof or a composition of In:Zn=4:1 [atomic ratio] or in the neighborhood thereof is used for the second layer, and a metal oxide with a composition of In:Ga:Zn=1:1:1 [atomic ratio] or in the neighborhood thereof is used for the third layer. Note that for each of the first layer and the third layer, a metal oxide with a composition of In:Ga:Zn=1:3:2 [atomic ratio] or in the neighborhood thereof or a metal oxide with a composition of In:Ga:Zn=1:3:4 [atomic ratio] or in the neighborhood thereof may be used instead of a metal oxide with a composition of In:Ga:Zn=1:1:1 [atomic ratio] or in the neighborhood thereof. For example, the thickness of each of the first layer and the third layer can be approximately 1 nm and the thickness of the second layer can be approximately 3 nm to 5 nm.

Here, the energy of the conduction band minimum of each of the first layer and the third layer is preferably higher than the energy of the conduction band minimum of the second layer. In other words, the electron affinity of each of the first layer and the third layer is preferably smaller than the electron affinity of the second layer. For example, the difference between the energy (electron affinity) of the conduction band minimum of each of the first layer and the third layer and the energy (electron affinity) of the conduction band minimum of the second layer is preferably greater than or equal to 0.05 eV and less than 0.3 eV.

Here, the electron affinity or the energy level of conduction band minimum Ec can be obtained from an energy gap Eg and an ionization potential Ip, which is the difference between a vacuum level and the energy of valence band maximum Ev. The ionization potential Ip can be measured using, for example, an ultraviolet photoelectron spectroscopy (UPS) apparatus. The energy gap Eg can be measured using, for example, a spectroscopic ellipsometer.

With the above structure, the on-state current of the transistor 200 can be increased, and the transistor can have high reliability with small variations.

For the insulator 48, a single layer or stacked layers of any of the insulators described in the later-described section [Insulator] can be used. For the insulator 48, silicon oxide or silicon oxynitride can be used, for example. Silicon oxide and silicon oxynitride are preferable because they are thermally stable.

For the insulator 48, any of the materials with high relative permittivity, that is, high-k materials, described in the later-described section [Insulator] may be used. For example, hafnium oxide or aluminum oxide may be used.

The thickness of the insulator 48 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulator 48 preferably has a region with the above-described thickness.

The concentration of impurities such as water and hydrogen in the insulator 48 is preferably reduced. This can inhibit entry of impurities such as water and hydrogen into the channel formation region of the oxide semiconductor 42.

Part of the insulator 48 is positioned outside the opening of the insulator 52 and the conductor 44, that is, over the conductor 44 and the insulator 52. Here, the insulator 48 preferably covers the side end portion of the oxide semiconductor 42 as illustrated in FIG. 8E, FIG. 8F, FIG. 9A to FIG. 9F, and FIG. 10. This can prevent a short circuit between the conductor 46 and the oxide semiconductor 42. The insulator 48 preferably covers the side end portion of the conductor 44 as illustrated in FIG. 9A. This can prevent a short circuit between the conductor 46 and the conductor 44.

Although the insulator 48 has a single-layer structure in FIG. 3A and the like, the present invention is not limited thereto. The insulator 48 may have a stacked-layer structure.

For example, as illustrated in FIG. 10, the insulator 48 may have a stacked-layer structure of an insulator 48a, an insulator 48b over the insulator 48a, an insulator 48c over the insulator 48b, and an insulator 48d over the insulator 48c.

For the insulator 48b, any of the materials with low relative permittivity described in the later-described section [Insulator] is preferably used. In particular, silicon oxide and silicon oxynitride are preferable because they are thermally stable. In that case, the insulator 48b contains at least oxygen and silicon. With such a structure, parasitic capacitance between the conductor 46 and the conductor 44 can be reduced. Furthermore, the concentration of impurities such as water and hydrogen in the insulator 48b is preferably reduced.

For the insulator 48a, any of the insulators having a barrier property against oxygen described in the later-described section [Insulator] is preferably used. The insulator 48a preferably has a higher barrier property against oxygen than at least the insulator 48b has. The insulator 48a includes a region in contact with the oxide semiconductor 42. When the insulator 48a has a barrier property against oxygen, release of oxygen from the oxide semiconductor 42 at the time of performing heat treatment or the like can be inhibited. This can inhibit formation of oxygen vacancies in the oxide semiconductor 42. Accordingly, the transistor 40 can have favorable electrical characteristics and higher reliability. As the insulator 48a, aluminum oxide is used, for instance. In that case, the insulator 48a contains at least oxygen and aluminum.

For the insulator 48d, any of the insulators having a barrier property against hydrogen described in the later-described section [Insulator] is preferably used. The insulator 48d preferably has a higher barrier property against hydrogen than at least the insulator 48b has. This can inhibit diffusion of impurities contained in the conductor 46 into the oxide semiconductor 42. Silicon nitride is suitable for the insulator 48d because of its high hydrogen barrier property. In that case, the insulator 48d contains at least nitrogen and silicon.

The insulator 48d may further have a barrier property against oxygen. The insulator 48d is provided between the insulator 48b and the conductor 46. Thus, diffusion of oxygen contained in the insulator 48b into the conductor 46 can be prevented, so that oxidation of the conductor 46 can be inhibited. It is also possible to inhibit a reduction in the amount of oxygen supplied to the channel formation region.

The insulator 48c is preferably provided between the insulator 48b and the insulator 48d. For the insulator 48c, any of the insulators having a function of capturing or fixing hydrogen described in the later-described section [Insulator] is preferably used. The insulator 48c preferably has a higher function of capturing or fixing hydrogen than at least the insulator 48b has. When the insulator 48c is provided, hydrogen contained in the oxide semiconductor 42 can be captured or fixed more effectively. Thus, the hydrogen concentration in the oxide semiconductor 42 can be lowered. As the insulator 48c, for example, hafnium oxide is used. In that case, the insulator 48c contains at least oxygen and hafnium. The insulator 48c may have an amorphous structure.

The thicknesses of the insulator 48a to the insulator 48d are preferably small for miniaturization of the transistor 40, and are preferably within the above-described ranges. Typically, the thicknesses of the insulator 48a, the insulator 48b, the insulator 48c, and the insulator 48d are 1 nm, 2 nm, 2 nm, and 1 nm, respectively. This structure enables the transistor 40 to have favorable electrical characteristics even when the transistor 40 is miniaturized or highly integrated.

The present invention is not limited to the structure illustrated in FIG. 10 in which the insulator 48 has a four-layer stacked structure of the insulator 48a to the insulator 48d. The insulator 48 may have a stacked-layer structure of two layers, three layers, or five or more layers. In that case, the layers included in the insulator 48 are selected as appropriate from the insulator 48a to the insulator 48d.

For the conductor 46, a single layer or stacked layers of any of the conductors described in the later-described section [Conductor] can be used. For the conductor 46, a conductive material with high conductivity such as tungsten can be used, for example.

For the conductor 46, a conductive material that is less likely to be oxidized, a conductive material having a function of inhibiting diffusion of oxygen, or the like is preferably used. Examples of the conductive material include a conductive material containing nitrogen (e.g., titanium nitride or tantalum nitride) and a conductive material containing oxygen (e.g., ruthenium oxide). This can inhibit a decrease in the conductivity of the conductor 46.

The conductor 46 may have a stacked-layer structure. For example, as illustrated in FIG. 10, the conductor 46 may have a stacked-layer structure of a conductor 46a and a conductor 46b over the conductor 46a. A conductive material that is less likely to be oxidized, a conductive material having a function of inhibiting diffusion of oxygen, or the like is preferably used for the conductor 46a. A conductive material having higher conductivity than that of the conductor 46a is preferably used for the conductor 46b. For example, titanium nitride may be used for the conductor 46a, and tungsten may be used for the conductor 46b, for example. When tungsten is stacked in this manner, the conductor 46 can have improved conductivity and can serve well as the wiring WWL.

The present invention is not limited to the structure illustrated in FIG. 10 in which the conductor 46 has a stacked-layer structure of two layers of the conductor 46a and the conductor 46b. The conductor 46 may have a stacked-layer structure of three or more layers.

Although the conductor 46 is provided to fill the opening of the insulator 52 and the conductor 44 in FIG. 9A and the like, the present invention is not limited thereto. For example, a depressed portion reflecting the shape of the opening of the insulator 52 and the conductor 44 is formed in a center portion of the conductor 46 and part of the depressed portion is positioned in the opening of the insulator 52 and the conductor 44 in some cases. In that case, the depressed portion may be filled with an inorganic insulating material or the like.

As illustrated in FIG. 8A to FIG. 9F and the like, part of the conductor 46 can be positioned outside the opening of the insulator 52 and the conductor 44, that is, over the conductor 44 and the insulator 52. In that case, a side end portion of the conductor 46 is preferably positioned inward from the side end portion of the oxide semiconductor 42 as illustrated in FIG. 8E, FIG. 9A, and the like. This can prevent a short circuit between the conductor 46 and the oxide semiconductor 42. Note that the side end portion of the conductor 46 may be aligned with the side end portion of the oxide semiconductor 42 or positioned outward from the side end portion of the oxide semiconductor 42.

As illustrated in FIG. 3A and the like, part of the conductor 46, part of the insulator 48, and part of the oxide semiconductor 42 can be positioned outside the opening of the insulator 52 and the conductor 44, that is, over the conductor 44 and the insulator 52. Here, the part of the conductor 46, the part of the insulator 48, and the part of the oxide semiconductor 42 are preferably provided to be embedded in the insulator 56. In that case, the top surface of the conductor 46 and the top surface of the insulator 56 are preferably level with each other. Note that without limitation to this structure, as illustrated in FIG. 9A and the like, the insulator 56 may be provided to cover the conductor 46.

As illustrated in FIG. 3A and the like, the conductor 50 may be provided in contact with the top surface of the conductor 46. For the conductor 50, a single layer or stacked layers of any of the conductors described in the later-described section [Conductor] can be used. For the conductor 50, a conductive material with high conductivity such as tungsten can be used, for example.

In the case where the conductor 50 is provided, the conductor 50 functions as the wiring WWL and thus is provided to extend in the Y-axis direction, for example. Here, the conductor 46 is formed into an island shape in a plan view. Note that in this specification and the like, an island shape refers to a state where two or more layers are formed using the same material in the same step and then are physically separated from each other in a plan view.

As illustrated in FIG. 3B or the like, the conductor 50 is preferably provided to be embedded in the insulator 58. In that case, the top surface of the conductor 50 and the top surface of the insulator 58 are preferably level with each other.

Although a side end portion of the conductor 50 is aligned with the side end portion of the conductor 46 in FIG. 3B and the like, the present invention is not limited thereto. The side end portion of the conductor 50 may be positioned outward from the side end portion of the conductor 46. Alternatively, the side end portion of the conductor 50 may be positioned inward from the side end portion of the conductor 46.

As illustrated in FIG. 3A and the like, the conductor 32c is provided in contact with the top surface of the conductor 30c. The conductor 32c is formed into an island shape in a plan view. The conductor 32c is preferably provided to be embedded in the insulator 38. The conductor 32a, which is formed in the same layer as the conductor 32c, is also preferably provided to be embedded in the insulator 38. In that case, the top surfaces of the conductor 32a and the conductor 32c are preferably level with the top surface of the insulator 38. Note that the present invention is not limited thereto, and the structure without the insulator 38 may be employed. In that case, the conductor 32a and the conductor 32c are covered with the insulator 52.

For the conductor 32a to the conductor 32c, a single layer or stacked layers of any of the conductors described in the later-described section [Conductor] can be used. For the conductor 32a to the conductor 32c, a conductive material that is less likely to be oxidized, a conductive material having a function of inhibiting diffusion of oxygen, or the like is preferably used. For example, titanium nitride, tantalum nitride, or the like can be used. Such a structure can inhibit excessive oxidation of the conductor 32c due to the oxide semiconductor 42. Alternatively, a metal oxide may be used for the conductor 32c. For example, indium tin oxide to which silicon is added may be used. Alternatively, indium tin oxide to which silicon is added may be stacked over tungsten, for example. When tungsten is stacked in this manner, the conductivity of the conductor 32c can be improved.

The present invention is not limited to the structure illustrated in FIG. 3A and the like in which the top surface of the conductor 32c is planarized. For example, as illustrated in FIG. 8A, a depressed portion overlapping with the opening of the insulator 52 and the conductor 44 may be formed on the top surface of the conductor 32c. With the structure in which at least parts of the oxide semiconductor 42, the insulator 48, and the conductor 46 are formed to fill the depressed portion, the gate electric field of the conductor 46 can be easily applied to a portion of the oxide semiconductor 42 close to the conductor 32c.

For another example, as illustrated in FIG. 8B, an opening overlapping with the opening of the insulator 52 and the conductor 44 may be formed in the conductor 32c. The opening is formed to penetrate the conductor 32c, and in the opening, the top surface of the conductor 30c is exposed, that is, the bottom surface of the oxide semiconductor 42 is in contact with the top surface of the conductor 30c. With such a structure, the gate electric field of the conductor 46 can be easily applied to the portion of the oxide semiconductor 42 close to the conductor 32c.

For the conductor 44, a single layer or stacked layers of any of the conductors described in the later-described section [Conductor] can be used. For the conductor 44, a conductive material with high conductivity such as tungsten can be used, for example.

For the conductor 44 as well as the conductor 46, a conductive material that is less likely to be oxidized, a conductive material having a function of inhibiting diffusion of oxygen, or the like is preferably used. For example, titanium nitride, tantalum nitride, or the like can be used. Such a structure can inhibit excessive oxidation of the conductor 44 due to the oxide semiconductor 42.

Alternatively, a metal oxide may be used for the conductor 44. For example, indium tin oxide to which silicon is added may be used. Alternatively, indium tin oxide to which silicon is added may be stacked over tungsten, for example. When tungsten is stacked in this manner, the conductor 44 can have improved conductivity and can serve well as the wiring WBL.

When the oxide semiconductor 42 and the conductor 32c are in contact with each other, a metal compound or oxygen vacancies are formed, so that the resistance of the second low-resistance region in the oxide semiconductor 42 is reduced. The reduction in the resistance of the oxide semiconductor 42 in contact with the conductor 32c can reduce the contact resistance between the oxide semiconductor 42 and the conductor 32c. Similarly, when the oxide semiconductor 42 and the conductor 44 are in contact with each other, the resistance of the first low-resistance region in the oxide semiconductor 42 is reduced. Accordingly, the contact resistance between the oxide semiconductor 42 and the conductor 44 can be reduced.

As illustrated in FIG. 3A and the like, the conductor 44 may be provided to be embedded in the insulator 54. In that case, the top surface of the conductor 44 and the top surface of the insulator 54 are preferably level with each other. With such a structure, the physical distance from the conductor 46 to the conductor 44 (specifically, the side end portion of the conductor 44) can be increased, so that a short circuit between the conductor 46 and the conductor 44 can be prevented. Note that the present invention is not limited thereto, and the structure without the insulator 54 may be employed as illustrated in FIG. 9A and the like.

As illustrated in FIG. 8C, an insulator 59 may be provided between the conductor 44 and the insulator 56. In that case, unlike in the structure illustrated in FIG. 3A and the like, the oxide semiconductor 42 is not in contact with the top surface of the conductor 44.

It is also possible to employ the structure illustrated in FIG. 8D in which the top surface of the oxide semiconductor 42 and a top surface of the insulator 52 are level with each other in the opening of the insulator 59, the conductor 44, and the insulator 52. In this structure, the top surface of the oxide semiconductor 42 is in contact with a bottom surface of the conductor 44. Here, the top surfaces of the insulator 48 and the conductor 46 are preferably level with the top surface of the insulator 59. In this structure, the top surface of the conductor 46 is in contact with a bottom surface of the conductor 50. With such a structure, the oxide semiconductor 42, the insulator 48, and the conductor 46 are formed only in the opening of the insulator 59, the conductor 44, and the insulator 52; thus, a step of processing the oxide semiconductor 42, the insulator 48, and the conductor 46 by a lithography method is not necessary.

The insulator 38, the insulator 52, the insulator 54, the insulator 59, the insulator 56, and the insulator 58 function as interlayer films and thus preferably have low relative permittivity. When a material with low relative permittivity is used for an interlayer film, parasitic capacitance generated between wirings can be reduced. As the insulator 38, the insulator 52, the insulator 54, the insulator 59, the insulator 56, and the insulator 58, a single layer or stacked layers of any of insulators each containing a material with low relative permittivity described in the later-described section [Insulator] can be used. Silicon oxide and silicon oxynitride are preferable because they are thermally stable.

The concentration of impurities such as water and hydrogen in the insulator 38, the insulator 52, the insulator 54, the insulator 59, the insulator 56, and the insulator 58 is preferably reduced. This can inhibit entry of impurities such as water and hydrogen into the channel formation region of the oxide semiconductor 42.

As the insulator 52 placed in the vicinity of the channel formation region, an insulator containing oxygen that is released by heating (hereinafter, sometimes referred to as excess oxygen) is preferably used. By performing heat treatment on the insulator 52 containing excess oxygen, oxygen can be supplied from the insulator 52 to the channel formation region of the oxide semiconductor 42 and oxygen vacancies and VoH can be reduced. Accordingly, the transistor 40 can have stable electrical characteristics and higher reliability.

Although the insulator 52 has a single-layer structure in FIG. 3A and the like, the present invention is not limited thereto. The insulator 52 may have a stacked-layer structure.

For example, as illustrated in FIG. 8F, FIG. 9E, FIG. 9F, and FIG. 10, the insulator 52 may have a stacked-layer structure of an insulator 52a, an insulator 52b over the insulator 52a, and an insulator 52c over the insulator 52b.

An insulator containing oxygen is preferably used as the insulator 52b. The insulator 52b preferably includes a region having a higher oxygen content than at least one of the insulator 52a and the insulator 52c. In particular, the insulator 52b preferably includes a region having a higher oxygen content than each of the insulator 52a and the insulator 52c. When the oxygen content of the insulator 52b is increased, an i-type region can be easily formed in a region of the oxide semiconductor 42 that is in contact with the insulator 52b and in the vicinity of the region.

It is further preferable that a film from which oxygen is released by heating be used as the insulator 52b. When the insulator 52b releases oxygen by being heated during the manufacturing process of the transistor 40, the oxygen can be supplied to the oxide semiconductor 42. Supply of oxygen from the insulator 52b to the oxide semiconductor 42, particularly to the channel formation region of the oxide semiconductor 42, can reduce oxygen vacancies and VoH in the oxide semiconductor 42, so that the transistor can have favorable electrical characteristics and high reliability.

For example, oxygen can be supplied to the insulator 52b when heat treatment in an oxygen-containing atmosphere or plasma treatment in an oxygen-containing atmosphere is performed. Alternatively, an oxide film may be formed over a top surface of the insulator 52b by a sputtering method in an oxygen atmosphere to supply oxygen. After that, the oxide film may be removed.

The insulator 52b is preferably formed by a deposition method such as a sputtering method or a plasma-enhanced chemical vapor deposition (PECVD) method. In particular, a film is formed by a sputtering method as a deposition method that does not use a hydrogen gas as a deposition gas, so that a film with an extremely low hydrogen content can be formed. Thus, supply of hydrogen to the oxide semiconductor 42 is inhibited and the electrical characteristics of the transistor 40 can be stabilized.

In the case where the channel length of the transistor 40 is short, oxygen vacancies and VoH in the channel formation region particularly greatly affect the electrical characteristics and reliability of the transistor 40. Supplying oxygen from the insulator 52b to the oxide semiconductor 42 can inhibit oxygen vacancies and VoH from increasing at least in a region of the oxide semiconductor 42 that is in contact with the insulator 52b. Accordingly, the transistor with a short channel length can have favorable electrical characteristics and high reliability.

For each of the insulator 52a and the insulator 52c, any of the insulators having a barrier property against oxygen described in the later-described section [Insulator] is preferably used. Each of the insulator 52a and the insulator 52c preferably has a higher barrier property against oxygen than at least the insulator 52b has. Accordingly, oxygen contained in the insulator 52b can be inhibited from diffusing to the substrate side through the insulator 52a and to the insulator 56 side through the insulator 52c by heating. In other words, when the insulator 52a and the insulator 52c that do not easily allow diffusion of oxygen are provided above and below the insulator 52b, oxygen contained in the insulator 52b can be enclosed. Thus, oxygen can be effectively supplied to the oxide semiconductor 42.

The conductor 32c and the conductor 44 are oxidized by oxygen contained in the insulator 52b and have high resistance in some cases. Providing the insulator 52a between the insulator 52b and the conductor 32c can inhibit the conductor 32c from being oxidized and having high resistance. Furthermore, providing the insulator 52c between the insulator 52b and the conductor 44 can inhibit the conductor 44 from being oxidized and having high resistance. Along with this, the amount of oxygen supplied from the insulator 52b to the oxide semiconductor 42 is increased, so that oxygen vacancies in the oxide semiconductor 42 can be reduced.

The contact region between the oxide semiconductor 42 and the insulator 52a and the contact region between the oxide semiconductor 42 and the insulator 52c are supplied with a smaller amount of oxygen than the contact region between the oxide semiconductor 42 and the insulator 52b. Thus, the contact region between the oxide semiconductor 42 and the insulator 52a and the contact region between the oxide semiconductor 42 and the insulator 52c each have a low resistance in some cases. That is, by adjusting the thickness of the insulator 52a, the range of the second low-resistance region functioning as one of the source region and the drain region can be controlled. Similarly, by adjusting the thickness of the insulator 52c, the range of the first low-resistance region functioning as the other of the source region and the drain region can be controlled. Since the source region and the drain region can be controlled by the thicknesses of the insulator 52a and the insulator 52c as described above, the thicknesses of the insulator 52a and the insulator 52c are determined as appropriate in accordance with characteristics required for the transistor 40.

For each of the insulator 52a and the insulator 52c, any of the insulators having a barrier property against hydrogen described in the later-described section [Insulator] is preferably used. Each of the insulator 52a and the insulator 52c preferably has a higher barrier property against hydrogen than at least the insulator 52b has. Accordingly, hydrogen can be inhibited from diffusing from the outside of the transistor into the oxide semiconductor 42 through the insulator 52a or the insulator 52c. A silicon nitride film and a silicon nitride oxide film can be suitably used for the insulator 52a and the insulator 52c because the silicon nitride film and the silicon nitride oxide film release fewer impurities (e.g., water and hydrogen) and are less likely to transmit oxygen and hydrogen. For the insulator 52a and the insulator 52c, the same material or different materials may be used.

The thickness of the insulator 52a is preferably smaller than that of the insulator 52b. The thickness of the insulator 52c is preferably smaller than that of the insulator 52b. The thicknesses of the insulator 52a and the insulator 52c are each preferably greater than or equal to 1 nm and less than or equal to 15 nm, further preferably greater than or equal to 2 nm and less than or equal to 10 nm, still further preferably greater than or equal to 3 nm and less than or equal to 7 nm, yet still further preferably greater than or equal to 3 nm and less than or equal to 5 nm. The thickness of the insulator 52b is preferably greater than or equal to 3 nm and less than or equal to 30 nm, further preferably greater than or equal to 5 nm and less than or equal to 20 nm, still further preferably greater than or equal to 7 nm and less than or equal to 15 nm. When the thicknesses of the insulator 52a to the insulator 52c are within any of the above ranges, oxygen vacancies in the oxide semiconductor 42, especially in the channel formation region, can be reduced.

For example, it is preferable that silicon nitride be used for the insulator 52a and the insulator 52c, and silicon oxide be used for the insulator 52b. In that case, each of the insulator 52a and the insulator 52c contains at least silicon and nitrogen. The insulator 52b contains at least silicon and oxygen.

Although the structure in which silicon oxide is used for the insulator 52b is described above, the present invention is not limited thereto. For example, as the insulator 52b, any of insulators having a function of capturing or fixing hydrogen described in the later-described section [Insulator] may be used. When the insulator 52b is provided, hydrogen contained in the oxide semiconductor 42 can be captured or fixed more effectively. Thus, the hydrogen concentration in the oxide semiconductor 42 can be lowered. As the insulator 52b, hafnium oxide, aluminum oxide, or the like is preferably used.

One embodiment of the present invention is not limited to the structure illustrated in FIG. 8F, FIG. 9E, FIG. 9F, and FIG. 10 in which the insulator 52 has a stacked-layer structure of three layers. The insulator 52 may have a stacked-layer structure of two layers or four or more layers.

As illustrated in FIG. 9F and FIG. 10, an insulator 57 may be provided to cover the conductor 46 and the insulator 48. In the case where the insulator 57 is provided, the insulator 56 is provided over the insulator 57. For the insulator 57, any of the insulators having a barrier property against hydrogen described in the later-described section [Insulator] is preferably used. The insulator 57 preferably has a higher barrier property against hydrogen than at least the insulator 56 has. Accordingly, hydrogen can be inhibited from diffusing from the outside of the transistor into the oxide semiconductor 42 through the insulator 48. A silicon nitride film and a silicon nitride oxide film can be suitably used for the insulator 57 because the silicon nitride film and the silicon nitride oxide film release fewer impurities (e.g., water and hydrogen) and are less likely to transmit oxygen and hydrogen.

### [Transistor 60]

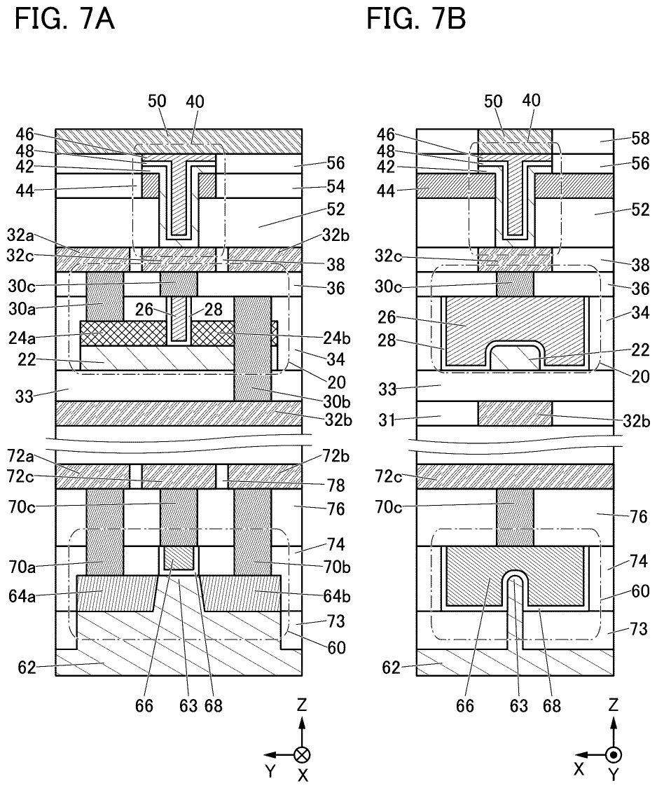

The memory device described in this embodiment may have a structure in which a transistor 60 is provided below the transistor 20 as illustrated in FIG. 7A and FIG. 7B. The transistor 60 is provided on a substrate 62 and includes a conductor 66, an insulator 68, a semiconductor region 63 that is a part of the substrate 62, and a low-resistance region 64a and a low-resistance region 64b functioning as a source region and a drain region. Here, FIG. 7A is a drawing corresponding to FIG. 3A, and FIG. 7B is a drawing corresponding to FIG. 3B.

As illustrated in FIG. 7B, in the transistor 60, a top surface and a side surface in the channel width direction of the semiconductor region 63 are covered with the conductor 66 with the insulator 68 therebetween. Such a Fin-type transistor 60 can have an increased effective channel width and thus have improved on-state characteristics. In addition, contribution of the electric field of the gate electrode can be increased, so that the off-state characteristics of the transistor 60 can be improved.

The transistor 60 may be either a p-channel transistor or an n-channel transistor. Alternatively, a structure in which a p-channel transistor 60 and an n-channel transistor 60 are mixed may be employed.

A region of the semiconductor region 63 where a channel is formed, a region in the vicinity thereof, the low-resistance region 64a and the low-resistance region 64b to be a source region or a drain region, and the like preferably include a semiconductor such as a silicon-based semiconductor, and preferably include single crystal silicon. Thus, a single crystal silicon substrate can be used as the substrate 62, for example. Alternatively, the substrate may be formed using a material containing Ge (germanium), SiGe (silicon germanium), GaAs (gallium arsenide), GaAlAs (gallium aluminum arsenide), or the like. A structure using silicon whose effective mass is controlled by applying stress to a crystal lattice and changing lattice spacing may be employed. Alternatively, the transistor 60 may be an HEMT (High Electron Mobility Transistor) by using GaAs and GaAlAs, or the like.

The low-resistance region 64a and the low-resistance region 64b include an element that imparts n-type conductivity, such as arsenic or phosphorus, or an element that imparts p-type conductivity, such as boron, in addition to the semiconductor material used for the semiconductor region 63.

For the conductor 66 functioning as a gate electrode, it is possible to use a semiconductor material such as silicon containing the element that imparts n-type conductivity, such as arsenic or phosphorus, or the element that imparts p-type conductivity, such as boron, or a conductive material such as a metal material, an alloy material, or a metal oxide material.

Note that since the work function of a conductor depends on a material thereof, the threshold voltage (Vth) of the transistor can be adjusted by changing the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

Note that the transistor 60 illustrated in FIG. 7A and FIG. 7B is an example and is not limited to the structure illustrated therein; an appropriate transistor is used in accordance with a circuit configuration and a driving method.

An insulator 74, an insulator 76, and an insulator 78 are stacked in this order to cover the transistor 60. The semiconductor region 63 is isolated by an insulator 73. The insulator 73 can be formed by a LOCOS (Local Oxidation of Silicon) method, an STI (Shallow Trench Isolation) method, or the like.

The insulator 73, the insulator 74, the insulator 76, and the insulator 78 can be formed using, for example, silicon oxide, silicon oxynitride, silicon nitride oxide, silicon nitride, aluminum oxide, aluminum oxynitride, aluminum nitride oxide, or aluminum nitride.

The insulator 76 may function as a planarization film for eliminating a level difference caused by the transistor 60 or the like provided below the insulator 76. For example, the top surface of the insulator 76 may be planarized by planarization treatment using a chemical mechanical polishing (CMP) method or the like to improve planarity.

The insulator 78 may have a stacked-layer structure. For example, it is preferable that silicon oxide or silicon oxynitride be provided as an upper layer of the insulator 78 and a film having a barrier property be provided as a lower layer of the insulator 78 so as to prevent diffusion of hydrogen and impurities from the substrate 62, the transistor 60, or the like into a region where the transistor 200 is provided. The insulator 78 preferably has a higher barrier property against hydrogen than at least the insulator 76 has.

For example, silicon nitride can be used for the film having a barrier property against hydrogen. Here, diffusion of hydrogen into a semiconductor element including an oxide semiconductor, such as the transistor 20, degrades the characteristics of the semiconductor element in some cases. Therefore, a film that inhibits hydrogen diffusion is preferably provided between the transistor 20 and the transistor 60. The film that inhibits hydrogen diffusion is specifically a film from which a small amount of hydrogen is released.

A conductor 70 (a conductor 70a, a conductor 70b, and a conductor 70c), a conductor 72 (a conductor 72a, a conductor 72b, and a conductor 72c), and the like are embedded in the insulator 74, the insulator 76, and the insulator 78. Here, the conductor 70 and the conductor 72 function as plugs or wirings and can be electrically connected to the transistor 20, the transistor 40, another circuit element, or the like. A plurality of conductors functioning as plugs or wirings are collectively denoted by the same reference numeral in some cases. Furthermore, in this specification and the like, a wiring and a plug electrically connected to the wiring may be a single component. That is, part of a conductor functions as a wiring in some cases and part of the conductor functions as a plug in other cases.

As a material for each of plugs and wirings (the conductor 70, the conductor 72, and the like), a single layer or stacked layers of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, it is preferable to use a low-resistance conductive material such as aluminum or copper. The use of a low-resistance conductive material can reduce wiring resistance.

A wiring layer may be provided over the insulator 78 and the conductor 72. The transistor 60 can be electrically connected to the transistor 20, the transistor 40, another circuit element, or the like through the wiring layer.

### <Modification Example 1 of Memory Device>

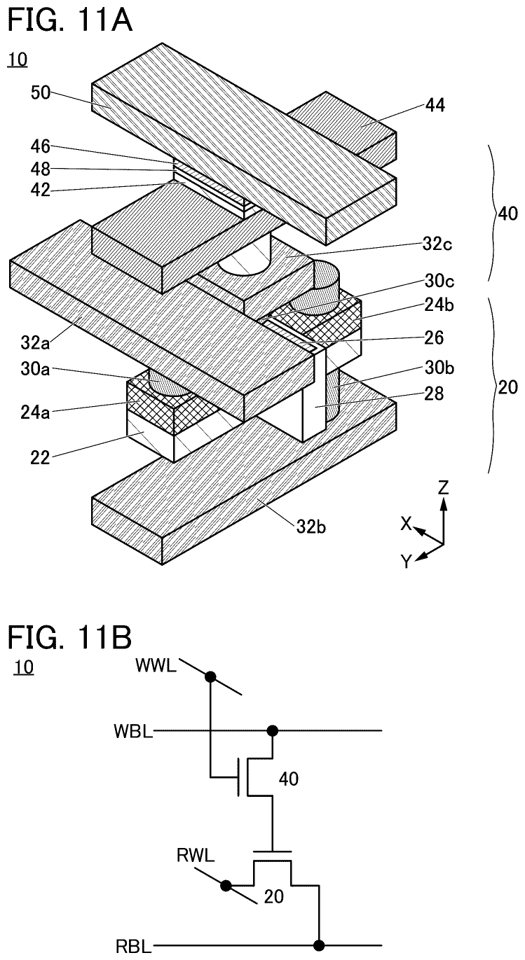

Although the above structure example is an example in which the conductor 32b functions as the wiring RWL and the conductor 32a functions as the wiring RBL, the present invention is not limited thereto. For example, in the memory cell 10, the conductor 32b may function as the wiring RBL and the conductor 32a may function as the wiring RWL. Here, the wiring RBL and the wiring WBL are preferably parallel to each other, and the wiring RWL and the wiring WWL are preferably parallel to each other. Unlike the above structure example, in this modification example, the conductor 44 functioning as the wiring WBL is provided to extend in the Y-axis direction, and the conductor 50 functioning as the wiring WWL is provided to extend in the X-axis direction. FIG. 11A and FIG. 11B illustrate a memory device of this modification example. FIG. 11A is a perspective view illustrating a structure example of the memory device of this modification example and corresponds to FIG. 1A. FIG. 11B is a circuit diagram corresponding to the memory device illustrated in FIG. 11A and corresponds to FIG. 1B. Note that the description of FIG. 1A and FIG. 1B can be referred to for the details of the components similar to those of the memory device illustrated in FIG. 1A and FIG. 1B.

As illustrated in FIG. 11A and FIG. 11B, in this modification example, the conductor 32b (the wiring RBL) and the conductor 44 (the wiring WBL) are provided to extend in the Y-axis direction, and the conductor 32a (the wiring RWL) and the conductor 50 (the wiring WWL) are provided to extend in the X-axis direction. In other words, the conductor 32b and the conductor 44 extend in the channel length direction of the transistor 40, and the conductor 32a and the conductor 50 extend in the channel length direction of the transistor 40 to intersect with each other. Thus, the conductor 32b and the conductor 44 can be provided to overlap with the oxide semiconductor 22 and the oxide semiconductor 42. With such a structure, the transistor 20, the transistor 40, and wirings connected to these can be provided without a great increase in the occupation area in the plan view. This results in a reduction in the area occupied by the memory cell, so that memory cells can be arranged densely to increase the memory capacity of the memory device.

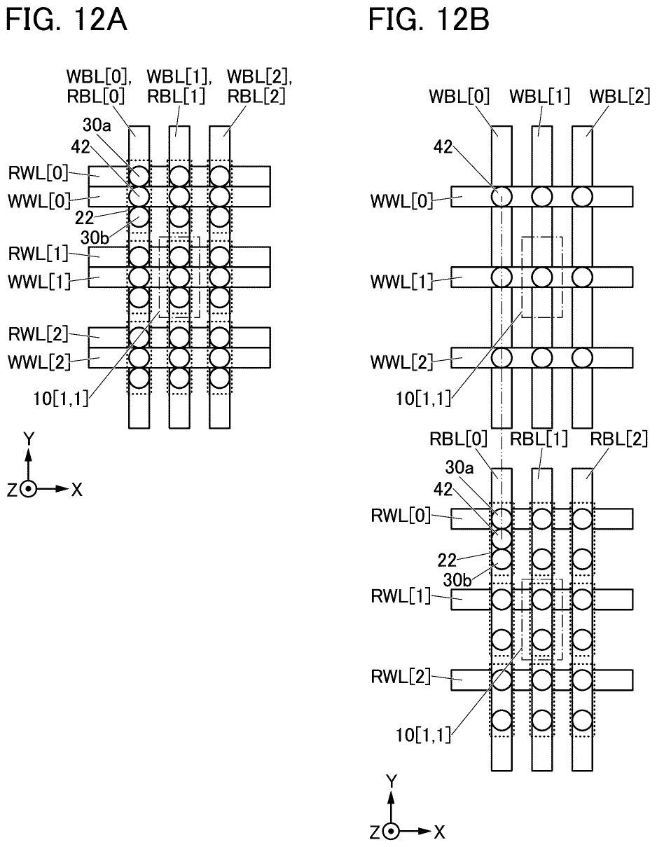

Here, FIG. 12A and FIG. 12B each illustrate a layout diagram in which the memory cells 10 in the above modification example are arranged in a matrix of three rows and three columns. In the layout diagrams illustrated in FIG. 12A and FIG. 12B, the wiring WWL, the wiring RWL, the wiring WBL, the wiring RBL, the oxide semiconductor 42, the oxide semiconductor 22, the conductor 30a, and the conductor 30b are illustrated. Here, FIG. 12B is a layout diagram in which components of the transistor 40 (the wiring WWL, the wiring WBL, and the oxide semiconductor 42) and components of the transistor 20 (the wiring RWL, the wiring RBL, the oxide semiconductor 22, the conductor 30a, and the conductor 30b) are separately displayed for clarity of the drawing. FIG. 12A corresponds to FIG. 5A illustrated in the above structure example, and FIG. 12B corresponds to FIG. 5B in the above structure example. Thus, the description of FIG. 5A and FIG. 5B can be referred to for details of the components of the memory device illustrated in FIG. 12A and FIG. 12B which are similar to that of the memory device illustrated in FIG. 5A and FIG. 5B.

As illustrated in FIG. 12A and FIG. 12B, the wiring WBL, the wiring RBL, and the oxide semiconductor 22 are provided to overlap with each other and extend in the Y-axis direction. The wiring WWL and the wiring RWL are provided to extend in the X-axis direction. The conductor 30a is positioned at the intersection between the wiring RWL and the wiring RBL. The oxide semiconductor 42 is positioned at the intersection between the wiring WWL and the wiring WBL. In each memory cell 10, the conductor 30b is placed in a position of the oxide semiconductor 22 where neither the conductor 30a nor the oxide semiconductor 42 is formed.

When the memory cell 10 has the above-described layout, the oxide semiconductor 22 can be provided between the wiring RBL and the wiring WBL to overlap with them, and the oxide semiconductor 42, the conductor 30a, and the conductor 30b can be provided to overlap with the oxide semiconductor 22. Therefore, ideally, as illustrated in FIG. 12A and FIG. 12B, the area occupied by the memory cell 10 can be reduced to an area obtained by adding an alignment margin area to the area occupied by the oxide semiconductor 22. For example, in the case where the wiring RBL, the oxide semiconductor 22, and the wiring WBL are laid out side by side with the wiring RBL not overlapping with the oxide semiconductor 22, the area occupied by the memory cell 10 is probably increased to be approximately 1.5 times or more as large as that in the layout illustrated in FIG. 12A and FIG. 12B. Thus, with the structure illustrated in FIG. 12A and FIG. 12B, the memory device can be highly integrated.

Although the layout of the memory cell array of three rows and three columns is described above as an example, the memory device of the present invention is not limited thereto. The memory device of the present invention can have a structure including a memory cell array of m rows and n columns (m and n are each an integer greater than or equal to 2).

### <Modification Example 2 of Memory Device>

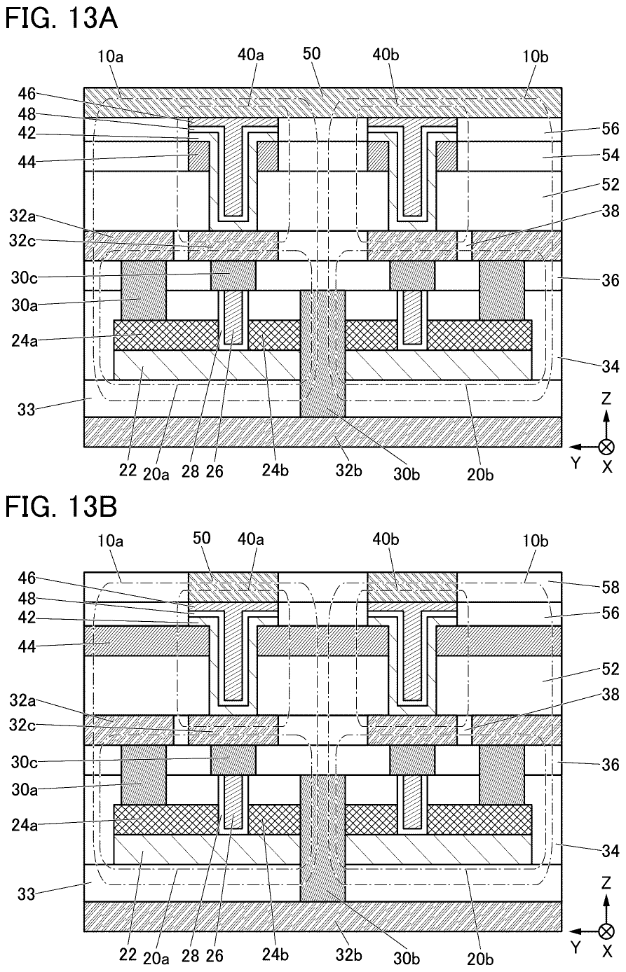

Although in the above structure, a structure in which one conductor 30b is provided in each memory cell 10 is described, the present invention is not limited thereto. For example, as illustrated in FIG. 13A, a memory cell 10a and a memory cell 10b which are adjacent to each other may share the conductor 30b. FIG. 13A is a cross-sectional view of the memory cell 10a and the memory cell 10b and corresponds to FIG. 3A. Therefore, the description of FIG. 3A can be referred to for the details of the components similar to those of the memory device illustrated in FIG. 3A.

As illustrated in FIG. 13A, the memory cell 10a includes a transistor 20a and a transistor 40a, and the memory cell 10b includes a transistor 20b and a transistor 40b. The memory cell 10a and the memory cell 10b each have a structure similar to that of the memory cell 10; the transistor 20a and the transistor 20b each have a structure similar to that of the transistor 20; and the transistor 40a and the transistor 40b each have a structure similar to that of the transistor 40. Note that in FIG. 13A, reference numerals of components of the transistor 20b and the transistor 40b that are the same as those of the transistor 20a and the transistor 40a are omitted.

As illustrated in FIG. 13A, the transistor 40a and the transistor 40b share the oxide semiconductor 22, the conductor 24b, and the conductor 30b. Accordingly, the conductor 24b functions as the other of the source electrode and the drain electrode of the transistor 40a and the transistor 40b. Furthermore, the conductor 24b is electrically connected to the conductor 32b functioning as the wiring RWL through the conductor 30b. In the oxide semiconductor 22, a channel formation region and one of a source region and a drain region of the transistor 40a, a channel formation region and one of a source region and a drain region of the transistor 40b, and a region functioning as the other of the source region and the drain region of the transistor 40a and the transistor 40b are formed.

This modification example illustrated in FIG. 13A can be seen as a memory device having a line-symmetric structure with the conductor 30b as a symmetry axis.

As illustrated in FIG. 13A, in this modification example, the conductor 32b (the wiring RWL) and the conductor 50 (the wiring WWL) are provided to extend in the Y-axis direction, and the conductor 32a (the wiring RBL) and the conductor 44 (the wiring WWL) are provided to extend in the X-axis direction. In other words, the conductor 32b and the conductor 50 extend in the channel length direction of the transistor 40, and the conductor 32a and the conductor 44 extend in the channel length direction of the transistor 40 to intersect with each other. Thus, the conductor 32b and the conductor 44 can be provided to overlap with the oxide semiconductor 22 and the oxide semiconductor 42. With such a structure, the transistor 20, the transistor 40, and wirings connected to these can be provided without a great increase in the occupation area in the plan view. This results in a reduction in the area occupied by the memory cell, so that memory cells can be arranged densely to increase the memory capacity of the memory device.

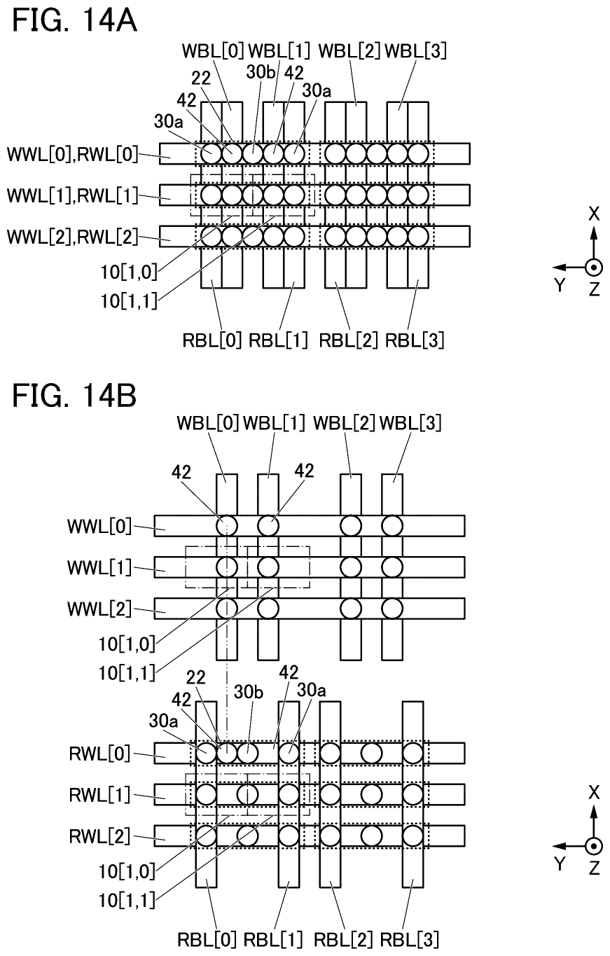

Here, FIG. 14A and FIG. 14B each illustrate a layout diagram in which the memory cells 10a and the memory cells 10b in the above modification example are arranged in a matrix of three rows and four columns. In the layout diagrams illustrated in FIG. 14A and FIG. 14B, the wiring WWL, the wiring RWL, the wiring WBL, the wiring RBL, the oxide semiconductor 42, the oxide semiconductor 22, the conductor 30a, and the conductor 30b are illustrated. In FIG. 14A and FIG. 14B, the memory cell 10[1,0] is denoted by a dashed-dotted frame line as the memory cell corresponding to the memory cell 10a, and the memory cell 10[1,1] is denoted by a dashed-dotted frame line as the memory cell corresponding to the memory cell 10b. Here, FIG. 14B is a layout diagram in which components of the transistor 40 (the wiring WWL, the wiring WBL, and the oxide semiconductor 42) and components of the transistor 20 (the wiring RWL, the wiring RBL, the oxide semiconductor 22, the conductor 30a, and the conductor 30b) are separately displayed for clarity of the drawing. FIG. 14A corresponds to FIG. 5A illustrated in the above structure example, and FIG. 14B corresponds to FIG. 5B in the above structure example. Thus, the description of FIG. 5A and FIG. 5B can be referred to for details of the components of the memory device illustrated in FIG. 14A and FIG. 14B which are similar to that of the memory device illustrated in FIG. 5A and FIG. 5B.

As illustrated in FIG. 14A and FIG. 14B, the wiring WWL, the wiring RWL, and the oxide semiconductor 22 are provided to overlap with each other and extend in the Y-axis direction. The wiring WBL and the wiring RBL are provided to extend in the X-axis direction. The conductor 30a is positioned at the intersection between the wiring RWL and the wiring RBL. The oxide semiconductor 42 is positioned at the intersection between the wiring WWL and the wiring WBL. In each memory cell 10, the conductor 30b is placed in a position of the oxide semiconductor 22 where neither the conductor 30a nor the oxide semiconductor 42 is formed.

When the memory cell 10 has the above-described layout, the oxide semiconductor 22 can be provided between the wiring RWL and the wiring WWL to overlap with them. Furthermore, in this modification example, the oxide semiconductor 42 of the transistor 40a, the oxide semiconductor 42 of the transistor 40b, the conductor 30a of the transistor 20a, the conductor 30a of the transistor 20b, and the conductor 30b shared by the transistor 20a and the transistor 20b can be stacked over the oxide semiconductor 22. Thus, in this modification example illustrated in FIG. 14A and FIG. 14B, the area occupied by two memory cells can be smaller than that in the structure example illustrated in FIG. 5A and FIG. 5B by an area occupied by one conductor 30b. Accordingly, high integration of the memory device can be achieved.

Although FIG. 13A illustrates an example in which the conductor 32b functions as the wiring RWL and the conductor 32a functions as the wiring RBL, the present invention is not limited thereto. For example, as illustrated in FIG. 13B, the conductor 32b may function as the wiring RBL, the conductor 32a may function as the wiring RWL, the conductor 44 functioning as the wiring WBL may be provided to extend in the Y-axis direction, and the conductor 50 functioning as the wiring WWL may be provided to extend in the X-axis direction. That is, the memory device illustrated in FIG. 13B has a structure in which two adjacent memory cells 10 share the conductor 30b in the memory device illustrated in FIG. 11A.

With the above structure, the conductor 32b and the conductor 44 can be provided to overlap with the oxide semiconductor 22 and the oxide semiconductor 42. Thus, the transistor 20, the transistor 40, and wirings connected to these can be provided without a great increase in the occupation area in the plan view. This results in a reduction in the area occupied by the memory cell, so that memory cells can be arranged densely to increase the memory capacity of the memory device.

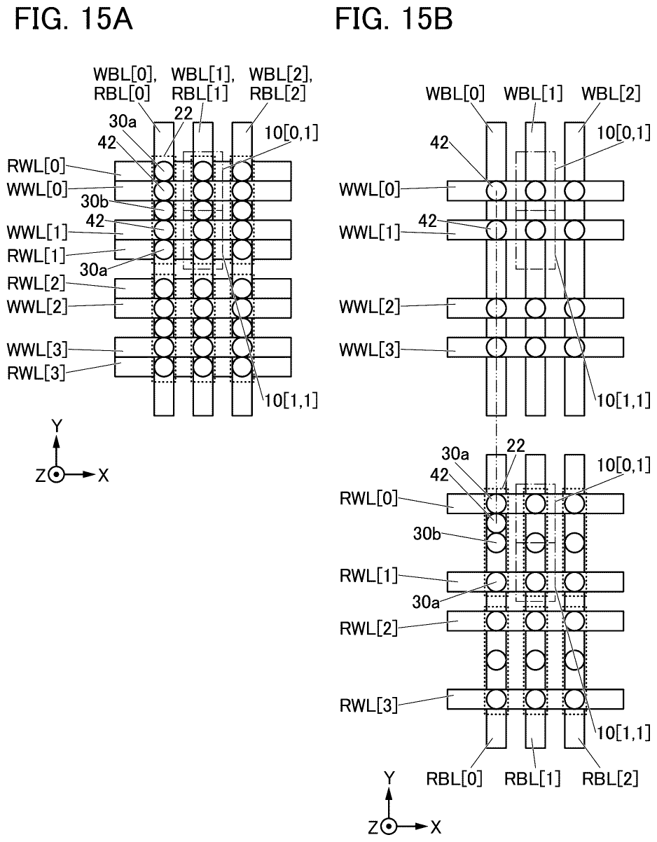

Here, FIG. 15A and FIG. 15B each illustrate a layout diagram in which the memory cells 10a and the memory cells 10b in the above modification example are arranged in a matrix of three rows and four columns. In the layout diagrams illustrated in FIG. 15A and FIG. 15B, the wiring WWL, the wiring RWL, the wiring WBL, the wiring RBL, the oxide semiconductor 42, the oxide semiconductor 22, the conductor 30a, and the conductor 30b are illustrated. In FIG. 15A and FIG. 15B, the memory cell 10[0,1] is denoted by a dashed-dotted frame line as the memory cell corresponding to the memory cell 10a, and the memory cell 10[1,1] is denoted by a dashed-dotted frame line as the memory cell corresponding to the memory cell 10b. Here, FIG. 15B is a layout diagram in which components of the transistor 40 (the wiring WWL, the wiring WBL, and the oxide semiconductor 42) and components of the transistor 20 (the wiring RWL, the wiring RBL, the oxide semiconductor 22, the conductor 30a, and the conductor 30b) are separately displayed for clarity of the drawing. FIG. 15A corresponds to FIG. 12A illustrated in the above modification example, and FIG. 15B corresponds to FIG. 12B in the above structure example. Thus, the description of FIG. 12A and FIG. 12B can be referred to for details of the components of the memory device illustrated in FIG. 15A and FIG. 15B which are similar to that of the memory device illustrated in FIG. 12A and FIG. 12B.

As illustrated in FIG. 15A and FIG. 15B, the wiring WBL, the wiring RBL, and the oxide semiconductor 22 are provided to overlap with each other and extend in the Y-axis direction. The wiring WWL and the wiring RWL are provided to extend in the X-axis direction. The conductor 30a is positioned at the intersection between the wiring RWL and the wiring RBL. The oxide semiconductor 42 is positioned at the intersection between the wiring WWL and the wiring WBL. In each memory cell 10, the conductor 30b is placed in a position of the oxide semiconductor 22 where neither the conductor 30a nor the oxide semiconductor 42 is formed.

When the memory cell 10 has the above-described layout, the oxide semiconductor 22 can be provided between the wiring RBL and the wiring WBL to overlap with them. Furthermore, also in the structure illustrated in FIG. 15A and FIG. 15B, as in the structure illustrated in FIG. 14A and FIG. 14B, the oxide semiconductor 42 of the transistor 40a, the oxide semiconductor 42 of the transistor 40b, the conductor 30a of the transistor 20a, the conductor 30a of the transistor 20b, and the conductor 30b shared by the transistor 20a and the transistor 20b can be stacked over the oxide semiconductor 22. Thus, in this structure illustrated in FIG. 15A and FIG. 15B, the area occupied by two memory cells can be smaller than that in the structure illustrated in FIG. 11A and FIG. 11B by an area occupied by one conductor 30b. Accordingly, high integration of the memory device can be achieved.

### <Component Materials of Memory Device>

Component materials that can be used for the memory device are described below.

### [Substrate]

As a substrate where the memory device is formed, an insulator substrate, a semiconductor substrate, or a conductor substrate may be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate in which an insulator region is included in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### [Insulator]

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. In contrast, when a material with low relative permittivity is used for the insulator functioning as an interlayer film, parasitic capacitance generated between wirings can be reduced. Thus, a material is preferably selected in accordance with the function of the insulator. Note that the material with low relative permittivity is a material with high dielectric strength.

Examples of the material with high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with low relative permittivity include silicon oxide to which fluorine is added, silicon oxide to which carbon is added, and silicon oxide to which carbon and nitrogen are added. Another example is porous silicon oxide. These silicon oxides may contain nitrogen.

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor or provided in the vicinity of the semiconductor layer, such as a gate insulator, preferably includes a region containing excess oxygen. For example, when an insulator including a region containing excess oxygen is in contact with a semiconductor layer or provided in the vicinity of the semiconductor layer, oxygen vacancies in the semiconductor layer can be reduced. Examples of an insulator in which a region containing excess oxygen is easily formed include silicon oxide, silicon oxynitride, and porous silicon oxide.

Examples of the insulator having a barrier property against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of the insulator having a barrier property against hydrogen include aluminum oxide, magnesium oxide, hafnium oxide, gallium oxide, indium gallium zinc oxide, silicon nitride, and silicon nitride oxide.

The insulator having a barrier property against oxygen and the insulator having a barrier property against hydrogen can each be regarded as an insulator having a barrier property against one or both of oxygen and hydrogen.

Examples of the insulator having a function of capturing or fixing hydrogen include an oxide containing magnesium and an oxide containing one or both of aluminum and hafnium. These oxides preferably have an amorphous structure. In the oxide having an amorphous structure, an oxygen atom has a dangling bond and sometimes has a property of capturing or fixing hydrogen with the dangling bond. Note that these metal oxides preferably have an amorphous structure, but a crystal region may be partly formed.

In this specification and the like, a barrier insulating film refers to an insulating film having a barrier property. The barrier property refers to a property that does not easily allow diffusion of a target substance (also referred to as a property that does not easily allow passage of a target substance, a property with low permeability to a target substance, or a function of inhibiting diffusion of a target substance). Note that a function of capturing or fixing (also referred to as gettering) a target substance can be rephrased as a barrier property. Hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule. Specifically, a barrier property against oxygen refers to a property that does not easily allow diffusion of at least one of an oxygen atom, an oxygen molecule, and the like.

### [Conductor]

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may also be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen.

A conductive material containing tungsten, copper, or aluminum as its main component is preferable because it has high conductivity.

A stack of a plurality of conductive layers formed of the above-described materials may be used. For example, a stacked-layer structure combining a material containing the above metal element and a conductive material containing oxygen may be employed. A stacked-layer structure combining a material containing the above metal element and a conductive material containing nitrogen may also be employed. A stacked-layer structure combining a material containing the above metal element, a conductive material containing oxygen, and a conductive material containing nitrogen may also be employed.

In the case where a metal oxide is used for the channel formation region of the transistor, the conductor functioning as the gate electrode preferably has a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Metal Oxide]

A metal oxide sometimes includes a lattice defect. Examples of a lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor may cause unstable electrical characteristics of the transistor. Hence, a metal oxide used in a semiconductor layer of a transistor preferably has a small number of lattice defects.

A transistor using a metal oxide is likely to have its electrical characteristics changed especially by impurities and oxygen vacancies (Vo) in a channel formation region in the metal oxide, which might degrade the reliability. In some cases, hydrogen in the vicinity of the oxygen vacancy forms VoH and generates an electron serving as a carrier. Therefore, when the channel formation region in the metal oxide includes oxygen vacancies, the transistor is likely to have normally-on characteristics (characteristics with which, even when no voltage is applied to the gate electrode, the channel exists and current flows through the transistor). Therefore, oxygen vacancies and impurities are preferably reduced as much as possible in the channel formation region in the metal oxide. In other words, the channel formation region in the metal oxide is preferably an i-type (intrinsic) or substantially i-type region with a reduced carrier concentration.

The kind of a lattice defect that is likely to exist in a metal oxide and the number of lattice defects that exist vary depending on the structure of the metal oxide, a method for depositing the metal oxide, or the like.

Structures of metal oxides are classified into a single crystal structure and other structures (non-single-crystal structures). Examples of non-single-crystal structures include a CAAC structure, a polycrystalline structure, an nc structure, an amorphous-like (a-like) structure, and an amorphous structure. An a-like structure has a structure between an nc structure and an amorphous structure. Note that the classification of crystal structures will be described later.

A metal oxide having an a-like structure and a metal oxide having an amorphous structure each include a void or a low-density region. That is, a metal oxide having an a-like structure and a metal oxide having an amorphous structure each have low crystallinity compared with a metal oxide having an nc structure and a metal oxide having a CAAC structure. Moreover, a metal oxide having an a-like structure has higher hydrogen concentration in the metal oxide than a metal oxide having an nc structure and a metal oxide having a CAAC structure. Thus, a lattice defect is likely to be generated in a metal oxide having an a-like structure and a metal oxide having an amorphous structure.

Therefore, a metal oxide with high crystallinity is preferably used for a semiconductor layer of a transistor. For example, a metal oxide having a CAAC structure or a metal oxide having a single crystal structure is preferably used. The use of the metal oxide for a transistor enables a transistor having favorable electrical characteristics. In addition, a transistor with high reliability can be achieved.

For the channel formation region of a transistor, a metal oxide that increases the on-state current of the transistor is preferably used. To increase the on-state current of the transistor, the mobility of the metal oxide used for the transistor is increased. To increase the mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor and a CAAC-OS (c-axis aligned crystalline oxide semiconductor).

The c-axis of the above crystal is preferably aligned in the normal direction with respect to the formation surface or film surface of the metal oxide. This enables the plurality of layers to be placed parallel or substantially parallel to the formation surface or film surface of the metal oxide. In other words, the plurality of layers extend in the channel length direction.

The above three-layer crystal structure is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal include a YbFe₂O₄ type structure, a Yb₂Fe₃O₇ type structure, and their deformed structures.

Each of the first layer to the third layer is preferably composed of oxygen and one metal element or a plurality of metal elements with the same valence. The valence of the one or plurality of metal elements included in the first layer is preferably equal to the valence of the one or plurality of metal elements included in the second layer. The first layer and the second layer may include the same metal element. The valence of the one or plurality of metal elements included in the first layer is preferably different from the valence of the one or plurality of metal elements included in the third layer.

The above structure can increase the crystallinity of the metal oxide, which leads to an increase in the mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three kinds selected from indium, an element M, and zinc. Note that the element Mis a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably any one or more kinds of the above elements, further preferably one or more kinds selected from aluminum, gallium, tin, and yttrium, still further preferably gallium. In this specification and the like, a metal element and a metalloid element may be collectively referred to as a “metal element”, and a “metal element” in this specification and the like may refer to a metalloid element.

For the oxide semiconductor of one embodiment of the present invention, it is possible to use, for example, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), indium gallium aluminum zinc oxide (In—Ga—Al—Zn oxide, also referred to as IGAZO or IAGZO), or the like. Alternatively, it is possible to use indium tin oxide containing silicon, gallium tin oxide (Ga—Sn oxide), aluminum tin oxide (Al—Sn oxide), or the like.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with larger period numbers in the periodic table. Alternatively, the metal oxide may contain, in addition to indium, one or more kinds of metal elements with larger period numbers in the periodic table. The larger the overlap between orbits of metal elements is, the more likely it is that the metal oxide will have high carrier conductivity. Thus, a transistor containing a metal element with a larger period number in the periodic table can have high field-effect mobility in some cases. Examples of the metal element with a larger period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element Min the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide, a high on-state current and high frequency characteristics of the transistor can be achieved.

In the description of this embodiment, In—Ga—Zn oxide is sometimes taken as an example of the metal oxide.

For the formation of a metal oxide having the layered crystal structure, an atomic layer is preferably deposited one by one. Since an ALD method is used as the deposition method of a metal oxide in one embodiment of the present invention, a metal oxide having the layered crystal structure is easily formed.

Examples of an ALD method include a thermal ALD method, in which a precursor and a reactant react with each other only by thermal energy, and a PEALD (Plasma Enhanced ALD) method, in which a reactant excited by plasma is used.

An ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. The use of plasma in a PEALD method is sometimes preferable because it enables deposition at a lower temperature. Note that some precursors used in an ALD method contain an element such as carbon or chlorine. Thus, in some cases, a film provided by an ALD method contains a larger amount of an element such as carbon or chlorine than a film provided by another deposition method. Note that these elements can be quantified by XPS or SIMS. The deposition method of a metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike a deposition method in which particles ejected from a target or the like are deposited, an ALD method is a deposition method in which a film is formed by reaction at a surface of an object to be processed. Thus, the ALD method is a deposition method that enables favorable step coverage almost regardless of the shape of an object to be processed. In particular, the ALD method enables excellent step coverage and excellent thickness uniformity and thus is suitable for covering a surface of an opening portion with a high aspect ratio, for example. Note that the ALD method has a relatively low deposition rate, and thus is preferably used in combination with another deposition method with a high deposition rate, such as a CVD method, in some cases.

In the ALD method, the composition of a film to be formed can be controlled with the amount of introduced source gas. For example, a film with a certain composition can be formed in the ALD method by adjusting the amount of introduced source gas, the number of times of introduction (also referred to as the number of pulses), the time required for one pulse (also referred to as the pulse time), and the like. Moreover, a film with a continuously changed composition can be formed in the ALD method by, for example, changing the source gas during deposition. In the case where a film is formed while the source gas is changed, the time taken for transfer and pressure adjustment is not necessary, which can shorten the time taken for deposition as compared with the case where the film is formed using a plurality of deposition chambers. Thus, the productivity of the semiconductor device can be increased in some cases.

Note that after a metal oxide film is formed by the ALD method or the like, microwave treatment is preferably performed; further preferably, the microwave treatment is performed in an oxygen-containing atmosphere.

The microwave treatment in an oxygen-containing atmosphere converts an oxygen gas into plasma using a high-frequency wave such as a microwave or RF, so that the oxygen plasma can be applied to the metal oxide. At this time, the metal oxide can be irradiated with the high-frequency wave such as a microwave or RF. In other words, the high-frequency wave such as a microwave or RF, the oxygen plasma, or the like can be applied to the metal oxide.

The effect of the high-frequency wave, the oxygen plasma, and the like can reduce the impurity concentration of the metal oxide. For example, hydrogen in the metal oxide can be released as a water molecule. Alternatively, carbon in the metal oxide can be released as oxocarbon (CO and/or CO₂), for example. In addition, by supply of oxygen radicals generated by the oxygen plasma to the metal oxide, oxygen vacancies, VoH, or the like in the metal oxide can be reduced.

By the effect of the high-frequency wave, the oxygen plasma, and the like, energy which is higher than or equal to the treatment temperature of the microwave treatment is applied to atoms in the metal oxide. This promotes rearrangement of metal atoms and oxygen atoms in the metal oxide, thereby improving the crystallinity of the metal oxide. Note that the metal oxide tends to have improved crystallinity as the impurity concentration and the amount of defects (e.g., oxygen vacancies and VoH) in the metal oxide decrease. That is, the microwave treatment in an oxygen-containing atmosphere reduces the impurity concentration and the amount of defects in the metal oxide and improves the crystallinity of the metal oxide.

### [[Transistor Including Metal Oxide]]

Next, the case where a metal oxide (oxide semiconductor) is used for a transistor will be described. Hereinafter, a transistor including an oxide semiconductor in a semiconductor layer is sometimes referred to as an OS transistor, and a transistor including silicon in a semiconductor layer is sometimes referred to as a Si transistor.

When a metal oxide (oxide semiconductor) of one embodiment of the present invention is used for a transistor, a transistor with high field-effect mobility can be achieved. In addition, a transistor with high reliability can be achieved. Furthermore, a miniaturized or highly integrated transistor can be achieved. For example, a transistor with a channel length greater than or equal to 2 nm and less than or equal to 30 nm can be fabricated.

An oxide semiconductor with a low carrier concentration is preferably used for a channel formation region of the transistor. For example, the carrier concentration in the channel formation region of the oxide semiconductor is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, yet further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that an impurity in an oxide semiconductor refers to, for example, elements other than the main components of the oxide semiconductor. For example, an element with a concentration lower than 0.1 atomic % can be regarded as an impurity.

In a Si transistor, a short-channel effect (also referred to as SCE) appears as miniaturization of the transistor proceeds. Thus, it is difficult to miniaturize the Si transistor. One factor that causes the short-channel effect is a narrow band gap of silicon. By contrast, the OS transistor includes an oxide semiconductor that is a semiconductor material having a wide band gap, and thus can suppress the short-channel effect. In other words, the OS transistor is a transistor in which the short-channel effect does not appear or hardly appears.

Note that the short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes referred to as an S value), and an increase in leakage current. Here, the S value means the amount of change in gate voltage in the subthreshold region when the drain voltage keeps constant and the drain current changes by one order of magnitude.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be fabricated, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure where the channel formation region is an n⁻-type region and the source region and the drain region are n⁺-type regions.

An OS transistor having the above structure enables a semiconductor device to have favorable electrical characteristics even when the semiconductor device is miniaturized or highly integrated. For example, the semiconductor device can have favorable electrical characteristics even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Therefore, the OS transistor can be suitably used as a transistor having a short channel length as compared with the Si transistor. Note that the gate length refers to the length of a gate electrode in a direction in which carriers move inside a channel formation region during an operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

As described above, the OS transistor has effects superior to those of the Si transistor, such as a low off-state current and capability of having a short channel length.

### [[Impurity in Metal Oxide]]

Here, the influence of each impurity in the metal oxide (oxide semiconductor) will be described.

When silicon or carbon, which is one of Group 14 elements, is contained in the oxide semiconductor, defect states are formed in the oxide semiconductor. Thus, the concentration of carbon obtained by SIMS in the channel formation region of the oxide semiconductor is set lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, further preferably lower than or equal to 3×10¹⁸ atoms/cm³, and further preferably lower than or equal to 1×10¹⁸ atoms/cm³. The concentration of silicon obtained by SIMS in the channel formation region of the oxide semiconductor is set lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, further preferably lower than or equal to 3×10¹⁸ atoms/cm³, and further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Therefore, the concentration of nitrogen obtained by SIMS in the channel formation region of the oxide semiconductor is set lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, further preferably lower than or equal to 1×10¹⁸ atoms/cm³, and further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the concentration of hydrogen obtained by SIMS in the channel formation region of the oxide semiconductor is set lower than 1×10²⁰ atoms/cm³, preferably lower than 5×10¹⁹ atoms/cm³, further preferably lower than 1×10¹⁹ atoms/cm³, further preferably lower than 5×10¹⁸ atoms/cm³, and further preferably lower than 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal obtained by SIMS in the channel formation region of the oxide semiconductor is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, the transistor can have stable electrical characteristics.

### [Other Semiconductor Materials]

The oxide semiconductor 42 can be rephrased as a semiconductor layer including the channel formation region of the transistor. A semiconductor material that can be used for the semiconductor layer is not limited to the above metal oxides. A semiconductor material that has a band gap (a semiconductor material that is not a zero-gap semiconductor) may be used for the semiconductor layer. For example, a single element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. As silicon that can be used for the semiconductor layer, single crystal silicon, polycrystalline silicon, microcrystalline silicon, and amorphous silicon can be given. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered substance contains carbon atoms, nitrogen atoms, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For a semiconductor layer, transition metal chalcogenide functioning as a semiconductor is preferably used, for example. Specific examples of the transition metal chalcogenide which can be used for a semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the above-described transition metal chalcogenide for the semiconductor layer enables a memory device with a high on-state current to be provided.

The memory device of this embodiment has a structure in which a plurality of OS transistors are stacked. Accordingly, a memory device having a large storage capacity per area can be achieved. Since the off-state current of the OS transistor is low, a memory device with low power consumption can be achieved. Since the OS transistor has high frequency characteristics, a memory device with a high operation speed can be achieved. Although an example in which the memory device has a structure in which the one of the source and the drain of the transistor 40 and the gate of the transistor 20 are electrically connected to each other is described above, the present invention is not limited thereto. A structure in which the one of the source and the drain of the transistor 40 and the gate of the transistor 20 are electrically connected to each other, which is described in this embodiment, can be provided in at least part of a display device, a light-emitting device, a power storage device, an electronic device, a lighting device, an input device, and an input/output device.

At least part of the structure, method, and the like described in this embodiment can be implemented in appropriate combination with any of the other embodiments described in this specification.

### Embodiment 2

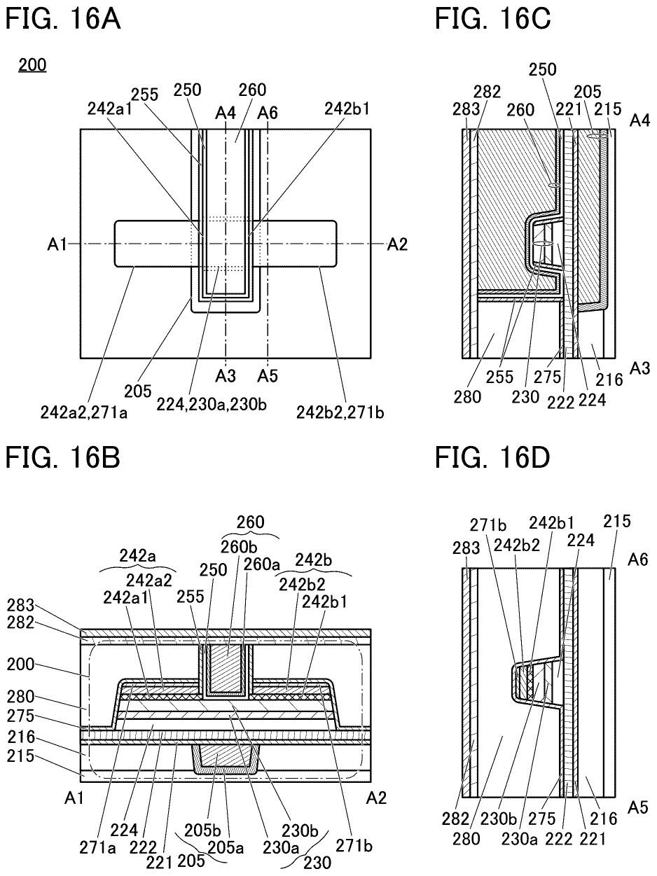

In this embodiment, structure examples of the transistor 20 shown in the above embodiment will be described with reference to FIG. 16 to FIG. 23.

### <Structure Example of Semiconductor Device>

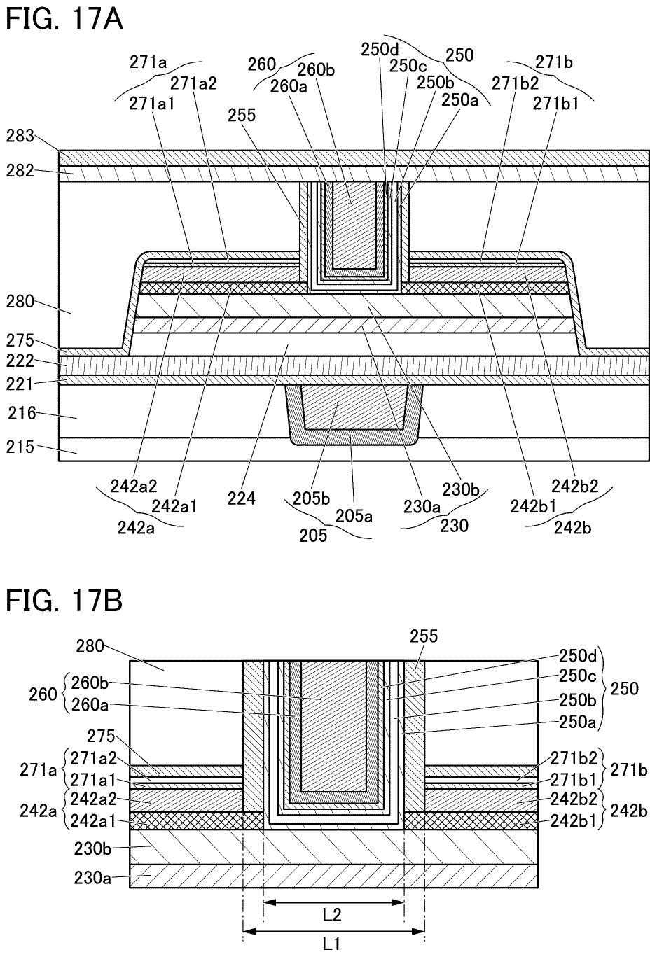

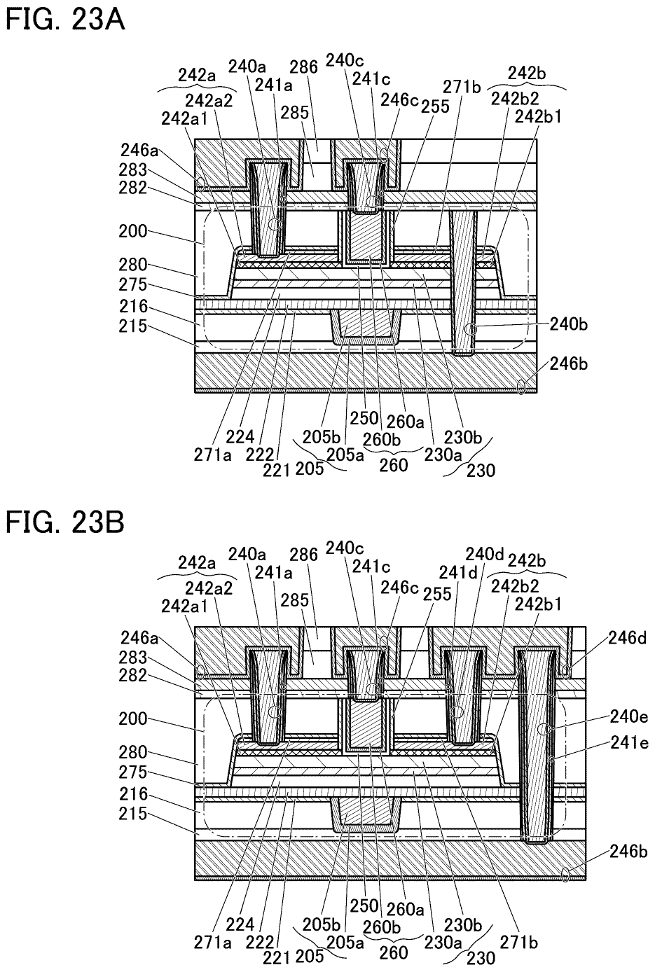

FIG. 16A to FIG. 16D are a top view and cross-sectional views of a semiconductor device (a transistor 200). FIG. 16A is a top view of the semiconductor device. FIG. 16B to FIG. 16D are cross-sectional views of the semiconductor device. Here, FIG. 16B is a cross-sectional view of a portion indicated by the dashed-dotted line A1-A2 in FIG. 16A, and is also a cross-sectional view of the transistor 200 in the channel length direction. FIG. 16C is a cross-sectional view of a portion indicated by the dashed-dotted line A3-A4 in FIG. 16A, and is also a cross-sectional view of the transistor 200 in a channel width direction. FIG. 16D is a cross-sectional view of a portion indicated by the dashed-dotted line A5-A6 in FIG. 16A, and is also a cross-sectional view of the transistor 200 in the channel width direction. Note that for clarity of the drawing, some components are omitted in the top view of FIG. 16A. FIG. 17A to FIG. 22D are enlarged cross-sectional views of the transistor 200 in the channel length direction. FIG. 23A and FIG. 23B are cross-sectional views of the transistor 200 in the channel length direction.

The transistor 200 includes a conductor 205 (a conductor 205a and a conductor 205b) provided to be embedded in an insulator 216; an insulator 221 over the insulator 216 and the conductor 205; an insulator 222 over the insulator 221; an insulator 224 over the insulator 222; an oxide 230 (an oxide 230a and an oxide 230b) over the insulator 224; a conductor 242a (a conductor 242a1 and a conductor 242a2) and a conductor 242b (a conductor 242b1 and a conductor 242b2) over the oxide 230; an insulator 271a over the conductor 242a; an insulator 271b over the conductor 242b; an insulator 250 over the oxide 230; and a conductor 260 (a conductor 260a and a conductor 260b) over the insulator 250.

An insulator 275 is provided over the insulators 271a and 271b, and an insulator 280 is provided over the insulator 275. An insulator 255, the insulator 250, and the conductor 260 are positioned in an opening provided in the insulator 280 and the insulator 275. An insulator 282 is provided over the insulator 280 and the conductor 260. An insulator 283 is provided over the insulator 282. An insulator 215 is provided over a substrate (not illustrated), and the insulator 216 and the conductor 205 are provided over the insulator 215. The insulator 255 is provided between the insulator 250 and the conductor 242a2, the conductor 242b2, the insulator 271a, the insulator 271b, the insulator 275, and the insulator 280.

Here, the transistor 200 corresponds to the transistor 20 described in Embodiment 1. That is, the oxide 230 corresponds to the oxide semiconductor 22, the conductor 242a corresponds to the conductor 24a, the conductor 242b corresponds to the conductor 24b, the insulator 250 corresponds to the insulator 28, the conductor 260 corresponds to the conductor 26, and the insulator 280 corresponds to the insulator 34.

The oxide 230 includes a region functioning as a channel formation region of the transistor 200. The conductor 260 includes a region functioning as a first gate electrode (an upper gate electrode) of the transistor 200. The insulator 250 includes a region functioning as a first gate insulator of the transistor 200. The conductor 205 includes a region functioning as a second gate electrode (a lower gate electrode) of the transistor 200. The insulator 224, the insulator 222, and the insulator 221 each include a region functioning as a second gate insulator of the transistor 200.

The conductor 242a includes a region functioning as one of a source electrode and a drain electrode of the transistor 200. The conductor 242b includes a region functioning as the other of the source electrode and the drain electrode of the transistor 200.

The oxide 230 preferably includes the oxide 230a over the insulator 224 and the oxide 230b over the oxide 230a. Including the oxide 230a under the oxide 230b makes it possible to inhibit diffusion of impurities into the oxide 230b from components formed below the oxide 230a.

One embodiment of the present invention is not limited to the example described in this embodiment in which the oxide 230 has a two-layer structure of the oxide 230a and the oxide 230b. The oxide 230 may have a single-layer structure of the oxide 230b or a stacked-layer structure of three or more layers, for example.

The oxide 230b includes a channel formation region of the transistor 200 and a source region and a drain region provided to sandwich the channel formation region. At least part of the channel formation region overlaps with the conductor 260. The source region overlaps with the conductor 242a, and the drain region overlaps with the conductor 242b. Note that the source region and the drain region can be interchanged with each other.

The channel formation region has a smaller amount of oxygen vacancies or a lower impurity concentration than the source region and the drain region, and thus is a high-resistance region with a low carrier concentration. Thus, the channel formation region can be regarded as being an i-type (intrinsic) or substantially i-type region.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

Note that the carrier concentration of the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1×10⁻⁹ cm⁻³.

In order to reduce the carrier concentration in the oxide 230b, the impurity concentration in the oxide 230b is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration is sometimes referred to as a highly purified intrinsic or substantially highly purified intrinsic oxide semiconductor (or metal oxide).

In order to obtain stable electrical characteristics of the transistor 200, reducing the impurity concentration in the metal oxide 230b is effective. In order to reduce the impurity concentration in the oxide 230b, it is preferable that the impurity concentration in an adjacent film be also reduced. Examples of impurities include hydrogen, nitrogen, an alkali metal, an alkaline earth metal, iron, nickel, and silicon. Note that an impurity in the oxide 230b refers to, for example, an element other than the main components of the oxide 230b. For example, an element with a concentration lower than 0.1 atomic % can be regarded as an impurity.

Note that the channel formation region, the source region, and the drain region may each be formed not only in the oxide 230b but also in the oxide 230a.

In the oxide 230, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

A metal oxide functioning as a semiconductor (hereinafter also referred to as an oxide semiconductor) is preferably used for the oxide 230 (the oxide 230a and the oxide 230b).

The metal oxide functioning as a semiconductor preferably has a wider band gap than silicon as described above. Since an OS transistor including a metal oxide having a wide band gap has a low off-state current, the power consumption of the semiconductor device can be adequately reduced. The OS transistor has excellent frequency characteristics, which enables the semiconductor device to operate at high speed.

The oxide 230 preferably includes a metal oxide (an oxide semiconductor). Examples of the metal oxide that can be used for the oxide 230 include indium oxide, gallium oxide, and zinc oxide. The metal oxide preferably contains at least indium (In) or zinc (Zn). The metal oxide preferably contains two or three kinds selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably any one or more kinds of the above elements, further preferably one or more kinds selected from aluminum, gallium, tin, and yttrium, still further preferably gallium. In this specification and the like, a metal element and a metalloid element may be collectively referred to as a “metal element”, and a “metal element” in this specification and the like may refer to a metalloid element.

For the oxide 230, it is possible to use, for example, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), indium gallium aluminum zinc oxide (In—Ga—Al—Zn oxide, also referred to as IGAZO or IAGZO), or the like. Alternatively, it is possible to use indium tin oxide containing silicon, gallium tin oxide (Ga—Sn oxide), aluminum tin oxide (Al—Sn oxide), or the like.

When the proportion of the number of indium atoms in the total number of atoms of all the metal elements contained in the metal oxide is increased, the field-effect mobility of the transistor can be increased.

Note that the metal oxide may contain, instead of or in addition to indium, one or more kinds of metal elements with larger period numbers in the periodic table. The larger the overlap between orbits of metal elements is, the more likely it is that the metal oxide will have high carrier conductivity. Thus, a transistor containing a metal element with a larger period number in the periodic table can have high field-effect mobility in some cases. Examples of the metal element with a larger period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have higher field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

As described above, the electrical characteristics and reliability of a transistor vary depending on the composition of the metal oxide used for the oxide 230. Therefore, by changing the composition of the metal oxide in accordance with the electrical characteristics and reliability required for the transistor, the semiconductor device can have both excellent electrical characteristics and high reliability.

The oxide 230 preferably has a stacked-layer structure of a plurality of oxide layers with different chemical compositions. For example, the atomic ratio of the element M to a metal element that is a main component in the metal oxide used for the oxide 230a is preferably greater than the atomic ratio of the element M to a metal element that is a main component in the metal oxide used for the oxide 230b. Moreover, the atomic ratio of the element M to In in the metal oxide used for the oxide 230a is preferably greater than the atomic ratio of the element M to In in the metal oxide used for the oxide 230b. With this structure, impurities and oxygen can be inhibited from diffusing into the oxide 230b from the components formed below the oxide 230a.

Furthermore, the atomic ratio of In to the element M in the metal oxide used for the oxide 230b is preferably greater than the atomic ratio of In to the element M in the metal oxide used for the oxide 230a. With this structure, the transistor 200 can have a high on-state current and excellent frequency characteristics.

When the oxide 230a and the oxide 230b include a common element as the main component besides oxygen, the density of defect states at the interface between the oxide 230a and the oxide 230b can be decreased. The density of defect states at the interface between the oxide 230a and the oxide 230b can be decreased. Thus, the influence of interface scattering on carrier conduction is reduced, and the transistor 200 can have a high on-state current and high frequency characteristics.

Specifically, for the oxide 230a, a metal oxide with a composition of In:M:Zn=1:3:2 [atomic ratio] or in the neighborhood thereof, a composition of In:M:Zn=1:3:4 [atomic ratio] or in the neighborhood thereof, a composition of In:M:Zn=1:1:1 [atomic ratio] or in the neighborhood thereof, or a composition of In:M:Zn=1:1:0.5 [atomic ratio] or in the neighborhood thereof can be used. For the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Alternatively, a metal oxide that does not contain the element M and has a composition of In:Zn=1:1 [atomic ratio] or in the neighborhood thereof, or a composition of In:Zn=4:1 [atomic ratio] or in the neighborhood thereof can be used for the oxide 230b. Note that a composition in the neighborhood includes the range of ±30% of an intended atomic ratio. Gallium is preferably used as the element M. In the case where a single layer of the oxide 230b is provided as the oxide 230, a metal oxide that can be used for the oxide 230a may be used for the oxide 230b. The compositions of the metal oxides that can be used for the oxide 230a and the oxide 230b are not limited to the above. For example, the composition of the metal oxide that can be used for the oxide 230a may be applied to the oxide 230b. Similarly, the composition of the metal oxide that can be used for the oxide 230b may be applied to the oxide 230a.

A metal oxide with any of the above compositions may be stacked for one or both of the oxide 230a and the oxide 230b. For example, the oxide 230b may be a stacked-layer film in which a metal oxide layer with an atomic ratio of In:Zn=4:1 and a metal oxide layer with an atomic ratio of In:Ga:Zn=1:1:1 are stacked in this order. Note that in the oxide 230b, a metal oxide layer with an atomic ratio of In:Ga:Zn=1:3:2 or a metal oxide layer with an atomic ratio of In:Ga:Zn=1:3:4 may be used instead of the metal oxide layer with an atomic ratio of In:Ga:Zn=1:1:1.

The metal oxide can be deposited by a sputtering method, a CVD method, an MBE method, a PLD method, or an ALD method. These deposition methods may be combined; for example, the oxide 230a may be deposited by a sputtering method and the oxide 230b may be deposited by an ALD method. When the metal oxide is deposited by a sputtering method, the above atomic ratio is not limited to the atomic ratio of the deposited metal oxide and may be the atomic ratio of a sputtering target used for depositing the metal oxide.

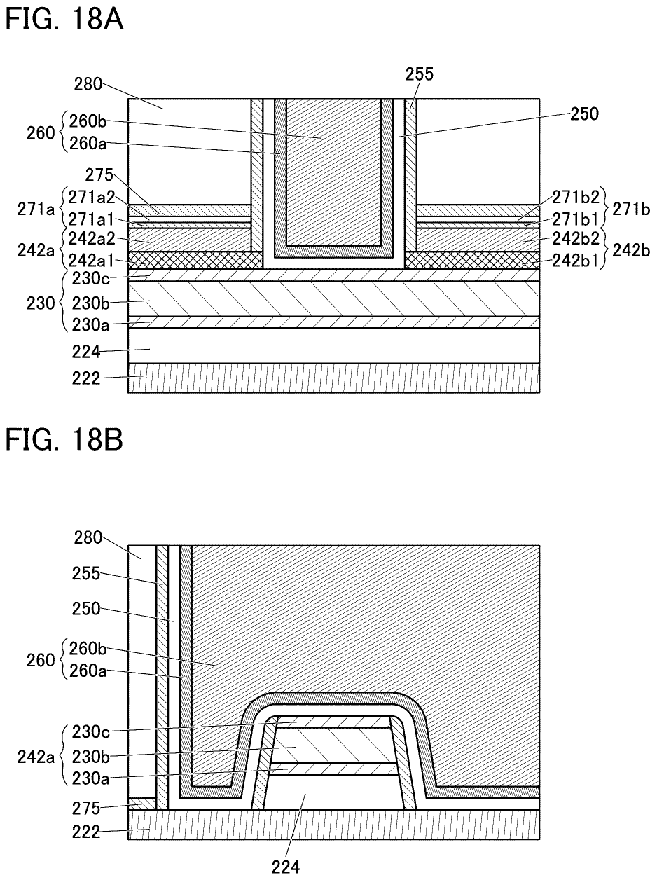

As illustrated in FIG. 18A and FIG. 18B, the oxide 230 may have a three-layer structure of the oxide 230a, the oxide 230b over the oxide 230a, and an oxide 230c over the oxide 230b. Here, a metal oxide that can be used as the oxide 230a may be used as the oxide 230c. The oxide 230c is formed successively with the oxide 230a and the oxide 230b and then processed into an island shape. Thus, in the plan view, an end portion of the oxide 230c is aligned or substantially aligned with an end portion of the oxide 230a and an end portion of the oxide 230b. The oxide 230c is in contact with the insulator 250 in a region between the conductor 242a and the conductor 242b. Note that FIG. 18A is an enlarged view corresponding to FIG. 16B, and FIG. 18B is an enlarged view corresponding to FIG. 16C.

In the above structure, for example, a metal oxide with a composition of In:Ga:Zn=1:1:1 [atomic ratio] or in the neighborhood thereof can be used for the oxide 230a, a metal oxide with a composition of In:Zn=1:1 [atomic ratio] or in the neighborhood thereof or a composition of In:Zn=4:1 [atomic ratio] or in the neighborhood thereof can be used for the oxide 230b, and a metal oxide with a composition of In:Ga:Zn=1:1:1 [atomic ratio] or in the neighborhood thereof can be used for the oxide 230c. For the oxide 230a and the oxide 230c, a metal oxide with a composition of In:Ga:Zn=1:3:2 [atomic ratio] or in the neighborhood thereof or a metal oxide with a composition of In:Ga:Zn=1:3:4 [atomic ratio] or in the neighborhood thereof may be used, instead of a metal oxide with a composition of In:Ga:Zn=1:1:1 [atomic ratio] or in the neighborhood thereof. For example, the thickness of each of the oxide 230a and the oxide 230c can be approximately 1 nm and the thickness of the oxide 230b can be approximately 3 nm to 5 nm.

Here, the energy of the conduction band minimum of each of the oxide 230a and the oxide 230c is preferably higher than the energy of the conduction band minimum of the oxide 230b. In other words, the electron affinity of each of the oxide 230a and the oxide 230c is preferably smaller than the electron affinity of the oxide 230b. For example, the difference between the energy (electron affinity) of the conduction band minimum of each of the oxide 230a and the oxide 230c and the energy (electron affinity) of the conduction band minimum of the oxide 230b is preferably greater than or equal to 0.05 eV and less than 0.3 eV.

With the above structure, the on-state current of the transistor 200 can be increased, and the transistor can have high reliability with small variations.

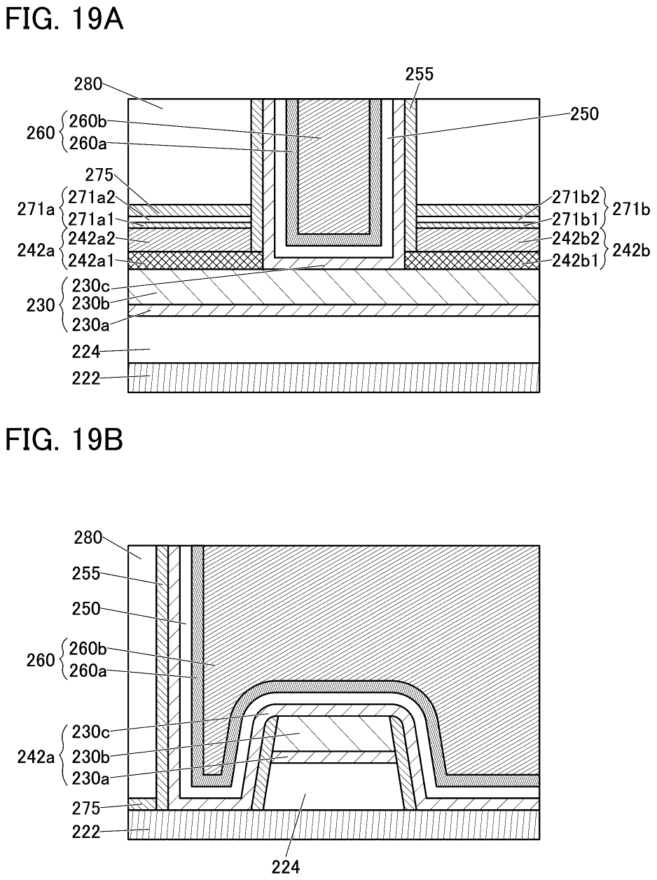

The three-layer structure of the oxide 230 is not limited to the structure illustrated in FIG. 18A and FIG. 18B. For example, the structure illustrated in FIG. 19A and FIG. 19B can also be employed. In the structure illustrated in FIG. 19A and FIG. 19B, the oxide 230c is provided in contact with a bottom surface and a side surface of the insulator 250. Thus, the oxide 230c is covered with the insulator 250 in the opening formed in the insulator 280 and the insulator 275. The oxide 230c is in contact with the oxide 230b in a region between the conductor 242a and the conductor 242b. Note that FIG. 19A is an enlarged view corresponding to FIG. 16B, and FIG. 19B is an enlarged view corresponding to FIG. 16C.

In the transistor 200, the oxide 230b preferably has crystallinity. It is particularly preferable to use a CAAC-OS for the oxide 230b.

The CAAC-OS is a metal oxide having a dense structure with high crystallinity and small amounts of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as a CAAC-OS, is used for the oxide 230b, oxygen extraction from the oxide 230b by the source electrode or the drain electrode can be inhibited. This can reduce oxygen extraction from the oxide 230b even when heat treatment is performed; thus, the transistor 200 is stable with respect to high temperatures in the manufacturing process (what is called thermal budget).

A transistor using an oxide semiconductor is likely to have its electrical characteristics changed by impurities and oxygen vacancies in a region where a channel is formed in the oxide semiconductor, which might degrade the reliability. In some cases, hydrogen in the vicinity of the oxygen vacancy forms VoH and generates an electron serving as a carrier. Therefore, when the channel formation region in the oxide semiconductor includes oxygen vacancies, the transistor is likely to have normally-on characteristics. Therefore, impurities, oxygen vacancies, and VoH are preferably reduced as much as possible in the channel formation region in the oxide semiconductor. In other words, the channel formation region in the oxide semiconductor is preferably an i-type (intrinsic) or substantially i-type region with a reduced carrier concentration.

As a countermeasure against the above, an insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and VoH. However, supply of an excess amount of oxygen to the source region or the drain region might cause a decrease in the on-state current or field-effect mobility of the transistor 200. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, which might adversely affect the electrical characteristics and reliability of the transistor.

Accordingly, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and VoH in the channel formation region of the oxide semiconductor are preferably reduced. Supply of an excess amount of oxygen to the source region and the drain region and excessive reduction in the amount of VOH in the source region and the drain region are preferably inhibited. Furthermore, a structure is preferable in which a reduction in the conductivity of the conductor 260, the conductor 242a, the conductor 242b, and the like is inhibited. For example, oxidation of the conductor 260, the conductor 242a, the conductor 242b, and the like is preferably inhibited. Note that hydrogen in the oxide semiconductor can form VoH; thus, the hydrogen concentration needs to be reduced in order to reduce the amount of VoH.

The semiconductor device of this embodiment thus has a structure in which the hydrogen concentration in the channel formation region is reduced, oxidation of the conductor 242a, the conductor 242b, and the conductor 260 is inhibited, and a reduction in the hydrogen concentration in the source region and the drain region is inhibited.

The insulator 250 in contact with the channel formation region of the oxide 230b preferably has a function of capturing or fixing hydrogen. Thus, the hydrogen concentration in the channel formation region of the oxide 230b can be reduced. Accordingly, VoH in the channel formation region can be reduced, so that the channel formation region can be an i-type or substantially i-type region.

Here, as illustrated in FIG. 17A, the insulator 250 preferably has a stacked-layer structure of an insulator 250a in contact with the oxide 230, an insulator 250b over the insulator 250a, an insulator 250c over the insulator 250b, and an insulator 250d over the insulator 250c. In that case, the insulator 250a and the insulator 250c preferably have a function of capturing or fixing hydrogen.

An example of the insulator having a function of capturing or fixing hydrogen is a metal oxide having an amorphous structure. For the insulator 250a and the insulator 250c, for example, a metal oxide such as magnesium oxide or an oxide containing one or both of aluminum and hafnium is preferably used. In such a metal oxide having an amorphous structure, an oxygen atom has a dangling bond and sometimes has a property of capturing or fixing hydrogen with the dangling bond. That is, the metal oxide having an amorphous structure has high capability of capturing or fixing hydrogen.

A high dielectric constant (high-k) material is preferably used for the insulator 250a and the insulator 250c. An example of the high-k material is an oxide containing one or both of aluminum and hafnium. With use of the high-k material for the insulator 250a and the insulator 250c, a gate potential applied during the operation of the transistor can be reduced while the physical thickness of the gate insulator is maintained. In addition, the equivalent oxide thickness (EOT) of the insulator functioning as the gate insulator can be reduced.

For the insulator 250a and the insulator 250c, an oxide containing one or both of aluminum and hafnium is preferably used, and an oxide that has an amorphous structure and contains one or both of aluminum and hafnium is further preferably used.

In this embodiment, an aluminum oxide film is used for the insulator 250a. The aluminum oxide preferably has an amorphous structure. Here, when the insulator 250a is provided in contact with the oxide 230b, hydrogen contained in the oxide 230b or the like can be captured and fixed more effectively.

In this embodiment, hafnium oxide is used for the insulator 250c. Here, when the insulator 250c is provided between the insulator 250b and the insulator 250d, hydrogen contained in the insulator 250b or the like can be captured and fixed more effectively.

An insulator having thermal stability, such as silicon oxide or silicon oxynitride, is preferably used as the insulator 250b. Note that in this specification and the like, an oxynitride refers to a material having a composition in which the oxygen content is higher than the nitrogen content, and a nitride oxide refers to a material having a composition in which the nitrogen content is higher than the oxygen content. For example, silicon oxynitride refers to a material having a composition in which the oxygen content is higher than the nitrogen content, and silicon nitride oxide refers to a material having a composition in which the nitrogen content is higher than the oxygen content.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device described in this embodiment, the insulator corresponds to the insulator 250a, the insulator 250c, the insulator 250d, the insulator 255, and the insulator 275, for example.

Note that in this specification and the like, a barrier insulator refers to an insulator having a barrier property. In this specification and the like, “having a barrier property” means having a property of hindering the permeation of a target substance (also referred to as having a low permeability). For example, an insulator having a barrier property hardly allows a target substance to diffuse into the insulator. As another example, an insulator having a barrier property has a function of capturing or fixing (also referred to as gettering) a target substance in the insulator.

Examples of the barrier insulator against oxygen include an oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate). For example, each of the insulator 250a, the insulator 250c, the insulator 250d, the insulator 255, and the insulator 275 preferably has a single-layer structure or a stacked-layer structure of the barrier insulator against oxygen. For example, in the case where the insulator 255 has a stacked-layer structure, a two-layer structure of an aluminum oxide film and a silicon nitride film over the aluminum oxide film can be employed.

The insulator 250a and the insulator 255 each preferably have a barrier property against oxygen. It is preferable that oxygen be less likely to pass through the insulator 250a and the insulator 255 than at least through the insulator 280. The insulator 250a includes a region in contact with a side surface of the conductor 242a1 and a region in contact with a side surface of the conductor 242b1. The insulator 255 includes a region in contact with a top surface of the conductor 242a1, a region in contact with a top surface of the conductor 242b1, a region in contact with a side surface of the conductor 242a2, and a region in contact with a side surface of the conductor 242b2. The insulator 250a is in contact with a side surface of the insulator 255. When the insulator 250a and the insulator 255 each have a barrier property against oxygen, oxidation of the side surfaces of the conductor 242a and the conductor 242b and formation of oxide films on the side surfaces can be inhibited. Accordingly, a decrease in the on-state current or field-effect mobility of the transistor 200 can be inhibited.

The insulator 250a is provided in contact with a top surface and a side surface of the oxide 230b, a side surface of the oxide 230a, a side surface of the insulator 224, and a top surface of the insulator 222. When the insulator 250a has a barrier property against oxygen, release of oxygen from the channel formation region of the oxide 230b caused by heat treatment or the like can be inhibited. This can reduce formation of oxygen vacancies in the oxide 230a and the oxide 230b.

By providing the insulator 250a and the insulator 255, even when the insulator 280 contains an excess amount of oxygen, excessive supply of oxygen to the oxide 230a and the oxide 230b can be inhibited and an appropriate amount of oxygen can be supplied to the oxide 230a and the oxide 230b. Thus, it is possible to inhibit excessive oxidation of the source region and the drain region and a decrease in the on-state current or field-effect mobility of the transistor 200.

The oxide containing one or both of aluminum and hafnium has a barrier property against oxygen and thus can be suitably used for the insulator 250a.

Silicon nitride also has a barrier property against oxygen and thus can be suitably used for the insulator 255. In that case, the insulator 255 is an insulator that contains at least nitrogen and silicon. The insulator 255 preferably has a barrier property against hydrogen. Accordingly, diffusion of impurities contained in the conductors 242a2 and 242b2, such as hydrogen, into the oxide 230b can be prevented.

The insulator 250d also preferably has a barrier property against oxygen. The insulator 250d is provided between the conductor 260 and the channel formation region of the oxide 230 and between the insulator 280 and the conductor 260. Such a structure can inhibit diffusion of oxygen contained in the channel formation region of the oxide 230 into the conductor 260 and formation of oxygen vacancies in the channel formation region of the oxide 230. Moreover, oxygen contained in the oxide 230 and oxygen contained in the insulator 280 can be inhibited from diffusing into the conductor 260 and oxidizing the conductor 260. It is preferable that oxygen be less likely to pass through the insulator 250d than at least through the insulator 280. For example, a silicon nitride film is preferably used for the insulator 250d. In that case, the insulator 250d is an insulator that contains at least nitrogen and silicon.

The insulator 250d preferably has a barrier property against hydrogen. Accordingly, diffusion of impurities contained in the conductor 260, such as hydrogen, into the oxide 230b can be prevented.

The insulator 275 preferably has a barrier property against oxygen. The insulator 275 is provided between the insulator 280 and the conductor 242a and between the insulator 280 and the conductor 242b. With this structure, oxygen contained in the insulator 280 can be inhibited from diffusing into the conductor 242a and the conductor 242b. Thus, the conductor 242a and the conductor 242b can be inhibited from being oxidized by oxygen contained in the insulator 280, so that an increase in resistivity and a reduction in on-state current can be inhibited. It is preferable that oxygen be less likely to pass through the insulator 275 than at least through the insulator 280. For example, silicon nitride is preferably used for the insulator 275. In that case, the insulator 275 is an insulator that contains at least nitrogen and silicon.

In order to inhibit a reduction in hydrogen concentration in the source region and the drain region in the oxide 230, a barrier insulator against hydrogen is preferably provided in the vicinity of each of the source region and the drain region. In the semiconductor device described in this embodiment, the barrier insulator against hydrogen is, for example, the insulator 275.

Examples of a barrier insulator against hydrogen include oxides such as aluminum oxide, hafnium oxide, and tantalum oxide and nitrides such as silicon nitride. For example, the insulator 275 preferably has a single-layer structure or a stacked-layer structure of the barrier insulator against hydrogen.

Providing the insulator 275 as described above can inhibit hydrogen in the source region and the drain region from diffusing to the outside, so that a reduction in the hydrogen concentrations of the source region and the drain region can be inhibited. Thus, the source region and the drain region can be n-type regions.

With the above structure, the channel formation region can be an i-type or substantially i-type region, and the source region and the drain region can be n-type regions. Thus, a semiconductor device with favorable electrical characteristics can be provided. The semiconductor device with the above structure can have favorable electrical characteristics even when miniaturized or highly integrated. Miniaturization of the transistor 200 can improve the high frequency characteristics. Specifically, the cutoff frequency can be improved.

The insulator 250a to the insulator 250d function as part of the gate insulator. The insulator 250a to the insulator 250d are provided in the opening formed in the insulator 280, together with the insulator 255 and the conductor 260. The thicknesses of the insulator 250a to the insulator 250d are preferably small for miniaturization of the transistor 200. The thickness of each of the insulator 250a to the insulator 250d is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet further preferably greater than or equal to 1.0 nm and less than 5.0 nm, yet still further preferably greater than or equal to 1.0 nm and less than or equal to 3.0 nm. Note that at least part of each of the insulator 250a to the insulator 250d includes a region having the above-described thickness.

To form the insulator 250a to the insulator 250d having a small thickness as described above, an atomic layer deposition (ALD) method is preferably used for deposition. Furthermore, in the case where the insulator 250a to the insulator 250d and the insulator 255 are provided in the opening of the insulator 280 and the like, an ALD method is preferably used for deposition. Examples of an ALD method include a thermal ALD method, in which a precursor and a reactant react with each other only by thermal energy, and a PEALD (Plasma Enhanced ALD) method, in which a reactant excited by plasma is used. The use of plasma in a PEALD method is sometimes preferable because it enables deposition at a lower temperature.

An ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. Therefore, the insulator 255 and the insulator 250 can be deposited on side surfaces of the opening portion formed in the insulator 280, side end portions of the conductors 242a and 242b, and the like, with favorable coverage and a small thickness like the above-described thickness.

Note that some precursors used in an ALD method contain carbon or the like. Thus, in some cases, a film provided by an ALD method contains a larger amount of impurities such as carbon than a film provided by another deposition method. Note that impurities can be quantified by secondary ion mass spectrometry (SIMS), X-ray photoelectron spectroscopy (XPS), or auger electron spectroscopy (AES).

The present invention is not limited to the structure described above in which the insulator 250 has a four-layer structure of the insulator 250a to the insulator 250d. The insulator 250 can have a structure including at least one of the insulator 250a to the insulator 250d. When the insulator 250 is formed of one, two, or three layer(s) of the insulator 250a to the insulator 250d, the fabrication process of the semiconductor device can be simplified and the productivity can be increased.

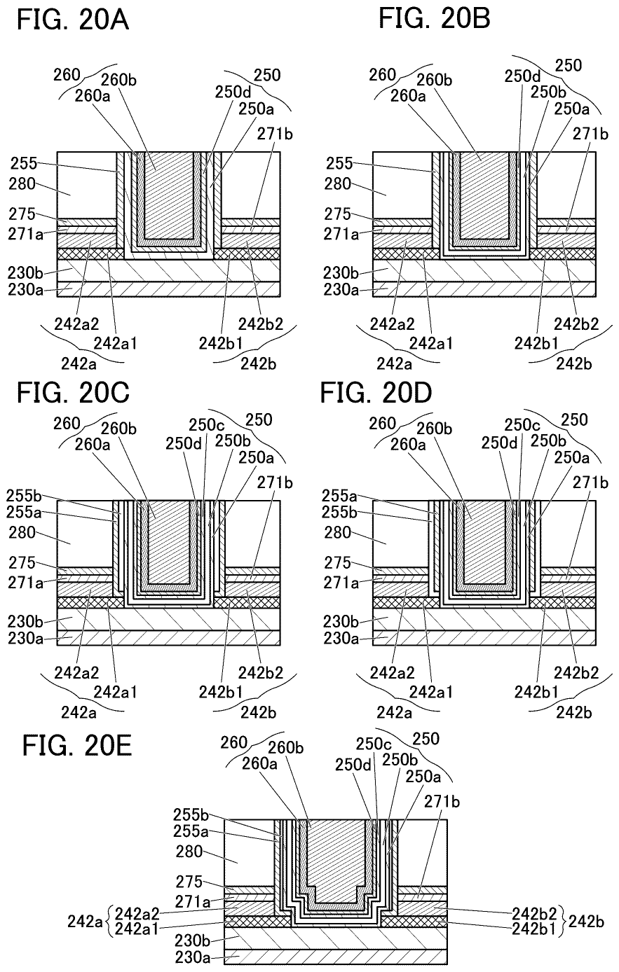

For example, as illustrated in FIG. 20A, the insulator 250 may have a two-layer structure. In that case, the insulator 250 preferably has a stacked-layer structure of the insulator 250a and the insulator 250d over the insulator 250a. A high-k material can be used for at least one of the insulator 250a and the insulator 250d. Thus, the equivalent oxide thicknesses (EOT) of the insulator 250a and the insulator 250d can be reduced while the thicknesses thereof are kept large enough to reduce leakage current.

For another example, as illustrated in FIG. 20B, the insulator 250 may have a three-layer structure. In that case, the insulator 250 preferably has a stacked-layer structure of the insulator 250a, the insulator 250b over the insulator 250a, and the insulator 250d over the insulator 250b. That is, the structure in which the insulator 250b is further provided in the structure illustrated in FIG. 20A is obtained.

In addition to the above structure, the semiconductor device of this embodiment preferably has a structure that inhibits entry of hydrogen into the transistor 200 and the like. For example, an insulator having a function of inhibiting diffusion of hydrogen is preferably provided to cover one or both of the upper portion and the lower portion of the transistor 200 and the like. In the semiconductor device described in this embodiment, the insulator corresponds to the insulator 283, the insulator 282, the insulator 222, and the insulator 221, for example. The insulator 215 provided below the transistor 200 may have a structure similar to the structure of one or both of the insulator 282 and the insulator 283. In such a case, the insulator 215 may have a stacked-layer structure of the insulator 282 and the insulator 283; the insulator 282 may be the lower layer and the insulator 283 may be the upper layer, or the insulator 282 may be the upper layer and the insulator 283 may be the lower layer.

One or more of the insulator 283, the insulator 282, the insulator 222, and the insulator 221 preferably function as a barrier insulator that inhibits diffusion of impurities such as water and hydrogen into the transistor 200 and the like from the substrate side or from above the transistor 200 and the like. Thus, one or more of the insulator 283, the insulator 282, the insulator 222, and the insulator 221 preferably include an insulating material into which impurities such as a hydrogen atom, a hydrogen molecule, a water molecule, a nitrogen atom, a nitrogen molecule, a nitrogen oxide molecule (N₂O, NO, NO₂, or the like), and a copper atom are less likely to diffuse (i.e., the insulating material through which the impurities are less likely to pass). Alternatively, it is preferable to include an insulating material into which oxygen (e.g., at least one of an oxygen atom, an oxygen molecule, and the like) is less likely to diffuse (i.e., the insulating material through which the oxygen is less likely to pass).

Each of the insulator 283, the insulator 282, the insulator 222, and the insulator 221 preferably includes an insulator having a function of inhibiting diffusion of oxygen and impurities such as water and hydrogen; for example, aluminum oxide, magnesium oxide, hafnium oxide, zirconium oxide, an oxide containing aluminum and hafnium (hafnium aluminate), an oxide containing hafnium and zirconium (hafnium zirconium oxide), gallium oxide, indium gallium zinc oxide, silicon nitride, or silicon nitride oxide can be used. For example, silicon nitride, which has a higher hydrogen barrier property, is preferably used for the insulator 283 and the insulator 221. For example, aluminum oxide, which has high capability of capturing or fixing hydrogen, is preferably used for the insulator 282. For example, hafnium oxide, which has high capability of capturing or fixing hydrogen and is a high dielectric constant (high-k) material, is preferably used for the insulator 222.

Such a structure can inhibit impurities such as water and hydrogen from diffusing into the transistor 200 or the like from an interlayer insulating film or the like positioned above the insulator 283. Furthermore, impurities such as water and hydrogen can be inhibited from diffusing into the transistor 200 or the like from an interlayer insulating film or the like positioned below the insulator 221. Moreover, hydrogen contained in the insulator 280, the insulator 224, the insulator 250, and the like can be captured and fixed in the insulator 282 or the insulator 222. Providing the insulator 282 and the insulator 283 can inhibit oxygen contained in the insulator 280 and the like from diffusing into the components over the transistor 200 or the like. Providing the insulator 222 and the insulator 221 can inhibit oxygen contained in the insulator 224 and the like from diffusing into the components below the transistor 200 or the like. Such a structure in which the transistor 200 is surrounded by upper and lower insulators having a function of inhibiting diffusion of oxygen and impurities such as water and hydrogen can reduce the amount of excess oxygen and hydrogen diffusing into the oxide semiconductor. Thus, the semiconductor device can have improved electrical characteristics and reliability.

For example, silicon nitride, which has a high hydrogen barrier property, is preferably used for the insulator 255, the insulator 275, and the insulator 250d. Aluminum oxide, which has high capability of capturing or fixing hydrogen, is preferably used for the insulator 250a, for example. Hafnium oxide, which has high capability of capturing or fixing hydrogen, is preferably used for the insulator 250c, for example.

Here, it is preferable that a region of the insulator 275 that does not overlap with the oxide 230 be in contact with the insulator 222, a side end portion of the insulator 275 be in contact with the insulator 255, and an upper end portion of the insulator 255 and upper end portions of the insulator 250a to the insulator 250d be in contact with the insulator 282. With the above structure, in a region sandwiched between the insulator 283 and the insulator 221, the insulator 280 is separated from the oxide 230 by the insulator 275, the insulator 280 is separated from the insulator 250b by the insulator 255 and the insulator 250a, the conductor 260 is separated from the insulator 250b by the insulator 250d, and the conductor 242a2 and the conductor 242b2 are separated from the insulator 250b by the insulator 255 and the insulator 250a.

Accordingly, diffusion of impurities contained in the insulator 280, such as water and hydrogen, into the oxide 230 and the insulator 250b can be inhibited. Impurities such as water and hydrogen contained in the conductor 260 can be inhibited from diffusing into the oxide 230 through the insulator 250b. Impurities such as water and hydrogen contained in the conductor 242a2 and the conductor 242b2 can be inhibited from diffusing into the oxide 230 through the insulator 250b. For example, even when a contact plug is formed in contact with top surfaces of the conductor 242a2 and the conductor 242b2 and impurities such as water and hydrogen diffuse into the conductor 242a2 and the conductor 242b2 through the contact plug, the amount of impurities such as water and hydrogen diffusing into the oxide 230 can be reduced. Hydrogen contained in the insulator 250a and the insulator 250b can be captured and fixed in the insulator 282. With such a structure, the amount of hydrogen diffusing into the oxide semiconductor can be further reduced. Thus, the semiconductor device can have improved electrical characteristics and reliability.

In the transistor 200, the conductor 205 is placed to overlap with the oxide 230 and the conductor 260. Here, the conductor 205 is preferably provided to be embedded in an opening portion formed in the insulator 216. Moreover, the conductor 205 is preferably provided to extend in the channel width direction as illustrated in FIG. 16A and FIG. 16C. With such a structure, the conductor 205 functions as a wiring when a plurality of transistors are provided.

As illustrated in FIG. 16B and FIG. 16C, the conductor 205 preferably includes the conductor 205a and the conductor 205b. The conductor 205a is provided in contact with a bottom surface and a sidewall of the opening portion. The conductor 205b is provided to fill a depressed portion formed by the conductor 205a along the opening portion. Here, the top surface of the conductor 205 is level or substantially level with the top surface of the insulator 216.

Here, the conductor 205a preferably contains a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to contain a conductive material having a function of inhibiting diffusion of oxygen (e.g., at least one of an oxygen atom, an oxygen molecule, and the like).

When the conductor 205a is formed using a conductive material having a function of inhibiting diffusion of hydrogen, impurities such as hydrogen contained in the conductor 205b can be prevented from diffusing into the oxide 230 through the insulator 216 and the like. When a conductive material having a function of inhibiting diffusion of oxygen is used for the conductor 205a, the conductivity of the conductor 205b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 205a can have a single-layer structure or a stacked-layer structure of the above conductive material. For example, the conductor 205a preferably contains titanium nitride.

The conductor 205b is preferably formed using a conductive material containing tungsten, copper, or aluminum as its main component. For example, the conductor 205b preferably contains tungsten.

The conductor 205 can function as the second gate electrode. In that case, by changing a potential applied to the conductor 205 not in conjunction with but independently of a potential applied to the conductor 260, the Vth of the transistor 200 can be controlled. In particular, by applying a negative potential to the conductor 205, the Vth of the transistor 200 can be increased and its off-state current can be reduced. Thus, a drain current at the time when a potential applied to the conductor 260 is 0 V can be lower in the case where a negative potential is applied to the conductor 205 than in the case where the negative potential is not applied to the conductor 205.

The electrical resistivity of the conductor 205 is designed in consideration of the potential applied to the conductor 205, and the thickness of the conductor 205 is set in accordance with the electrical resistivity. The thickness of the insulator 216 is substantially equal to that of the conductor 205. Here, the conductor 205 and the insulator 216 are preferably as thin as possible in the allowable range of the design of the conductor 205. When the thickness of the insulator 216 is reduced, the absolute amount of impurities such as hydrogen contained in the insulator 216 can be reduced, inhibiting diffusion of the impurities into the oxide 230.

Although the stacked-layer structure of the conductor 205a and the conductor 205b is described above, the present invention is not limited to this structure. The conductor 205 may have a single-layer structure or a stacked-layer structure of three or more layers. For example, in the case where the conductor 205 has a stacked-layer structure of three layers, a conductor that contains a material similar to that of the conductor 205a can be further provided over the conductor 205b in the above-described stacked-layer structure of the conductor 205a and the conductor 205b. In that case, the level of the top surface of the conductor 205b may be lower than the level of the uppermost portion of the conductor 205a, and the aforementioned conductor may be formed to fill the depressed portion formed by the conductor 205a and the conductor 205b.

The insulator 224, the insulator 221, and the insulator 222 function as a gate insulator.

The insulator 224 that is in contact with the oxide 230 preferably includes silicon oxide or silicon oxynitride, for example. Accordingly, oxygen can be supplied from the insulator 224 to the oxide 230, so that oxygen vacancies can be reduced.

The insulator 224 is preferably processed into an island shape like the oxide 230. Thus, in the case where a plurality of the transistors 200 are provided, the insulators 224 having substantially the same size are provided for the respective transistors 200. Accordingly, substantially the same amount of oxygen is supplied from the insulator 224 to the oxide 230 in the transistors 200. This can reduce variations in electrical characteristics of the transistors 200 in the substrate plane. Note that the structure is not limited to this, and it is possible not to pattern the insulator 224 as in the case of the insulator 222.

Note that the insulator 224 may have a stacked-layer structure of two or more layers. In that case, the stacked layers are not necessarily formed of the same material and may be formed of different materials.

A conductive material that is less likely to be oxidized or a conductive material having a function of inhibiting diffusion of oxygen is preferably used for each of the conductor 242a, the conductor 242b, and the conductor 260. Examples of the conductive material include a conductive material containing nitrogen and a conductive material containing oxygen. Thus, a decrease in the conductivity of the conductor 242a, the conductor 242b, and the conductor 260 can be inhibited. In the case where a conductive material containing metal and nitrogen is used for the conductor 242a, the conductor 242b, and the conductor 260, the conductor 242a, the conductor 242b, and the conductor 260 are conductors that contain at least metal and nitrogen.

In FIG. 16B, the conductors 242a and 242b each have a two-layer structure. The conductor 242a is a stacked film of the conductor 242a1 and the conductor 242a2 over the conductor 242a1, and the conductor 242b is a stacked film of the conductor 242b1 and the conductor 242b2 over the conductor 242b1. In that case, a conductive material that is less likely to be oxidized or a conductive material having a function of inhibiting diffusion of oxygen is preferably used for the layer (the conductor 242a1 and the conductor 242b1) in contact with the oxide 230b. This can inhibit a reduction in the conductivity of the conductors 242a and 242b. It is also possible to inhibit oxygen extraction from the oxide 230b and formation of an excessive amount of oxygen vacancies. For the layer (the conductor 242a1 and the conductor 242b1) in contact with the oxide 230b, a material that is likely to absorb (extract) hydrogen is preferably used, in which case the hydrogen concentration in the oxide 230 can be reduced.

As the conductors 242a1 and 242b1, a metal nitride is preferably used; for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

Note that hydrogen included in the oxide 230b or the like diffuses into the conductor 242a1 or the conductor 242b1 in some cases. In particular, when a nitride containing tantalum is used for the conductor 242a1 and the conductor 242b1, hydrogen included in the oxide 230b or the like is likely to diffuse into the conductor 242a1 or the conductor 242b1, and the diffused hydrogen is bonded to nitrogen included in the conductor 242a1 or the conductor 242b1 in some cases. That is, hydrogen included in the oxide 230b or the like is absorbed by the conductor 242a1 or the conductor 242b1 in some cases.

The conductor 242a2 and the conductor 242b2 preferably have higher conductivity than the conductor 242a1 and the conductor 242b1. For example, the thicknesses of the conductor 242a2 and the conductor 242b2 are preferably larger than the thicknesses of the conductor 242a1 and the conductor 242b1. For the conductor 242a2 and the conductor 242b2, a conductor that can be used for the conductor 205b can be used. The above structure can reduce the resistances of the conductor 242a2 and the conductor 242b2. Accordingly, the operating speed of the semiconductor device of this embodiment can be improved.

For example, tantalum nitride or titanium nitride can be used for the conductor 242a1 and the conductor 242b1, and tungsten can be used for the conductor 242a2 and the conductor 242b2.

To inhibit a reduction in the conductivity of the conductors 242a and 242b, an oxide having crystallinity, such as a CAAC-OS, is preferably used for the oxide 230b. Specifically, a metal oxide containing indium, zinc, and one or more selected from gallium, aluminum, and tin is preferably used. When a CAAC-OS is used, oxygen extraction from the oxide 230b by the conductor 242a or the conductor 242b can be inhibited. Furthermore, it is possible to inhibit a reduction in the conductivity of the conductor 242a and the conductor 242b.

As illustrated in FIG. 16B and FIG. 16C, the insulator 255 is provided in the opening formed in the insulator 280 and the like, and in contact with a side surface of the insulator 280, a side surface of the insulator 275, a side surface of the insulator 271a, a side surface of the insulator 271b, the side surface of the conductor 242a2, the side surface of the conductor 242b2, the top surface of the conductor 242a1, the top surface of the conductor 242b1, and the top surface of the insulator 222. In other words, the insulator 255 is formed in contact with the sidewall of the opening formed in the insulator 280 and the like. That is, the insulator 255 can also be referred to as a sidewall insulating film. As illustrated in FIG. 16C, a part of the insulator 255 is formed in contact with a side surface of the oxide 230 and the side surface of the insulator 224 in some cases.

The insulator 255 is an inorganic insulator that is formed in contact with the side surface of the conductor 242a2 and the side surface of the conductor 242b2 and protects the conductor 242a2 and the conductor 242b2. The insulator 255 is exposed to an oxidation atmosphere and thus is preferably an inorganic insulator that is less likely to be oxidized. Furthermore, the insulator 255 is in contact with the conductor 242a2 and the conductor 242b2 and thus is preferably an inorganic insulator that is less likely to oxidize the conductors 242a2 and 242b2. Hence, for the insulator 255, an insulating material that can be used for the insulator 250d having a barrier property against oxygen is preferably used. For example, silicon nitride can be used for the insulator 255.

With the use of the insulator 255 described above, even when heat treatment is performed in an atmosphere containing oxygen after the separation of the conductor into the conductor 242a1 and the conductor 242b1 and before the deposition of the insulator 250, the conductor 242a2 and the conductor 242b2 are not excessively oxidized.

The thickness of the insulator 255 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulator 255 has a thickness in the above range, excessive oxidation of the conductor 242a2 and the conductor 242b2 can be inhibited. Note that at least part of the insulator 255 may have a region with the above-described thickness. Since the insulator 255 is provided in contact with the sidewall of the opening formed in the insulator 280 and the like, the insulator 255 is preferably formed by a method that offers excellent coverage, such as an ALD method. When the thickness of the insulator 255 is set excessively large, the time for depositing the insulator 255 by an ALD method is long, which decreases the productivity; for this reason, the thickness of the insulator 255 is preferably in the above range.

The insulator 255 may have a stacked-layer structure of two or more layers. In that case, at least one of the layers is the above-described inorganic insulator that is less likely to be oxidized. For example, as illustrated in FIG. 20C, the insulator 255 may have a stacked-layer structure of an insulator 255a and an insulator 255b over the insulator 255a. The insulator 255b can be regarded as being placed on the inner side of the insulator 255a. Here, a bottom surface of the insulator 255b is in contact with the insulator 255a in some cases. The above-described inorganic insulator that is less likely to be oxidized may be used for the insulator 255a.

For the insulator 255b, an oxide insulator that can be used for the insulator 250b is preferably used. For example, silicon oxide can be used for the insulator 255b. The dielectric constant of the insulator 255b is preferably lower than that of the insulator 255a. In the above manner, the insulator 255 has a two-layer structure to have a large thickness, and the distance between the conductor 260 and the conductor 242a or the conductor 242b can be increased, so that the parasitic capacitance can be reduced.

For the insulator 255b, an oxide insulator that can be used for the insulator 250a may be used. For example, aluminum oxide or hafnium oxide can be used for the insulator 255b. As described above, aluminum oxide and hafnium oxide have a function of capturing or fixing hydrogen. The use of such an oxide insulator for the insulator 255b can reduce the hydrogen concentration in the insulator 250, the channel formation region of the oxide 230b, and the vicinity of the channel formation region. Accordingly, VoH in the channel formation region can be reduced, so that the channel formation region can be an i-type or substantially i-type region.

The present invention is not limited to the structure illustrated in FIG. 20C in which the insulator 255a is positioned on the outer side and the insulator 255b is positioned on the inner side. For example, the insulator 255b may be placed on the outer side and the insulator 255a may be placed on the inner side as illustrated in FIG. 20D. Here, a bottom surface of the insulator 255a is in contact with the insulator 255b in some cases.

Note that the present invention is not limited to the structure illustrated in FIG. 20C in which a side surface of the insulator 255 that is closer to the conductor 260 side is substantially aligned with a side surface of the conductor 242a1 or the conductor 242b1 that is closer to the conductor 260 side. For example, as illustrated in FIG. 20E, the side surface of the insulator 255 that is closer to the conductor 260 side may be provided to recede from the side surface of the conductor 242a1 or the conductor 242b1 that is closer to the conductor 260 side. At this time, the insulator 250a is in contact with part of the top surface of the conductor 242a1 or the conductor 242b1. With such a structure, the width of an upper portion of the conductor 260 can be increased while the distance between the conductor 242a1 and the conductor 242b1 is kept equal to that in the structure illustrated in FIG. 20C. Thus, the resistance of the conductor 260 functioning as a wiring can be lower in the structure illustrated in FIG. 20E than in the structure illustrated in FIG. 20C.

The insulator 255 functions as a mask at the time of dividing the conductor into the conductor 242a1 and the conductor 242b1. Hence, as illustrated in FIG. 16B or the like, it is preferable that a side end portion of the insulator 255 be aligned or substantially aligned with a side end portion of the conductor 242a1 and a side end portion of the conductor 242b1 in the cross-sectional view of the transistor 200.

In the case where side end portions are aligned or substantially aligned with each other in a cross-sectional view and the case where top surface shapes are the same or substantially the same, it can be said that outlines of stacked layers at least partly overlap with each other in a top view. Examples of such a case include the case where the upper layer and the lower layer are processed with the same mask pattern or mask patterns that are partly the same. Another example is the case where the lower layer is processed with the upper layer used as a mask. Note that, in some cases, the outlines do not exactly overlap with each other; part of the upper layer is positioned inward from the lower layer, or part of the upper layer is positioned outward from the lower layer. Also in such a case, side end portions are regarded as being aligned or substantially aligned or top surface shapes are regarded as being the same or substantially the same.

Here, a portion of the conductor 242a1, which has a top surface over which the insulator 255 is formed, is formed to protrude more than the conductor 242a2 toward the conductor 260 side. Similarly, a portion of the conductor 242b1, which has a top surface over which the insulator 255 is formed, is formed to protrude more than the conductor 242b2 toward the conductor 260 side. As illustrated in FIG. 17B, in a cross-sectional view of the transistor 200 in the channel length direction, a distance L2 between the conductor 242a1 and the conductor 242b1 is smaller than a distance L1 between the conductor 242a2 and the conductor 242b2. Specifically, the difference between L1 and L2 is equal to or substantially equal to twice the thickness of the insulator 255.

The distance L2 between the conductor 242a1 and the conductor 242b1 is preferably short because of affecting the channel length of the transistor 200. For example, the distance L2 is preferably less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm. For example, it is preferable that the distance L2 be approximately greater than or equal to 2 nm and less than or equal to 20 nm. Such a structure allows the distance between the source and the drain to be shortened and the channel length to be shortened accordingly. As a result, the frequency characteristics of the transistor 200 can be improved. The semiconductor device that is miniaturized in this manner can have higher operating speed.

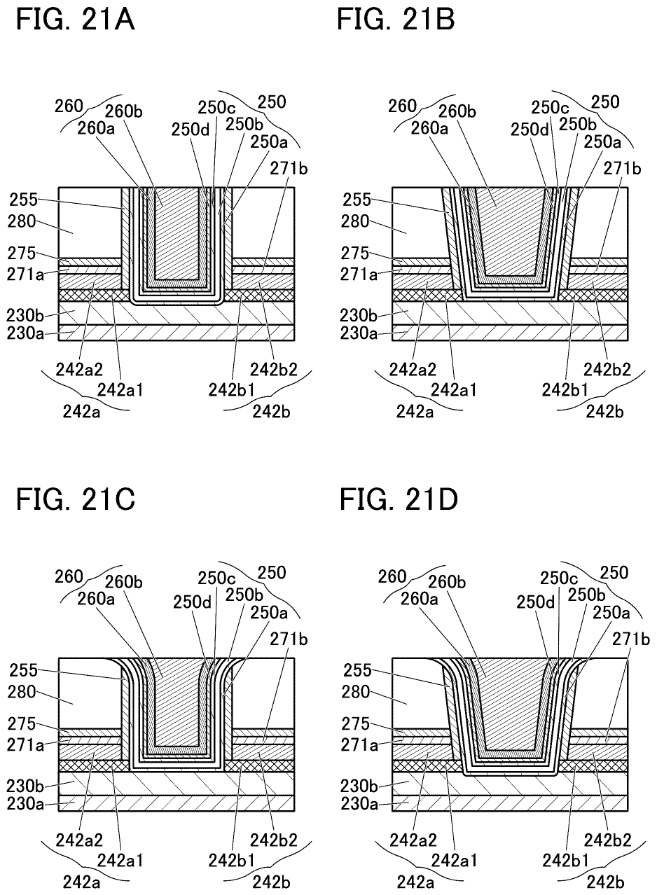

As illustrated in FIG. 21A, a depressed portion is sometimes formed in a portion of the oxide 230b that is exposed from the conductor 242a1 and the conductor 242b1. In other words, in a top surface of the oxide 230b, the level of a region sandwiched between the conductor 242a1 and the conductor 242b1 is lower than the level of a region overlapping with the conductor 242a1 and the level of a region overlapping with the conductor 242b1 in some cases.

In the transistor 200 illustrated in FIG. 17A, the side surfaces of the conductor 242a1 and the conductor 242b1 that face each other and the side surfaces of the conductor 242a2 and the conductor 242b that face each other are perpendicular or substantially perpendicular to the top surface of the oxide 230b; however, the present invention is not limited thereto. As illustrated in FIG. 21B, for example, the facing side surfaces of the conductor 242a1 and the conductor 242b1 and the facing side surfaces of the conductor 242a2 and the conductor 242b2 may have tapered shapes. In that case, the side surfaces of the insulator 271a, the insulator 271b, the insulator 275, and the insulator 280 have tapered shapes in some cases.

The taper angles of the conductors 242a1 and 242b1 may be formed to be more acute than the taper angles of the conductors 242a2 and 242b2.

As illustrated in FIG. 21C, an upper portion of the side surface of the insulator 255 has a tapered shape in some cases. Also as illustrated in FIG. 21C, an upper portion of the insulator 280 has a tapered shape that continues or roughly continues to the tapered shape of the side surface of the insulator 255 in some cases. Also as illustrated in FIG. 21C, the upper portions of the insulator 255 and the insulator 280 have curved surfaces in some cases. Here, the insulator 250a is sometimes in contact with the tapered shapes of the upper portions of the insulator 255 and the insulator 280. In that case, when the upper portions of the insulator 255 and the insulator 280 have curved surfaces, the insulator 250a can be formed with good coverage.

As illustrated in FIG. 21D, the transistor 200 may have the structures illustrated in FIG. 21A to FIG. 21C. That is, in some cases, the oxide 230b includes a depressed portion in a part exposed from the conductors 242a1 and 242b1, the side surfaces of the conductors 242a1 and 242b1 and the side surfaces of the conductors 242a2 and 242b2 have tapered shapes, and the upper portion of the side surface of the insulator 255 has a tapered shape.

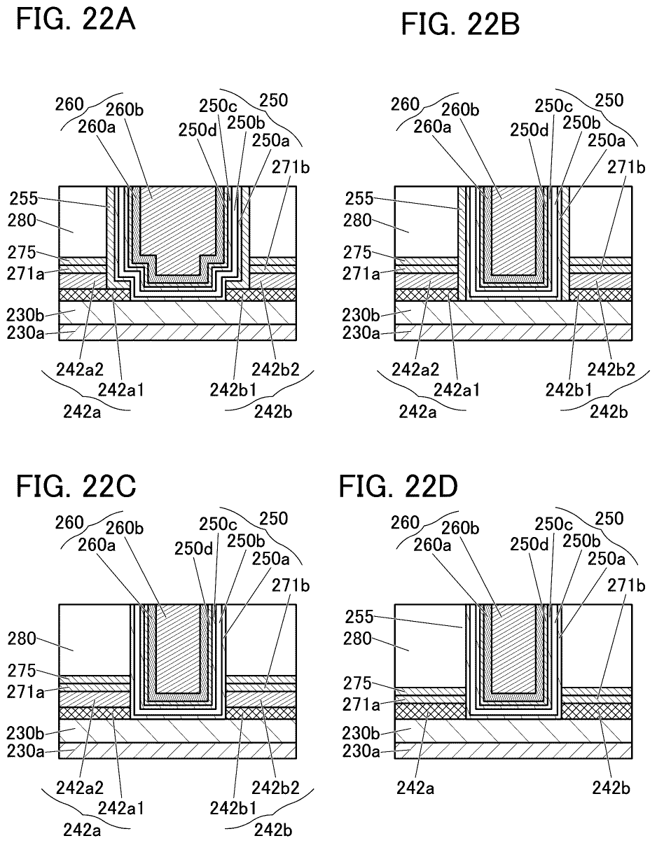

The present invention is not limited to the structure illustrated in FIG. 16B and the like in which the entire side surface of the insulator 255 is aligned or substantially aligned with the side end portion of the conductor 242a1 and the side end portion of the conductor 242b1. As illustrated in FIG. 22A, part of the side surface of the insulator 255 may be aligned or substantially aligned with the side end portion of the conductor 242a1 and the side end portion of the conductor 242b1. Here, as illustrated in FIG. 22A, the insulator 255 has a projecting portion in a portion of the insulator 255 that is in contact with the top surface of the conductor 242a1 or the top surface of the conductor 242b1. The projecting portion of the insulator 255 protrudes more than the other portion toward a center portion of the opening formed in the insulator 280 and the like. In other words, the insulator 255 has what is called an L shape in the cross-sectional view in the channel length direction.

The present invention is not limited to the structure illustrated in FIG. 16B and the like in which parts of the conductor 242a1 and the conductor 242b1 include portions protruding more than the conductor 242a2 and the conductor 242b2, respectively. As illustrated in FIG. 22B, end portions of the conductor 242a1 and the conductor 242b1 may be aligned or substantially aligned with end portions of the conductor 242a2 and the conductor 242b2. In that case, the insulator 255 is in contact with the end portion of the conductor 242a1, the end portion of the conductor 242a2, the end portion of the conductor 242b1, and the end portion of the conductor 242b2. That is, the insulator 255 is in contact with the top surface of the oxide 230b without being in contact with the top surface of the conductor 242a1 and the top surface of the conductor 242b1.

The present invention is not limited to the structure illustrated in FIG. 16B and the like in which the insulator 255 is provided. A structure in which the insulator 255 is not provided as illustrated in FIG. 22C may be employed. In that case, the insulator 250 is in contact with the side surface of the insulator 280, the side surface of the insulator 275, the side surface of the insulator 271a, the side surface of the insulator 271b, the side surface of the conductor 242a2, and the side surface of the conductor 242b2.

The present invention is not limited to the structure illustrated in FIG. 16B and the like in which the conductor 242a has a stacked-layer structure of the conductor 242a1 and the conductor 242a2 and the conductor 242b has a stacked-layer structure of the conductor 242b1 and the conductor 242b2. As illustrated in FIG. 22D, the conductor 242a and the conductor 242b may each have a single-layer structure. In that case, the conductor 242a and the conductor 242b are in contact with the top surface of the oxide 230b; thus, a conductive material that can be used for the conductor 242a1 and the conductor 242b1 is preferably used for the conductor 242a and the conductor 242b.

The insulator 271a and the insulator 271b are inorganic insulators functioning as etching stoppers in the processing into the conductor 242a2 and the conductor 242b2 and protecting the conductor 242a2 and the conductor 242b2. Furthermore, the insulator 271a and the insulator 271b are in contact with the conductor 242a2 and the conductor 242b2 and thus are preferably inorganic insulators that are less likely to oxidize the conductors 242a2 and 242b2. Thus, as illustrated in FIG. 17A, the insulator 271a preferably has a stacked-layer structure of an insulator 271a1 and an insulator 271a2 over the insulator 271a1, and the insulator 271b preferably has a stacked-layer structure of an insulator 271b1 and an insulator 271b2 over the insulator 271b1. Here, the insulators 271a1 and 271b1 are preferably formed using an nitride insulator that can be used for the insulator 250d, so as not to easily oxidize the conductors 242a2 and 242b2. The insulators 271a2 and 271b2 are preferably formed using an oxide insulator that can be used for the insulator 250b, so as to function as etching stoppers.

Here, the insulator 271a1 is in contact with a top surface of the conductor 242a2 and a part of the insulator 275, and the insulator 271b1 is in contact with a top surface of the conductor 242b2 and another part of the insulator 275. The insulator 271a2 is in contact with a top surface of the insulator 271a1 and a bottom surface of the insulator 275, and the insulator 271b2 is in contact with a top surface of the insulator 271b1 and the bottom surface of the insulator 275. For example, silicon nitride can be used for the insulator 271a1 and the insulator 271b1, and silicon oxide can be used for the insulator 271a2 and the insulator 271b2.

An insulator to be the insulator 271a and the insulator 271b functions as a mask for a conductor to be the conductor 242a and the conductor 242b, and thus each of the conductor 242a and the conductor 242b does not have a curved surface between the side surface and the top surface. Thus, end portions at the intersections of the side surfaces and the top surfaces of the conductor 242a and the conductor 242b are angular. The cross-sectional area of each of the conductor 242a and the conductor 242b is larger in the case where the end portion at the intersection of the side surface and the top surface of each of the conductor 242a and the conductor 242b is angular than in the case where the end portion has a curved surface. Furthermore, when a nitride insulator that is less likely to oxidize a metal is used for the insulators 271a1 and 271b1, excessive oxidation of the conductor 242a and the conductor 242b can be prevented. Accordingly, the resistance of the conductor 242a and the conductor 242b is reduced, so that the on-state current of the transistor can be increased.

As illustrated in FIG. 16B and FIG. 16C, the conductor 260 is placed in the opening formed in the insulator 280, the insulator 275, the insulator 255, the insulator 271a, the insulator 271b, the conductor 242a, the conductor 242b, the oxide 230, the insulator 224, and the insulator 222. The conductor 260 is provided in the opening to cover the top surface of the insulator 222, the side surface of the insulator 224, the side surface of the oxide 230a, the side surface of the oxide 230b, and the top surface of the oxide 230b, with the insulator 250 therebetween. A top surface of the conductor 260 is positioned to be level or substantially level with the uppermost portion of the insulator 250, the uppermost portion of the insulator 255, and a top surface of the insulator 280.

Note that the sidewall of the opening in which the conductor 260 and the insulator 250 are placed may be perpendicular or substantially perpendicular to the top surface of the insulator 222 or may be tapered. The tapered shape of the sidewall can improve the coverage with the insulator 255, the insulator 250, and the like provided in the opening of the insulator 280; as a result, defects such as voids can be reduced.

The conductor 260 functions as a first gate electrode of the transistor 200. Here, the conductor 260 is preferably provided to extend in the channel width direction as illustrated in FIG. 16A and FIG. 16C. With such a structure, the conductor 260 functions as a wiring when a plurality of transistors are provided.

In the case of the above structure, a curved surface may be provided between the side surface of the oxide 230b and the top surface of the oxide 230b in a cross-sectional view of the transistor 200 in the channel width direction as illustrated in FIG. 16C. That is, an end portion of the side surface and an end portion of the top surface may be curved (hereinafter also referred to as rounded).

The radius of curvature of the curved surface is preferably greater than 0 nm and less than the thickness of the oxide 230b in a region overlapping with the conductor 242a and the conductor 242b, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide 230b with the insulator 250 and the conductor 260.

Note that in this specification and the like, a transistor structure where a channel formation region is electrically surrounded by at least the electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of the Fin-type structure. Note that in this specification and the like, the Fin-type structure refers to a structure in which at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect is less likely to occur can be provided.

When the transistor 200 has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or an LGAA (Lateral Gate All Around) structure. When the transistor 200 has the S-channel structure, the GAA structure, or the LGAA structure, the channel formation region that is formed at the interface between the oxide 230 and the gate insulator or in the vicinity of the interface can correspond to the entire bulk of the oxide 230. Accordingly, the density of current flowing through the transistor can be increased, which can be expected to increase the on-state current of the transistor or increase the field-effect mobility of the transistor.

In this embodiment, the insulator 224 with an island shape is provided. Accordingly, as illustrated in FIG. 16C, at least part of the bottom surface of the conductor 260 can be positioned lower than the bottom surface of the oxide 230b. Thus, the conductor 260 can be provided to face the top surface and the side surface of the oxide 230b, so that an electric field of the conductor 260 can be applied to the top surface and the side surface of the oxide 230b. When the insulator 224 with an island shape is provided in this manner, the transistor 200 can have an S-channel structure.

Although FIG. 16C illustrates a transistor with an S-channel structure as the transistor 200, the semiconductor device of one embodiment of the present invention is not limited thereto. For example, a transistor structure that can be used in one embodiment of the present invention may be one or more selected from the planar structure, the Fin-type structure, and the GAA structure.

FIG. 16B and the like illustrate the conductor 260 having a two-layer structure. Here, the conductor 260 preferably includes the conductor 260a and the conductor 260b placed over the conductor 260a. For example, the conductor 260a is preferably placed to cover a bottom surface and a side surface of the conductor 260b. At this time, a conductive material that is less likely to be oxidized or a conductive material having a function of inhibiting diffusion of oxygen is preferably used for the conductor 260a.

The conductor 260a is preferably formed using a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

When the conductor 260a has a function of inhibiting diffusion of oxygen, the conductivity of the conductor 260b can be inhibited from being lowered because of oxidation due to oxygen contained in the insulator 280 or the like. Examples of the conductive material having a function of inhibiting diffusion of oxygen include titanium, titanium nitride, tantalum, tantalum nitride, ruthenium, and ruthenium oxide.

As the conductor 260b, a conductor having high conductivity is preferably used. For example, the conductor 260b can be formed using a conductive material containing tungsten, copper, or aluminum as its main component. The conductor 260b may have a stacked-layer structure; for example, a stacked-layer structure of titanium or titanium nitride and the above conductive material may be employed.

In the transistor 200, the conductor 260 is formed in a self-aligned manner to fill the opening formed in the insulator 280 and the like. The formation of the conductor 260 in this manner allows the conductor 260 to be placed to overlap with a region between the conductor 242a1 and the conductor 242b1 without alignment.

The insulator 216 and the insulator 280 each preferably have a lower dielectric constant than the insulator 222. When a material with a low dielectric constant is used for an interlayer film, parasitic capacitance generated between wirings can be reduced.

For example, the insulator 216 and the insulator 280 each preferably include one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. A material such as silicon oxide, silicon oxynitride, or porous silicon oxide is particularly preferably used, in which case a region including oxygen that is released by heating can be easily formed.

The top surfaces of the insulator 216 and the insulator 280 may be planarized.

The concentration of impurities such as water and hydrogen in the insulator 280 is preferably reduced. For example, the insulator 280 preferably includes an oxide containing silicon, such as silicon oxide or silicon oxynitride.

As illustrated in FIG. 23A, a conductor functioning as a wiring can be provided over the insulator 283 and under the insulator 215. In the semiconductor device illustrated in FIG. 23A, an opening reaching the conductor 242a and an opening reaching the conductor 260 are formed in the insulator 283, the insulator 282, the insulator 280, the insulator 275, and the insulator 271a. An opening reaching a conductor 246b provided below the insulator 215 is formed in the insulator 280, the insulator 275, the insulator 271b, the conductor 242b, the oxide 230, the insulator 224, the insulator 222, the insulator 221, the insulator 216, and the insulator 215. Here, a conductor 240a and an insulator 241a are formed in the opening reaching the conductor 242a. A conductor 240c and an insulator 241c are formed in the opening reaching the conductor 260. A conductor 240b is formed in the opening reaching the conductor 246b. Hereinafter, the conductor 240a, the conductor 240b, and the conductor 240c are collectively referred to as a conductor 240 in some cases. The insulator 241a and the insulator 241c are collectively referred to as an insulator 241 in some cases.

In the semiconductor device illustrated in FIG. 23A, an insulator 285 is provided over the insulator 283, and an insulator 286 is provided over the insulator 285. An opening in which the conductor 240a is exposed and an opening in which the conductor 240c is exposed are formed in the insulator 285 and the insulator 286. Here, a conductor 246a is formed in the opening in which the conductor 240a is exposed. A conductor 246c is formed in the opening in which the conductor 240c is exposed. In the structure illustrated in FIG. 23A, the conductor 246b is formed under the insulator 215. The conductor 246b is provided to overlap with the oxide 230. The conductor 246b may be formed to be embedded in an insulator. Hereinafter, the conductor 246a, the conductor 246b, and the conductor 246c are collectively referred to as a conductor 246 in some cases.

Here, the transistor 200 corresponds to the transistor 20 described in Embodiment 1. That is, the conductor 240a corresponds to the conductor 30a, the conductor 240b corresponds to the conductor 30b, the conductor 240c corresponds to the conductor 30c, the conductor 246a corresponds to the conductor 32a, the conductor 246b corresponds to the conductor 32b, the conductor 246c corresponds to the conductor 32c, the insulator 285 corresponds to the insulator 36, and the insulator 286 corresponds to the insulator 38.

An insulator that can be used as the insulator 280 can be used as the insulator 285 and the insulator 286.

The conductor 240 is a conductor functioning as a plug. Here, the conductor 240a includes a region in contact with the conductor 242a and a region in contact with at least part of a bottom surface of the conductor 246a. The conductor 240c includes a region in contact with the conductor 260 and a region in contact with at least part of a bottom surface of the conductor 246c. That is, the conductor 240a is electrically connected to one of the source and the drain of the transistor 200 and is electrically connected to the conductor 246a functioning as a wiring. The conductor 240c is electrically connected to a gate of the transistor 200.

The conductor 240b includes a region in contact with the conductor 242b and a region in contact with at least part of a top surface of the conductor 246b. The conductor 240b is in contact with the conductor 240b on the sidewall of the opening. The conductor 240b may be in contact with the oxide 230b on the sidewall of the opening. With such a structure, the conductor 240b is electrically connected to the other of the source and the drain of the transistor 200 and is electrically connected to the conductor 246b functioning as a wiring. In order to electrically connect the conductor 240b and the conductor 242b, it is preferable that an insulator corresponding to the insulator 241 not be provided on the side surface of the conductor 240b, which is different from the conductor 240a and the conductor 240c.

The conductor 240 is preferably formed using a conductive material containing tungsten, copper, or aluminum as its main component. The conductor 240 may have a stacked-layer structure of a first conductor provided along a side surface and a bottom surface of the opening and a second conductor over the first conductor.

In the case where the conductor 240 has a stacked-layer structure, a conductive material having a function of inhibiting passage of impurities such as water and hydrogen is preferably used for the first conductor placed in the vicinity of the insulator 280. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. With such a structure, impurities such as water and hydrogen contained in a layer above the insulator 283 can be inhibited from entering the oxide 230 through the conductor 240. Note that the second conductor functions also as a wiring and thus is preferably formed using a conductor having high conductivity. The second conductor is formed using a conductive material containing tungsten, copper, or aluminum as its main component, for example.

The present invention is not limited to the structure illustrated in FIG. 23A in which the conductor 240 is a stack of the first conductor and the second conductor. For example, the conductor 240 may have a single-layer structure or a stacked-layer structure of three or more layers.

The insulator 241 is provided in contact with the inner wall of the opening and a side surface of the conductor 240. Note that in FIG. 23A, the insulator 241 has a structure in which a first insulator is provided in contact with the inner wall of the opening and a second insulator is provided inward from the first insulator.

As the insulator 241, a barrier insulator against one or both of hydrogen and oxygen is used. The insulator 241 preferably has a higher barrier property against at least one or both of hydrogen and oxygen than the insulator 280 has. For example, silicon nitride, silicon nitride oxide, aluminum oxide, or hafnium oxide is preferably used as the insulator 241. It is also possible to use a metal oxide such as magnesium oxide, gallium oxide, germanium oxide, yttrium oxide, zirconium oxide, lanthanum oxide, neodymium oxide, or tantalum oxide, for example. When the insulator 241 is provided, impurities such as water and hydrogen contained in the insulator 280 and the like can be inhibited from entering the oxide 230 through the conductor 240. In particular, silicon nitride is suitable because of having a high barrier property against hydrogen.

The barrier insulator against oxygen used as the insulator 241 can inhibit oxygen contained in the insulator 280 from being absorbed by the conductor 240.

When the insulator 241 has a stacked-layer structure as illustrated in FIG. 23A, the first insulator in contact with the inner wall of the opening formed in the insulator 280 and the like and the second insulator on the inner side of the first insulator are preferably formed using a combination of a barrier insulator against oxygen and a barrier insulator against hydrogen.

For example, aluminum oxide deposited by an ALD method is used for the first insulator and silicon nitride deposited by a PEALD method is used for the second insulator. With this structure, oxidation of the conductor 240 can be inhibited, and hydrogen can be inhibited from entering the conductor 240.

The conductor 246 is preferably formed using a conductive material containing tungsten, copper, or aluminum as its main component. The conductor may have a stacked-layer structure and may be, for example, a stack of titanium or titanium nitride and the above conductive material. Note that FIG. 23A illustrates a structure in which the conductor 246a and the conductor 246b are formed in the opening of the insulator 285 and the insulator 286 and are in contact with part of a side surface of the insulator 241. However, the structure of the conductor 246a and the conductor 246b are not limited thereto and may be a structure in which an opening is formed in the insulator 286, a top surface of the conductor 240 is exposed in the opening, and the bottom surface of the conductor 246 is in contact with the top surface of the conductor 240.

The present invention is not limited to the structure illustrated in FIG. 23A in which the conductor 240c and the conductor 246c as well as the conductor 240a, the conductor 240b, the conductor 246a, and the conductor 246b are formed in a region overlapping with the oxide 230b. It is possible to employ the structure illustrated in FIG. 23B in which only the conductor 240a, the conductor 240b, the conductor 246a, and the conductor 246b are formed in a region overlapping with the oxide 230b and the conductor 240c and the conductor 246c are formed in a region not overlapping with the oxide 230b.

Although the semiconductor device illustrated in FIG. 23A has a structure in which a conductor functioning as a plug of the conductor 246b penetrates the conductor 242b and the oxide 230, the present invention is not limited thereto. For example, as illustrated in FIG. 23B, a structure may be employed in which a conductor functioning as a plug of the conductor 246b is provided in a position not overlapping with the oxide 230.

Unlike the semiconductor device illustrated in FIG. 23A, in the semiconductor device illustrated in FIG. 23B, the conductor 240d, the conductor 240e, the conductor 246d, the insulator 241d, and the insulator 241e are formed. Furthermore, an opening reaching the conductor 242b is formed in the insulator 283, the insulator 282, the insulator 280, the insulator 275, and the insulator 271b. An opening reaching the conductor 246b is formed in the insulator 280, the insulator 275, the insulator 222, the insulator 221, the insulator 216, and the insulator 215. Here, the conductor 240d and the insulator 241d are formed in the opening reaching the conductor 242b. The conductor 240e and the insulator 241e are formed in the opening reaching the conductor 246b.

Note that a material for the conductor 240 can be used for the conductor 240d and the conductor 240e. A material for the conductor 246 can be used for the conductor 246d. A material for the insulator 241 can be used for the insulator 241d and the insulator 241e.

In the semiconductor device illustrated in FIG. 23B, an opening in which the conductor 240d is exposed and an opening in which the conductor 240e is exposed are formed in the insulator 285 and the insulator 286. Here, the conductor 246d is formed in an opening in which the conductor 240d and the conductor 240e are exposed.

The conductor 240d includes a region in contact with the conductor 242b and a region in contact with at least part of a bottom surface of the conductor 246b. The conductor 240e includes a region in contact with the conductor 246b and a region in contact with at least part of a bottom surface of the conductor 246b. With such a structure, the conductor 240b is electrically connected to the other of the source and the drain of the transistor 200 and is electrically connected to the conductor 246b functioning as a wiring. Since the conductor 240d and the conductor 240e do not penetrate the conductor 242b and the oxide 230, the insulator 241d can be provided to cover the side surface of the conductor 240d and the insulator 241e can be provided to cover the side surface of the conductor 240e.

Note that as illustrated in FIG. 23B, the conductor 240e and the insulator 241e are preferably formed on an extended line in the channel length direction of the oxide 230. With such a structure, the conductor 246b can be provided to overlap with the oxide 230; thus, the area occupied by the transistor 200 can be reduced and high integration of the semiconductor device can be achieved.

Note that for the components of the semiconductor device described above, the description in sections [Substrate], [Insulator], [Conductor], [Metal oxide], and the like in Embodiment 1 can also be referred to. Each of the components included in the semiconductor device may have a single-layer structure or a stacked-layer structure.

Thus, like the oxide semiconductor layer of the transistor 40, the oxide semiconductor layer used in the transistor 200 can also be referred to as a semiconductor layer including a channel formation region. The semiconductor layer can be formed using any of the semiconductor materials described in [Other semiconductor materials]. With use of a semiconductor layer for the transistor 200, the conductor 240b can be provided to penetrate the semiconductor layer, unlike in the case where a semiconductor substrate is used. Thus, the conductor 246b can be provided below the semiconductor layer to overlap with the semiconductor layer, whereby the area occupied by the transistor 200 can be reduced and high integration of the semiconductor device can be achieved.

Although the structure in which the conductor 260 is provided in the opening formed in the insulator 280 and the like in a region between the conductor 242a and the conductor 242b is described above, the present invention is not limited thereto. The transistor 200 of this embodiment is a top-gate transistor including a semiconductor layer. For example, part of the conductor 260 may overlap with one or both of the conductor 242a and the conductor 242b. In that case, the insulator 280 is not necessarily provided between the conductor 260 and the conductor 242a or the conductor 242b.

The semiconductor device of this embodiment includes OS transistors. Since the off-state current of the OS transistors is low, a semiconductor device or a memory device with low power consumption can be achieved. Since the OS transistors have excellent frequency characteristics, a semiconductor device or a memory device with high operating speed can be achieved. With use of the OS transistors, a semiconductor device having favorable electrical characteristics, a semiconductor device with a small variation in electrical characteristics of transistors, a semiconductor device with a high on-state current, or a highly reliable semiconductor device or memory device can be achieved.

This embodiment can be combined with the other embodiments as appropriate. In this specification, in the case where a plurality of structure examples are shown in one embodiment, the structure examples can be combined as appropriate.

### Embodiment 3

In this embodiment, a memory device of one embodiment of the present invention will be described with reference to drawings. The memory device of one embodiment of the present invention is a memory device in which a transistor using an oxide as a semiconductor (hereinafter, referred to as an OS transistor in some cases) is used (hereinafter, such a memory device is referred to as an OS memory device in some cases).

### <Structure Example of Memory Device>

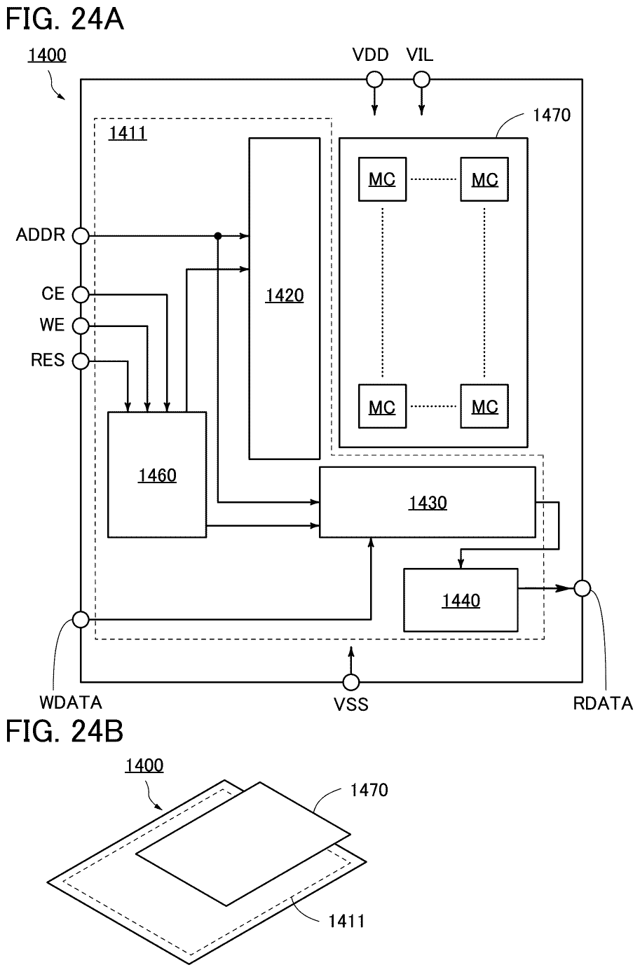

FIG. 24A illustrates a structure example of the OS memory device. A memory device 1400 includes a peripheral circuit 1411 and a memory cell array 1470. The peripheral circuit 1411 is a circuit having a function of writing data to memory cells included in the memory cell array 1470 and reading data from the memory cells included in the memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and are described later in detail. The amplified data signal is output as a data signal RDATA to the outside of the memory device 1400 through the output circuit 1440. The row circuit 1420 includes, for example, a row decoder, a word line driver circuit, and the like, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the memory device 1400. Control signals (CE, WE, and RES), an address signal ADDR, and a data signal WDATA are also input to the memory device 1400 from the outside. The address signal ADDR is input to the row decoder and the column decoder, and the data signal WDATA is input to the write circuit.

The control logic circuit 1460 processes the control signals (CE, WE, and RES) input from the outside, and generates control signals for the row decoder and the column decoder. The control signal CE is a chip enable signal, the control signal WE is a write enable signal, and the control signal RES is a read enable signal. Signals processed by the control logic circuit 1460 are not limited thereto, and other control signals are input as necessary.

The memory cell array 1470 includes a plurality of memory cells MC arranged in a matrix and a plurality of wirings. The memory cell 10 or the like described in Embodiment 1 can be used as the memory cell MC. Note that the number of wirings that connect the memory cell array 1470 to the row circuit 1420 depends on the structure of the memory cell MC, the number of memory cells MC in a column, and the like. For example, in the case where the wiring WWL and the wiring RWL are connected to the memory cell as described in Embodiment 1, the wiring WWL and the wiring RWL may be connected to the row circuit 1420. The number of wirings that connect the memory cell array 1470 to the column circuit 1430 depends on the structure of the memory cell MC, the number of memory cells MC in a row, and the like. For example, in the case where the wiring WBL and the wiring RBL are connected to the memory cell as described in Embodiment 1, the wiring WBL and the wiring RBL may be connected to the column circuit 1430.

Note that this embodiment is not limited to the example illustrated in FIG. 24A in which the peripheral circuit 1411 and the memory cell array 1470 are formed on the same plane. For example, as illustrated in FIG. 24B, the memory cell array 1470 may be provided to overlap with part of the peripheral circuit 1411. For example, the sense amplifier may be provided below the memory cell array 1470 so that they overlap with each other.

When an OS transistor is used as the transistor in the memory cell MC, the transistor in the memory cell MC can be formed in a BEOL (Back end of line) process for forming a wiring of the memory device. In the case where a Si transistor is used in the peripheral circuit 1411 that is below and overlaps with the memory cell array 1470, technology for forming an OS transistor directly above the Si transistor (referred to as BEOL-Tr technology) can be employed. With this technology, a 3D functional circuit can be constructed without a change of design rule, and high functionality can be achieved with low power consumption and low cost.

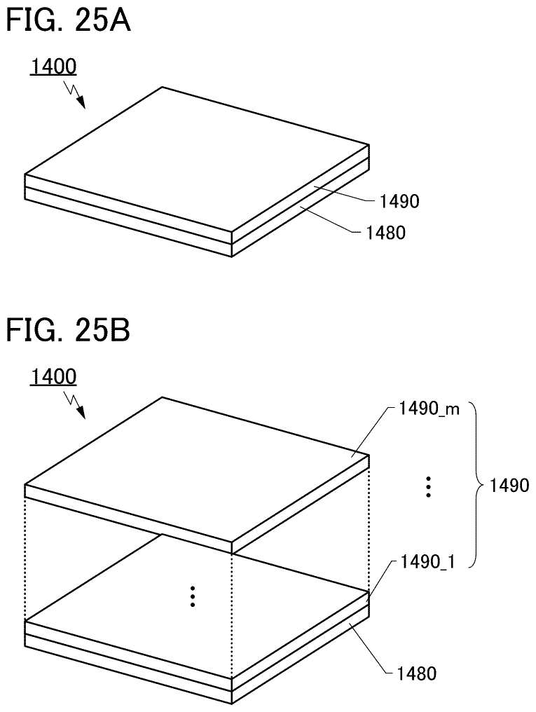

FIG. 25A is a perspective view of the memory device 1400. The memory device 1400 includes a layer 1480 and a layer 1490. FIG. 25B is a perspective view for explaining the structure of the memory device 1400, in which m layers 1490_1 to 1490_m are stacked.

The layer 1480 includes a transistor. A semiconductor layer including a channel formation region of the transistor may be formed using a semiconductor material such as a single crystal semiconductor, a polycrystalline semiconductor, a microcrystalline semiconductor, or an amorphous semiconductor alone or in combination. As the semiconductor material, silicon, germanium, or the like can be used, for example. Alternatively, a compound semiconductor such as silicon germanium, silicon carbide, gallium arsenide, an oxide semiconductor, or a nitride semiconductor may be used. Alternatively, gallium arsenide, aluminum gallium arsenide, indium gallium arsenide, gallium nitride, indium phosphide, silicon germanium, or the like that can be used for an HEMT (High Electron Mobility Transistor) may be used.

The layer 1490 includes a transistor. A semiconductor layer including a channel formation region of the transistor may be formed using a semiconductor material enabling formation of a thin film, such as an oxide semiconductor or silicon. With use of the BEOL-Tr technology, the layer 1490 can be provided over the layer 1480. Thus, high integration of the memory device 1400 can be achieved.

For example, the transistor included in the layer 1480 is a Si transistor. In that case, the peripheral circuit 1411 can be provided in the layer 1480. The transistor included in the layer 1490 is an OS transistor. In that case, the memory cell array 1470 can be provided in the layer 1490. Here, the memory device illustrated in FIG. 7A and FIG. 7B can be used as the memory device 1400 illustrated in FIG. 25A. In that case, the transistor 60 is formed in the layer 1480, and the memory cell including the transistor 20 and the transistor 40 is formed in the layer 1490.

Furthermore, when the m layers 1490_1 to 1490_m are stacked as illustrated in FIG. 25B, the memory cell array 1470 can have a stacked-layer structure. In that case, the transistor 60 is formed in the layer 1480, and the memory cell including the transistor 20 and the transistor 40 is formed in each of the layer 1490_1 to the layer 1490_m.

Accordingly, the memory device 1400 can be manufactured with use of the BEOL-Tr technology. Thus, the area occupied by the memory device 1400 can be reduced.

### Embodiment 4

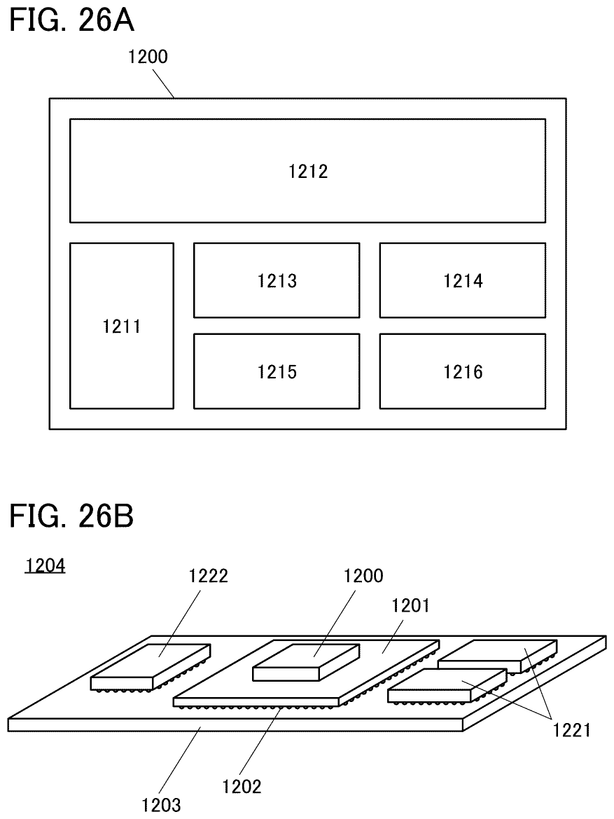

In this embodiment, an example of a chip on which the memory device of one embodiment of the present invention is mounted will be described with reference to FIG. 26.

A plurality of circuits (systems) are mounted on a chip 1200 illustrated in FIG. 26A and FIG. 26B. A technique for integrating a plurality of circuits (systems) into one chip is referred to as system on chip (SoC) in some cases.

As illustrated in FIG. 26A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 26B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Memory devices such as a DRAM 1221 and a flash memory 1222 may be provided over the motherboard 1203. The memory device described in any of the above embodiments can be used as these memory devices. This can make the memory device have low power consumption and large capacity.

The CPU 1211 preferably includes a plurality of CPU cores. The GPU 1212 preferably includes a plurality of GPU cores. The CPU 1211 and the GPU 1212 may each include a memory for temporarily storing data. Alternatively, a common memory for the CPU 1211 and the GPU 1212 may be provided in the chip 1200. The DOSRAM described above can be used as the memory. The GPU 1212 is suitable for parallel computation of a number of data and thus can be used for image processing or product-sum operation. The memory device described in any of the above embodiments can be used as a memory of the GPU 1212. This can make the memory of the GPU 1212 have low power consumption and large capacity.

Since the CPU 1211 and the GPU 1212 are provided in the same chip, a wiring between the CPU 1211 and the GPU 1212 can be shortened; accordingly, data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a circuit for connection with a network such as a LAN (Local Area Network). The network circuit may further include a circuit for network security.

The circuits (systems) can be formed in the chip 1200 through the same manufacturing process. Thus, even when the number of circuits needed for the chip 1200 increases, there is no need to increase the number of steps in the manufacturing process, so that the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 formed using the SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with the other embodiments as appropriate.

### Embodiment 5

This embodiment will describe an electronic component, an electronic device, a large computer, space equipment, and a data center (also referred to as DC) in which the memory device described in any of the above embodiments can be used. An electronic component, an electronic device, a large computer, space equipment, and a data center in which the memory device of one embodiment of the present invention is used are effective in improving performance, e.g., reducing power consumption.

### [Electronic Component]

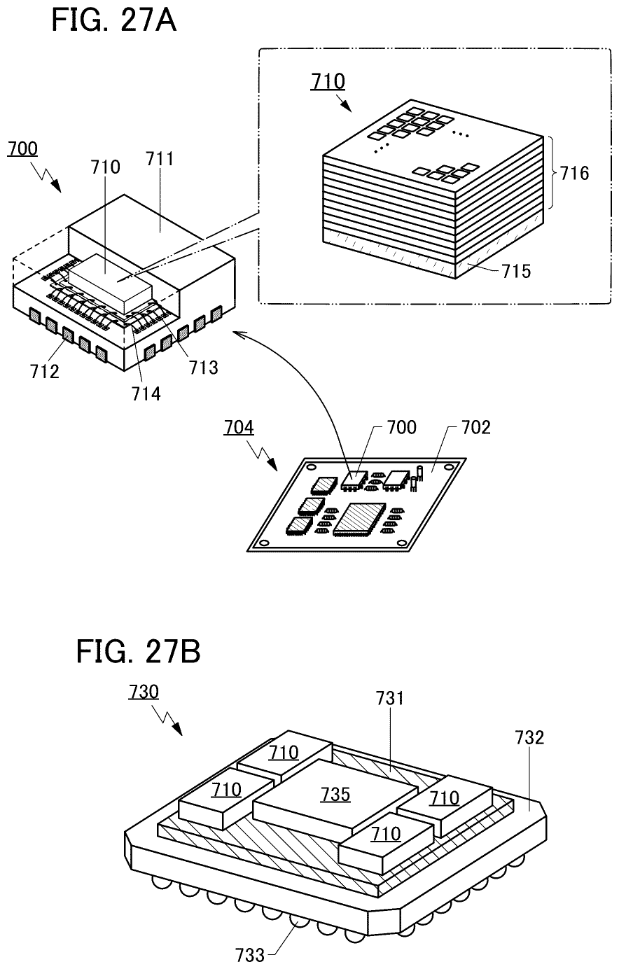

FIG. 27A is a perspective view of a substrate (a circuit board 704) on which an electronic component 700 is mounted. The electronic component 700 illustrated in FIG. 27A includes a semiconductor device 710 in a mold 711. Some components are omitted in FIG. 27A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as TSV (Through Silicon Via) or a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 27B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like that includes a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer, TSV, and the like, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

A heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 27B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Memory Device]

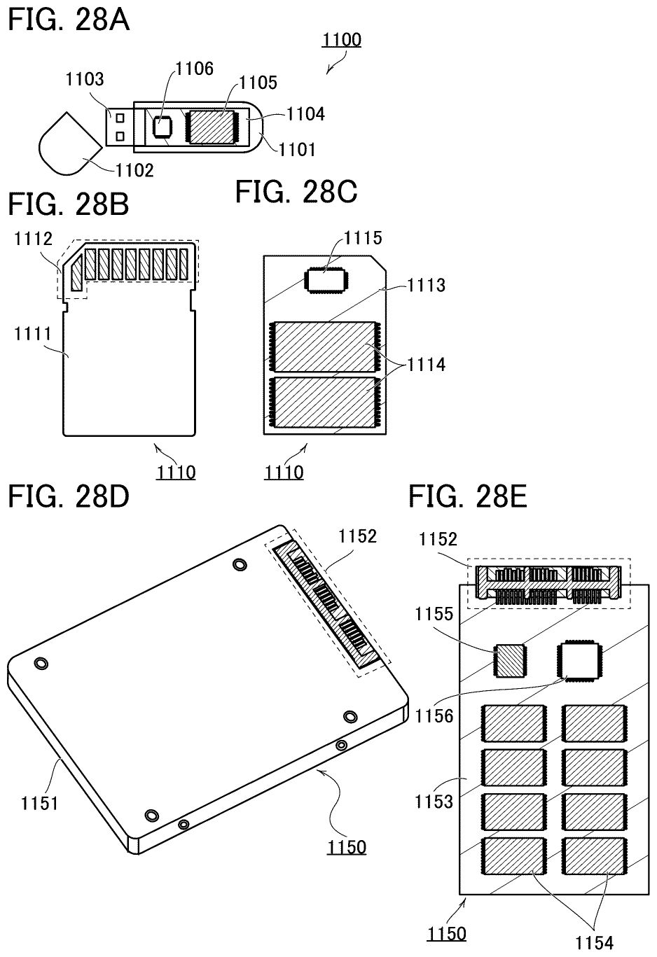

Alternatively, the memory device described in the above embodiment is used for a variety of removable memory devices such as memory cards (e.g., SD cards), USB memories, and SSDs (solid state drives). FIG. 28A to FIG. 28E schematically illustrate some structure examples of removable memory devices. The memory device described in any of the above embodiments is processed into a packaged memory chip and used in a variety of storage devices and removable memories, for example.

FIG. 28A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The memory device described in any of the above embodiments can be incorporated in the memory chip 1105 or the like.

FIG. 28B is a schematic external view of an SD card, and FIG. 28C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. This enables data to be read from and written to the memory chip 1114 by radio communication between a host device and the SD card 1110. The memory device described in any of the above embodiments can be incorporated in the memory chip 1114 or the like.

FIG. 28D is a schematic external view of an SSD, and FIG. 28E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip is used, for example. When the memory chip 1154 is also provided on the back side of the substrate 1153, the capacity of the SSD 1150 can be increased. The memory device described in any of the above embodiments can be incorporated in the memory chip 1154 or the like.

### [Electronic Device]

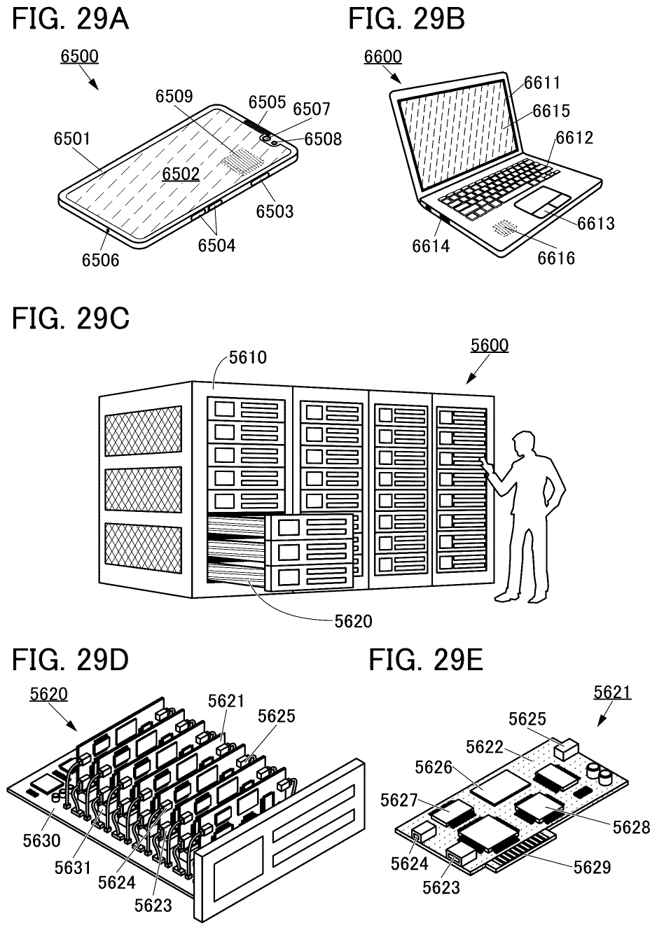

Next, a perspective view of an electronic device 6500 is illustrated in FIG. 29A. The electronic device 6500 illustrated in FIG. 29A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a memory device are provided as the control device 6509, for example. The memory device of one embodiment of the present invention can be used for the control device 6509 and the like.

An electronic device 6600 illustrated in FIG. 29B is an information terminal that can be used as a laptop personal computer. The electronic device 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The memory device of one embodiment of the present invention can be used for the control device 6616 and the like. Note that the memory device of one embodiment of the present invention is preferably used for the control device 6509 and the control device 6616, in which case power consumption can be reduced.

### [Large Computer]

Next, a perspective view of a large computer 5600 is illustrated in FIG. 29C. In the large computer 5600 illustrated in FIG. 29C, a plurality of rack mount computers 5620 are stored in a rack 5610. Note that the large computer 5600 may be referred to as a supercomputer.

The computer 5620 can have a structure in a perspective view of FIG. 29D, for example. In FIG. 29D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 29E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Although FIG. 29E illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The memory device of one embodiment of the present invention can be suitably used for space equipment such as equipment that processes and stores information.

The memory device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

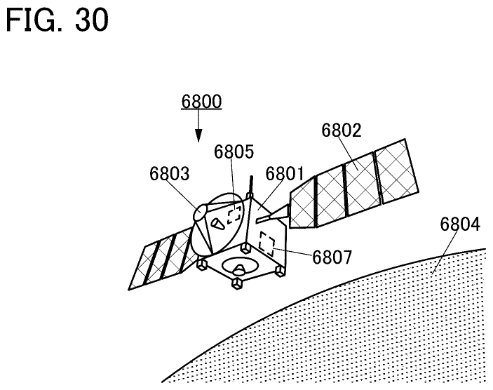

FIG. 30 illustrates an artificial satellite 6800 as an example of space equipment. The artificial satellite 6800 includes a body 6801, a solar panel 6802, an antenna 6803, a secondary battery 6805, and a control device 6807. Note that FIG. 30 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 30, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. One or more selected from a CPU, a GPU, and a memory device are used as the control device 6807, for example. Note that the memory device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The memory device of one embodiment of the present invention can be suitably used for space equipment such as a spacecraft, a space capsule, or a space probe, for example.

As described above, the OS transistor has excellent effects of achieving a wide memory bandwidth and being highly resistant to radiation as compared with the Si transistor.

### [Data Center]

The memory device of one embodiment of the present invention can be suitably used for a storage system in a data center, for example. Long-term management of data, such as guarantee of data immutability, is required for the data center. The long-term management of data needs an increase in building size owing to installation of storages and servers for storing an enormous amount of data, stable electric power for data retention, cooling equipment necessary for data retention, and the like.

With the use of the memory device of one embodiment of the present invention for the storage system used in the data center, electric power required for data retention can be reduced and the size of a memory device retaining data can be downsized. Thus, downsizing of the storage system, downsizing of the power supply for retaining data, downscaling of the cooling equipment, and the like can be achieved. This can reduce the space of the data center.

Since the memory device of one embodiment of the present invention has low power consumption, heat generation from a circuit can be reduced. Accordingly, adverse effects of the heat generation on the circuit itself, the peripheral circuit, and the module can be reduced. Furthermore, the use of the memory device of one embodiment of the present invention enables a data center that operates stably even in a high-temperature environment. Thus, the reliability of the data center can be increased.

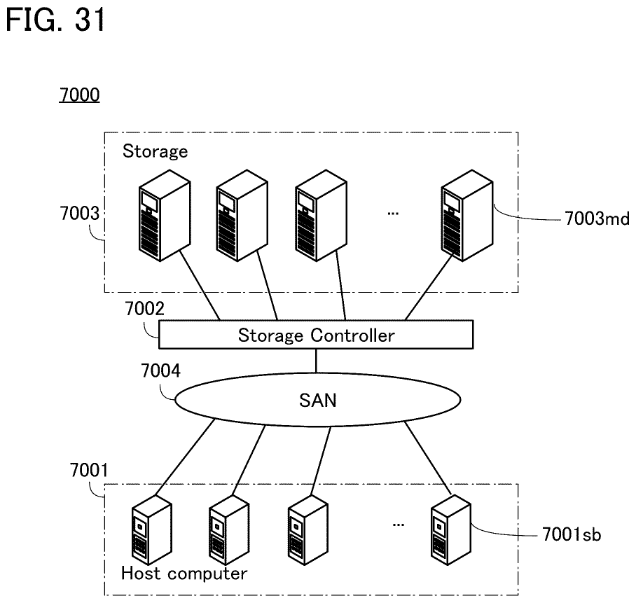

FIG. 31 illustrates a storage system that can be used in a data center. A storage system 7000 illustrated in FIG. 31 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in the storage 7003. In the storage system, in order to solve the problem of low access speed of the storage 7003, a cache memory is normally provided in the storage 7003 to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing of the storage is possible by stacking memory cell arrays.

The use of the memory device of one embodiment of the present invention for one or more selected from an electronic component, an electronic device, a large computer, space equipment, and a data center will produce an effect of reducing power consumption. While the demand for energy is expected to increase with higher performance or integration of semiconductor devices, the use of the memory device of one embodiment of the present invention can thus reduce the emission amount of greenhouse effect gas typified by carbon dioxide (CO₂). The memory device of one embodiment of the present invention can be effectively used as one of the global warming countermeasures because of its low power consumption.

Although this embodiment describes an example of a memory device having a structure in which the one of the source and the drain of the transistor 40 is electrically connected to the gate of the transistor 20, which is described in the above embodiment, the present invention is not limited thereto. For a portion that does not function directly as a memory device, such as a display portion or a control portion in the above electronic component, electronic device, large computer, device for space, data center, or the like, the structure described in the above embodiment in which the one of the source and the drain of the transistor 40 is electrically connected to the gate of the transistor 20 can be used.

The configurations, structures, methods, and the like described in this embodiment can be used in an appropriate combination with any of the configurations, structures, methods, and the like described in the other embodiments and the like.

### REFERENCE NUMERALS

MC: memory cell, RBL[0]: wiring, RBL: wiring, Read: reading period, RWL[0]: wiring, RWL[1]: wiring, RWL: wiring, WBL[0]: wiring, WBL: wiring, Write: writing period, WWL[0]: wiring, WWL[1]: wiring, WWL[2]: wiring, WWL: wiring, 10[0,0]: memory cell, 10[0,1]: memory cell, 10[1,0]: memory cell, 10[1,1]: memory cell, 10a: memory cell, 10b: memory cell, 10: memory cell, 20a: transistor, 20b: transistor, 20: transistor, 22: oxide semiconductor, 24a: conductor, 24b: conductor, 24: conductor, 26: conductor, 28: insulator, 30a: conductor, 30b: conductor, 30c: conductor, 31: insulator, 32a: conductor, 32b: conductor, 32c: conductor, 33: insulator, 34: insulator, 36: insulator, 38: insulator, 40a: transistor, 40b: transistor, 40: transistor, 42a: oxide semiconductor, 42b: oxide semiconductor, 42: oxide semiconductor, 44: conductor, 46a: conductor, 46b: conductor, 46: conductor, 48a: insulator, 48b: insulator, 48c: insulator, 48d: insulator, 48: insulator, 50: conductor, 52a: insulator, 52b: insulator, 52c: insulator, 52: insulator, 54: insulator, 56: insulator, 57: insulator, 58: insulator, 59: insulator, 60: transistor, 62: substrate, 63: semiconductor region, 64a: low-resistance region, 64b: low-resistance region, 66: conductor, 68: insulator, 70a: conductor, 70b: conductor, 70c: conductor, 70: conductor, 72a: conductor, 72b: conductor, 72c: conductor, 72: conductor, 73: insulator, 74: insulator, 76: insulator, 78: insulator, 200: transistor, 205a: conductor, 205b: conductor, 205: conductor, 215: insulator, 216: insulator, 221: insulator, 222: insulator, 224: insulator, 230a: oxide, 230b: oxide, 230c: oxide, 230: oxide, 240a: conductor, 240b: conductor, 240c: conductor, 240d: conductor, 240e: conductor, 240: conductor, 241a: insulator, 241c: insulator, 241d: insulator, 241e: insulator, 241: insulator, 242a: conductor, 242b: conductor, 246a: conductor, 246b: conductor, 246c: conductor, 246d: conductor, 246: conductor, 250a: insulator, 250b: insulator, 250c: insulator, 250d: insulator, 250: insulator, 255a: insulator, 255b: insulator, 255: insulator, 260a: conductor, 260b: conductor, 260: conductor, 271a: insulator, 271b: insulator, 275: insulator, 280: insulator, 282: insulator, 283: insulator, 285: insulator, 286: insulator, 700: electronic component, 702: printed circuit board, 704: circuit board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 1400: memory device, 1411: peripheral circuit, 1420: row circuit, 1430: column circuit, 1440: output circuit, 1460: control logic circuit, 1470: memory cell array, 1480: layer, 1490_1: layer, 1490_m: layer, 1490: layer, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage, 7004: storage area network

1. A semiconductor device comprising:
a first transistor;
a first wiring electrically connected to one of a source and a drain of the first transistor;
a second wiring electrically connected to the other of the source and the drain of the first transistor; and
a second transistor in which a source or a drain is electrically connected to a gate of the first transistor,
wherein the second transistor is provided above the first transistor,
wherein the first transistor comprises a channel formation region in a semiconductor layer,
wherein the semiconductor layer comprises a region that extends in a channel length direction of the first transistor,
wherein the first wiring comprises a region that extends in a channel length direction of the first transistor,
wherein the second wiring comprises a region that extends in a channel width direction of the first transistor,
wherein the first wiring comprises a region positioned below the semiconductor layer to overlap with the semiconductor layer, and
wherein the second wiring comprises a region positioned above the semiconductor layer.

2. A semiconductor device comprising:
a first transistor;
a second transistor over the first transistor; and
a first conductor under the first transistor,
wherein the first transistor comprises:
a first oxide semiconductor;
a second conductor and a third conductor which are separated from each other over the first oxide semiconductor;
a first insulator being positioned over the second conductor and the third conductor and comprising an opening positioned between the second conductor and the third conductor;
a second insulator positioned in the opening of the first insulator and over the first oxide semiconductor; and
a fourth conductor positioned in the opening of the first insulator and over the second insulator,
wherein the second transistor comprises:
a third insulator being positioned over the first insulator and the fourth conductor and comprising an opening overlapping with the first oxide semiconductor;
a fifth conductor being positioned over the third insulator and comprising an opening overlapping with the opening of the third insulator;
a second oxide semiconductor positioned in the opening of the third insulator and the opening of the fifth conductor;
a fourth insulator positioned over the second oxide semiconductor in the opening of the third insulator and the opening of the fifth conductor; and
a sixth conductor positioned over the fourth insulator in the opening of the third insulator and the opening of the fifth conductor,
wherein the second oxide semiconductor is electrically connected to the fourth conductor,
wherein the first conductor is electrically connected to the third conductor,
wherein the first conductor extends in a channel length direction of the first transistor, and
wherein the first conductor is positioned to overlap with the first oxide semiconductor and the second oxide semiconductor.

3. The semiconductor device according to claim 2,
wherein a seventh conductor is placed to penetrate the third conductor and the first oxide semiconductor, and
wherein the seventh conductor is in contact with a top surface of the first conductor.

4. The semiconductor device according to claim 3, further comprising an eighth conductor in contact with a top surface of the sixth conductor,
wherein the eighth conductor extends in a channel length direction of the first transistor, and
wherein the fifth conductor extends to intersect the channel length direction of the first transistor.

5. The semiconductor device according to claim 3, further comprising an eighth conductor in contact with a top surface of the sixth conductor,
wherein the eighth conductor extends to intersect a channel length direction of the first transistor, and
wherein the fifth conductor extends in the channel length direction of the first transistor.

6. The semiconductor device according to claim 2,
wherein the second oxide semiconductor comprises at least one of In, Ga, and Zn.

7. The semiconductor device according to claim 6,
wherein a ninth conductor is positioned over the second conductor, and
wherein the ninth conductor extends to intersect a channel length direction of the first transistor.

8. The semiconductor device according to claim 6,
wherein a tenth conductor is positioned under the second oxide semiconductor,
wherein the opening of the third insulator reaches the tenth conductor,
wherein the tenth conductor is in contact with a part of the second oxide semiconductor, and
wherein the tenth conductor is electrically connected to the fourth conductor.

9. The semiconductor device according to claim 6,
wherein a channel length of the second transistor is smaller than at least a channel width of the second transistor.

10. The semiconductor device according to claim 8,
wherein another part of the second oxide semiconductor, a part of the fourth insulator, and a part of the sixth conductor are positioned over the fifth conductor.

11. The semiconductor device according to claim 10,
wherein the another part of the second oxide semiconductor is in contact with a top surface of the fifth conductor.

12. The semiconductor device according to claim 6,
wherein the opening of the third insulator and the fifth conductor has a circular shape or a substantially circular shape in a plan view.

13. The semiconductor device according to claim 6,
wherein the third insulator has a stacked-layer structure,
wherein the stacked-layer structure comprises a first layer, a second layer over the first layer, and a third layer over the second layer,
wherein the first layer comprises silicon and nitrogen,
wherein the second layer comprises silicon and oxygen, and
wherein the third layer comprises silicon and nitrogen.

14. The semiconductor device according to claim 6,
wherein the first oxide semiconductor comprises at least one of In, Ga, and Zn.

15. A memory device comprising:
the semiconductor device according to claim 7;
a first circuit; and
a second circuit,
wherein the first circuit is electrically connected to the first conductor, and
wherein the second circuit is electrically connected to the ninth conductor.
